(19) United States
(12) Patent Application Publication
(10) Pub. No.: US 2025/0374657 A1
(43) Pub. Date: Dec. 4, 2025

(54) SEMICONDUCTOR PROCESSING INTEGRATION FOR BIPOLAR JUNCTION TRANSISTOR (BJT)

(71) Applicant: TEXAS INSTRUMENTS INCORPORATED, Dallas, TX (US)

(72) Inventors: Giulio Albini, Draper, UT (US); Jonathan Lane, Sandy, UT (US); Robert Cassel, Lehi, UT (US)

(21) Appl. No.: 18/680,460

(22) Filed: May 31, 2024

(51) Int. Cl. H01L 27/06; H01L 21/762; H01L 21/8249; H01L 29/08; H01L 29/66; H01L 29/732

(52) U.S. Cl. CPC H10D 84/401; H10D 10/051; H10D 10/40; H10D 62/138; H10D 84/0109; H10D 84/038; H01L 21/76229

(57) ABSTRACT

The present disclosure generally relates to semiconductor processing integration for a bipolar junction transistor (BJT). In an example, a semiconductor device includes a semiconductor substrate, an etch stop layer, a pedestal dielectric layer, a BJT, and a field effect transistor (FET). The semiconductor substrate includes a BJT region and a complementary FET (CFET) region. The etch stop layer is over the semiconductor substrate in the BJT region. The pedestal dielectric layer is over the etch stop layer in the BJT region. The BJT is on the semiconductor substrate in the BJT region. At least a first portion of the BJT is in an opening through the pedestal dielectric layer and the etch stop layer. At least a second portion of the BJT is further over the pedestal dielectric layer. The FET is on the semiconductor substrate in the CFET region.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices. Further, integrating a BJT with other devices may complicate that semiconductor processing.

### SUMMARY

An example described herein is a semiconductor device. The semiconductor device includes a semiconductor substrate, an etch stop layer, a pedestal dielectric layer, a bipolar junction transistor (BJT), and a field effect transistor (FET). The semiconductor substrate includes a BJT region and a complementary FET (CFET) region. The etch stop layer is over the semiconductor substrate in the BJT region. The pedestal dielectric layer is over the etch stop layer in the BJT region. The BJT is on the semiconductor substrate in the BJT region. At least a first portion of the BJT is in an opening through the pedestal dielectric layer and the etch stop layer. At least a second portion of the BJT is further over the pedestal dielectric layer. The FET is on the semiconductor substrate in the CFET region.

Another example is a method. A gate layer is formed over a semiconductor substrate in a BJT region and a CFET region. The gate layer is patterned into a gate electrode of a FET in the CFET region. A etch stop layer is formed conformally over the semiconductor substrate in the BJT region and the CFET region and over the gate electrode. A collector layer is formed on the semiconductor substrate and in an opening through the etch stop layer in the BJT region. A base layer is formed on the collector layer and at least partially over the etch stop layer. An emitter layer is formed on the base layer.

A further example is a method. A gate layer is formed over a semiconductor substrate in a BJT region and a CFET region. The gate layer is patterned in the CFET region into a gate electrode of a FET in the CFET region. A first etch stop layer is formed conformally in the CFET region and the BJT region. The first etch stop layer is along a side of the gate electrode and over the gate electrode. A collector layer is formed on the semiconductor substrate and through an opening in the first etch stop layer in the BJT region. A material of a base layer is formed over the collector layer and over the first etch stop layer. A material of an emitter layer is formed over the base layer. The material of the emitter layer is patterned into the emitter layer in the BJT region. The material of the base layer is patterned into the base layer in the BJT region.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1A and 1B through FIGS. 32A and 32B are respective cross-sectional views of a semiconductor device in intermediate stages of manufacturing according to some examples.

FIGS. 33A and 33B through FIGS. 39A and 39B are respective cross-sectional views of a semiconductor device in intermediate stages of manufacturing according to some examples.

FIGS. 40A and 40B through FIGS. 42A and 42B are respective cross-sectional views of a semiconductor device in intermediate stages of manufacturing according to some examples.

FIGS. 43A and 43B through FIGS. 45A and 45B are respective cross-sectional views of a semiconductor device in intermediate stages of manufacturing according to some examples.

FIG. 46 is a layout view of overlaid components of a bipolar junction transistor (BJT) according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing integration for a bipolar junction transistor (BJT). Some examples include a semiconductor device including a BJT. A semiconductor substrate includes a BJT region and a complementary field effect transistor (CFET) region. An etch stop layer is over the semiconductor substrate in the BJT region, and a pedestal dielectric layer is over the etch stop layer in the BJT region. A BJT is on the semiconductor substrate in the BJT region. At least a portion of the BJT is in an opening through the pedestal dielectric layer and the etch stop layer, and at least a portion of the BJT is over the pedestal dielectric layer. A field effect transistor (FET) is on the semiconductor substrate in the CFET region.

Methods of fabricating such a semiconductor device are described. Generally, a gate electrode of the FET in the CFET region may be patterned and a sidewall of the gate electrode oxidized before layers of the BJT are formed. An etch stop layer may then be formed over the gate electrode to permit removal of any materials and/or layers subsequently formed over the gate electrode. Performing such oxidation before forming layers of the BJT may avoid performing some higher temperature processing after doped layers of a BJT have been formed, which may permit outdiffusion and/or outgassing of dopants from those doped layers to be reduced. Other benefits and advantages may be achieved.

Various examples are described subsequently. Although the specific examples may illustrate various aspects of the above generally described features, examples may incorporate any combination of the above generally described features (which are described in more detail in examples below).

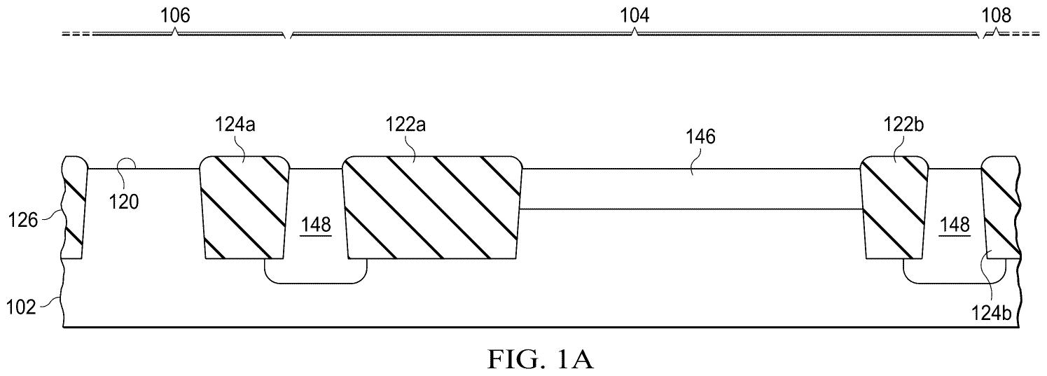

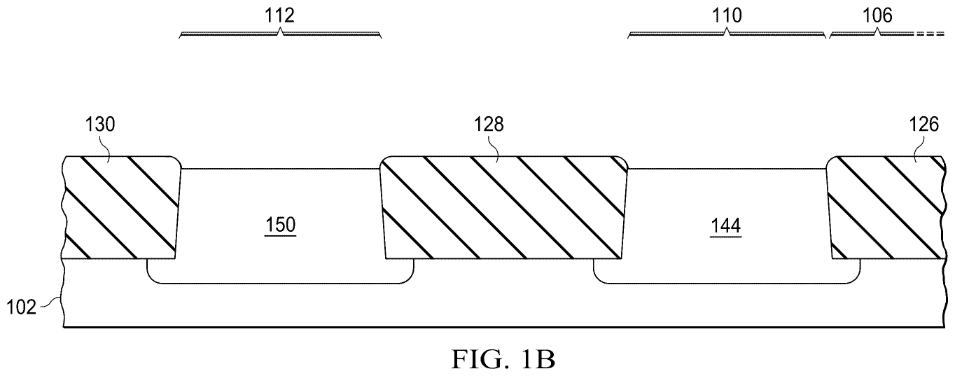

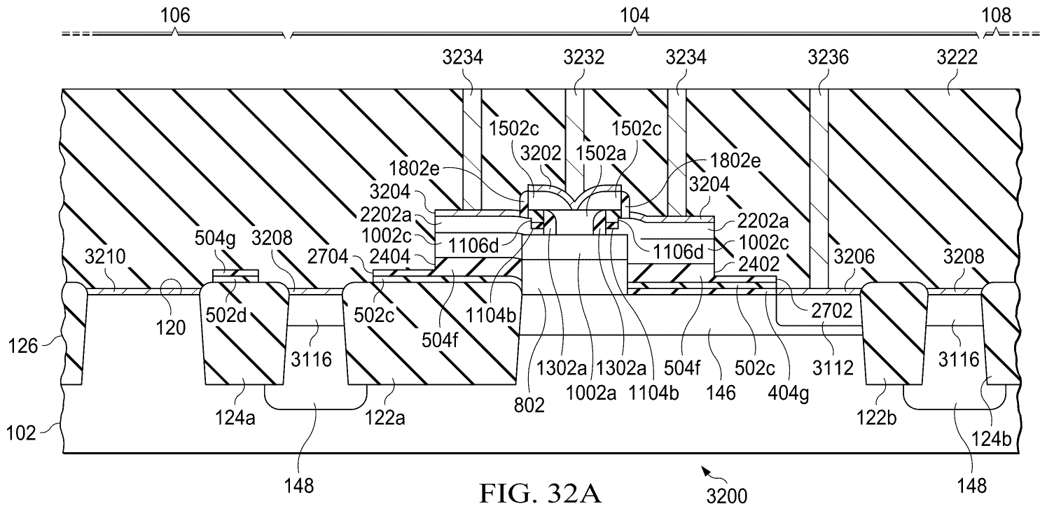

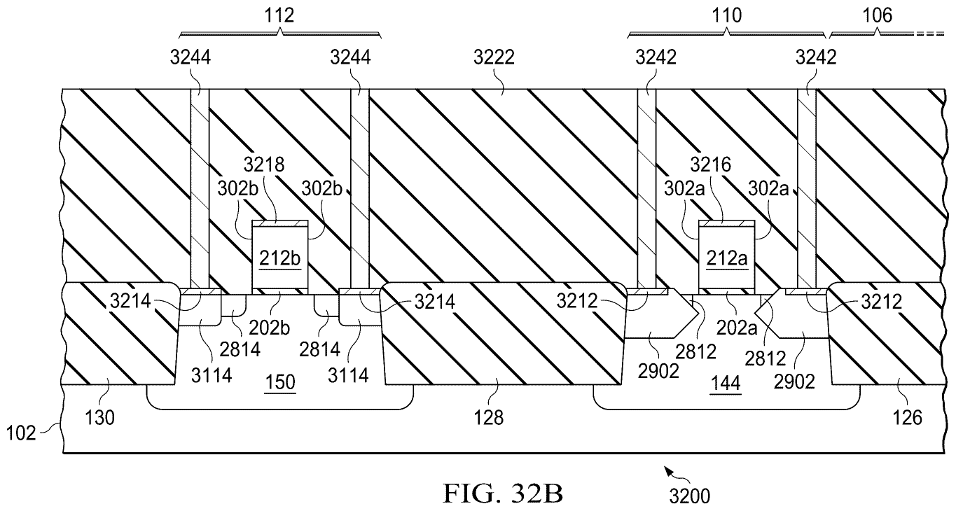

FIGS. 1A and 1B through FIGS. 32A and 32B are respective cross-sectional views of a semiconductor device in intermediate stages of manufacturing according to some examples. The method illustrated in these figures forms the semiconductor device 3200 of FIGS. 32A and 32B.

Referring to FIGS. 1A and 1B, a semiconductor substrate 102 is provided. The semiconductor substrate 102 includes a BJT region 104, a first transition region 106, a second transition region 108, a p-type FET (pFET) region 110, and an n-type FET (nFET) region 112. Together, the pFET region 110 and the nFET region 112 are included in a complementary field effect transistor (CFET) region.

The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material in and/or on which devices, such as a BJT, a pFET, and an nFET (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 102 has an upper surface 120 in and/or on which devices (e.g., the BJT, pFET, and nFET) are formed. In the illustrated example, the semiconductor material of the semiconductor substrate 102 is p-type doped with a p-type dopant. In some examples, the semiconductor substrate 102 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

Isolation structures 122 (including a first portion 122a and a second portion 122b), 124 (including a first portion 124a and a second portion 124b), 126, 128, 130 are formed on the semiconductor substrate 102. In the illustrated example, the isolation structures 122-130 are shallow trench isolation structures (STIs) extending from the upper surface 120 of the semiconductor substrate 102 into the semiconductor substrate 102. As illustrated, the isolation structures 122-130 are also raised above the upper surface 120 of the semiconductor substrate 102, and in other examples, the isolation structures 122-130 may have respective upper surfaces co-planar with and/or below the upper surface 120 of the semiconductor substrate 102. The isolation structures 122-130 may include, for example, a liner layer, such as including silicon oxide or silicon nitride, conformally along surfaces of a respective trench in the semiconductor substrate 102 and a fill isolation material, such as silicon oxide, over and on the liner layer.

The isolation structures 122-130, as illustrated, may be formed by depositing a hardmask layer over the semiconductor substrate 102. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, in the semiconductor substrate 102 using the patterned hardmask layer as a mask. The liner layer may then be conformally deposited in the recesses or trenches and over the patterned hardmask layer, such as by plasma enhanced CVD (PECVD) or formed on exposed surfaces of the recesses or trenches (e.g., by an oxidation process), and the fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structures 122-130 may be field oxide structures, such as local oxidation of silicon (LOCOS) structures, at the upper surface 120 of the semiconductor substrate 102, which may be formed using a LOCOS process.

The isolation structure 122 laterally defines an active area of the upper surface 120 of the semiconductor substrate 102 on which the BJT is to be formed. The isolation structure 122 laterally encircles or encompasses the active area of the upper surface 120 of the semiconductor substrate 102 on which the BJT is to be formed. As indicated subsequently, an active portion (e.g., a base layer) of the BJT extends laterally beyond the active area of the upper surface 120 of the semiconductor substrate 102 on which the BJT is formed and over the first portion 122a of the isolation structure 122. Further, the isolation structure 124 defines lateral boundaries of the BJT region 104. The isolation structure 124 laterally encircles or encompasses the isolation structure 122 with a doped isolation or guardring well therebetween, as described subsequently.

The isolation structures 126, 128 laterally define, at least in part, an active area of the upper surface 120 of the semiconductor substrate 102 on which the pFET is to be formed. The active area of the upper surface 120 of the semiconductor substrate 102 on which the pFET is formed defines the lateral boundary of the pFET region 110. Similarly, the isolation structures 128, 130 laterally define, at least in part, an active area of the upper surface 120 of the semiconductor substrate 102 on which the nFET is to be formed. The active area of the upper surface 120 of the semiconductor substrate 102 on which the nFET is formed defines the lateral boundary of the nFET region 112. The CFET region includes the pFET region 110 and the nFET region 112. The laterally exterior boundaries of the pFET region 110 and/or nFET region 112 (or other pFET and/or nFET regions) define the lateral boundary of the CFET region.

The first transition region 106 is defined from a lateral boundary of the BJT region 104 to a nearest lateral boundary of the CFET region (which in the illustrated example is a boundary of the pFET region 110). The first transition region 106 includes the isolation structure 126 and the first portion 124a of the isolation structure 124. As illustrated, a portion of the upper surface 120 of the semiconductor substrate 102 is between the first portion 124a of the isolation structure 124 and the isolation structure 126 in the first transition region 106. In other examples, the first transition region 106 may have an isolation structure laterally throughout the first transition region 106. The second transition region 108 is defined from a lateral boundary of the BJT region 104 to a nearest lateral boundary of another region (not illustrated). The second transition region 108 includes the second portion 124b of the isolation structure 124. The second transition region 108 may be formed and/or structured like the first transition region 106.

An n-type doped well 144 is formed in the semiconductor substrate 102 in the pFET region 110. The n-type doped well 144 may be formed by masking (e.g., by a photoresist using photolithography) areas of the semiconductor substrate 102 where an n-type doped well is not to be formed and implanting n-type dopants into the semiconductor substrate 102. The n-type doped well 144 extends from the upper surface 120 of the semiconductor substrate 102 into a depth in the semiconductor substrate 102 and is in the pFET region 110 laterally between the isolation structures 126, 128. A concentration of the n-type dopant of the n-type doped well 144 is greater than a concentration of the p-type dopant of the p-type doped semiconductor substrate 102. In some examples, the n-type doped well 144 is doped with an n-type dopant (e.g., phosphorus (P) or arsenic (As)) with a concentration in a range from 1×10¹⁵ cm⁻³ to 1×10¹⁷ cm⁻³. Another dopant and/or other doping concentrations may be implemented.

An n-type doped sub-collector diffusion region 146 is formed in the semiconductor substrate 102 in the BJT region 104 and laterally between the portions 122a, 122b of the isolation structure 122. The n-type doped sub-collector diffusion region 146 may be formed by masking (e.g., by a photoresist using photolithography) areas of the semiconductor substrate 102 where an n-type doped sub-collector diffusion region is not to be formed and implanting n-type dopants into the semiconductor substrate 102. The n-type doped sub-collector diffusion region 146 extends from the upper surface 120 of the semiconductor substrate 102 into a depth in the semiconductor substrate 102 and is in the BJT region 104 laterally between the portions 122a, 122b of the isolation structure 122. A concentration of the n-type doped sub-collector diffusion region 146 is greater than a concentration of the p-type dopant of the semiconductor substrate 102. In some examples, the n-type doped sub-collector diffusion region 146 is doped with an n-type dopant with a concentration in a range from 1×10¹⁸ cm⁻³ to 1×10²⁰ cm⁻³. Another dopant and/or other doping concentrations may be implemented.

P-type doped wells 148, 150 are formed in the semiconductor substrate 102. The p-type doped wells 148, 150 may be formed by masking (e.g., by a photoresist using photolithography) areas of the semiconductor substrate 102 where a p-type doped well is not to be formed and implanting p-type dopants into the semiconductor substrate 102. The p-type doped well 148 extends from the upper surface 120 of the semiconductor substrate 102 into a depth in the semiconductor substrate 102 and is in the BJT region 104 laterally between the isolation structures 122, 124. The p-type doped well 148 is an isolation ring or guardring laterally encircling or encompassing the active area in which the BJT is to be formed. The p-type doped well 150 extends from the upper surface 120 of the semiconductor substrate 102 into a depth in the semiconductor substrate 102 and is in the nFET region 112 laterally between the isolation structures 128, 130. A concentration of the p-type dopant of the p-type doped wells 148, 150 is greater than a concentration of the p-type dopant of the p-type doped semiconductor substrate 102. In some examples, the p-type doped wells 148, 150 are doped with a p-type dopant with a concentration in a range from 1×10¹⁵ cm⁻³ to 1×10¹⁷ cm⁻³. Another dopant and/or other doping concentrations may be implemented.

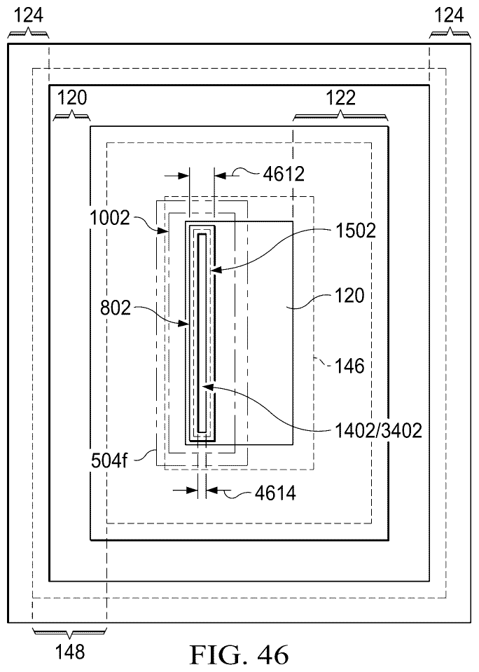

Referring to FIG. 46, the n-type doped sub-collector diffusion region 146 and the p-type doped well 148 are shown (e.g., by dashed line boundaries) in a layout view of the BJT region 104 and neighboring portions of the transition regions 106, 108. Additionally, the isolation structures 122, 124 are shown (e.g., by solid line boundaries) with the upper surface 120 of the semiconductor substrate 102 shown between the isolation structures 122, 124, as well as within the isolation structure 122.

Although the semiconductor substrate 102, n-type doped well 144, n-type doped sub-collector diffusion region 146, and p-type doped wells 148, 150 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

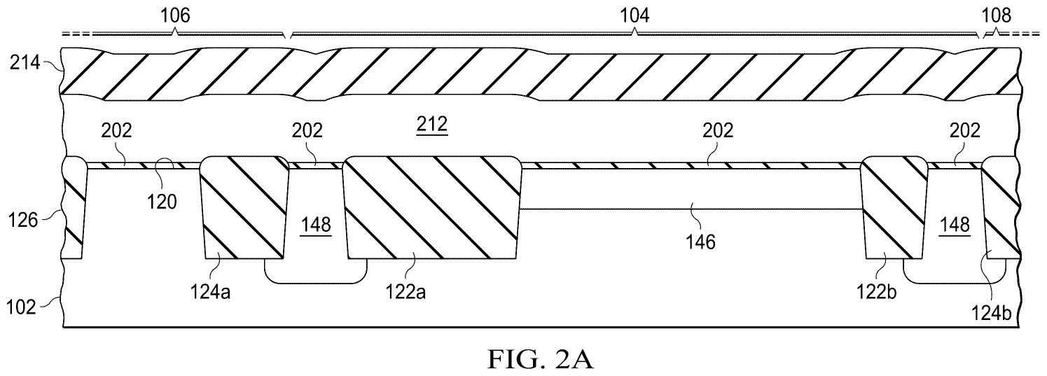

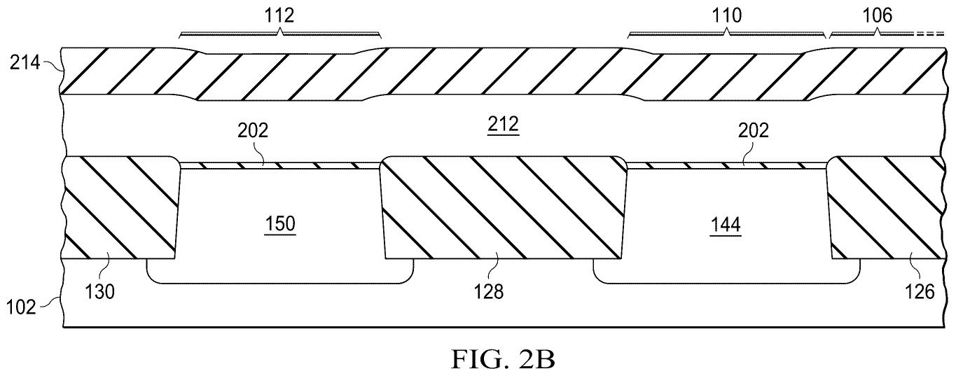

Referring to FIGS. 2A and 2B, gate dielectric layers 202 are formed on or over the upper surface 120 of the semiconductor substrate 102 in the regions 104-112. In some examples, the gate dielectric layers 202 may be silicon oxide formed using oxidation, such as by in situ steam generation (ISSG) oxidation or another oxidation process. In other examples, another dielectric material and/or another deposition process may be used to form the gate dielectric layers 202. In some examples, different gate dielectric layers and/or gate dielectric layers with different thicknesses may be formed in different regions, such as to form pFETs and/or nFETs rated for different operating voltages (e.g., in high voltage applications, medium voltage applications, or low voltage applications). In such examples, iterative processes for oxidizing the upper surface 120 of the semiconductor substrate 102 may be performed, such as described in U.S. patent application Ser. No. 18/520,527, entitled “SEMICONDUCTOR PROCESSING INTEGRATION FOR BIPOLAR JUNCTION TRANSISTOR (BJT)”, filed on Nov. 27, 2023, the entirety of which is incorporated herein by reference.

A gate layer 212 is formed over the semiconductor substrate 102 in the regions 104-112, and a hardmask layer 214 is formed over the gate layer 212 in the regions 104-112. The gate layer 212 is formed over the gate dielectric layers 202 and the isolation structures 122-130. In some examples, the gate layer 212 is or includes a semiconductor material, such as polycrystalline silicon (polysilicon), and may be formed by any deposition process, such as CVD. In some examples, the semiconductor material may be doped in situ during deposition and/or may be implanted by a dopant after deposition. For example, the gate layer 212 may be in situ doped during deposition with a p-type dopant, and after deposition, a portion of the gate layer 212 may be implanted with an n-type dopant to a greater concentration than the p-type dopant while another portion of the gate layer 212 is masked (e.g., by a photoresist formed by photolithography). In some examples, the gate layer 212 in the BJT region 104, transition regions 106, 108, and pFET region 110 is polysilicon doped with a p-type dopant with a concentration in a range from 1×10¹⁹ cm⁻³ to 1×10²¹ cm⁻³ after deposition and/or implantation, and the gate layer 212 in the nFET region 112 is polysilicon doped with an n-type dopant with a concentration in a range from 5×10¹⁹ cm⁻³ to 5×10²¹ cm⁻³ after implantation. Other materials (e.g., conductive material) may be implemented as the gate layer 212, which may be formed by any deposition process. In some examples, the hardmask layer 214 is silicon nitride deposited by CVD, although other dielectric materials and/or other deposition processes may be used in other examples.

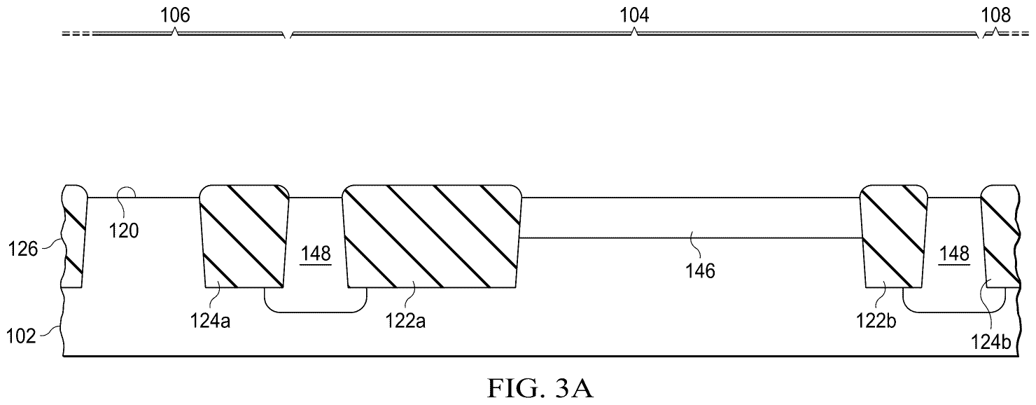

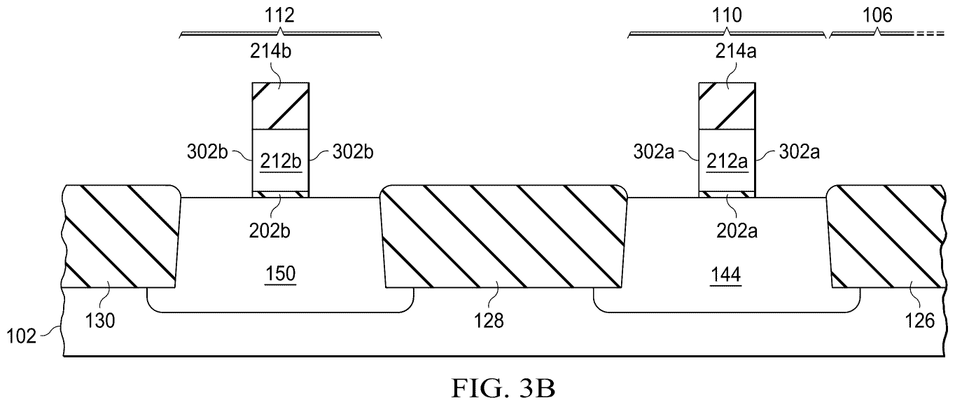

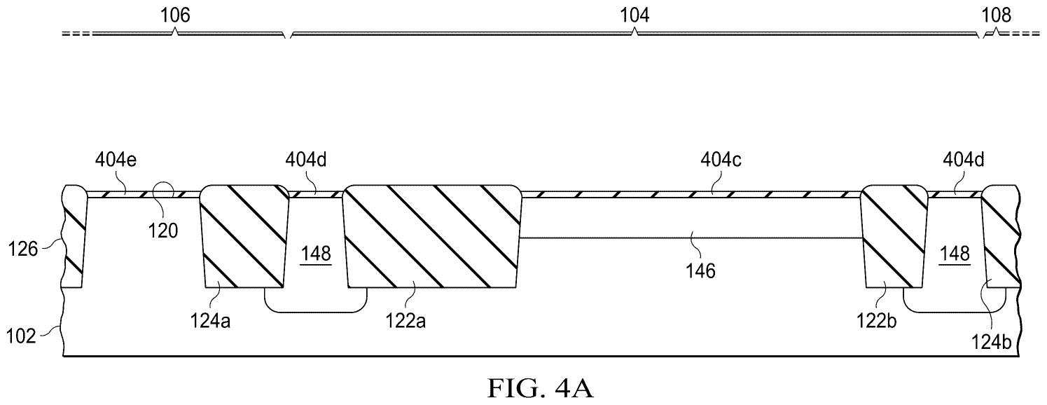

Referring to FIGS. 3A and 3B, the gate layer 212 is patterned into gate electrodes 212a, 212b in the pFET region 110 and nFET region 112, respectively, and the gate dielectric layers 202 are patterned into gate dielectric layers 202a, 202b in the pFET region 110 and nFET region 112, respectively. The hardmask layer 214 is patterned to hardmask layers 214a, 214b in the pFET region 110 and nFET region 112, respectively. The hardmask layers 214a, 214b are patterned corresponding to the pattern of the gate electrodes 212a, 212b. The hardmask layer 214, gate layer 212, and gate dielectric layers 202 are removed from the BJT region 104 and transition regions 106, 108. In the illustrated example, the hardmask layer 214 is patterned using appropriate photolithography and etch (e.g., RIE) processes. Using the patterned hardmask layers 214a, 214b as a mask, the gate layer 212 and the gate dielectric layers 202 are patterned. The gate layer 212 and the gate dielectric layers 202 are patterned using an appropriate etch process (e.g., RIE).

The gate electrode 212a is over (e.g., on) the gate dielectric layer 202a in the pFET region 110, and the gate electrode 212b is over (e.g., on) the gate dielectric layer 202b in the nFET region 112. The hardmask layers 214a, 214b remain over (e.g., on) the gate electrodes 212a, 212b, respectively. The gate electrode 212a has opposing sidewalls 302a, and the gate dielectric layer 202a and hardmask layer 214a have respective sidewalls that align with the opposing sidewalls 302a. The gate electrode 212b has opposing sidewalls 302b, and the gate dielectric layer 202b and hardmask layer 214b have respective sidewalls that align with the opposing sidewalls 302b.

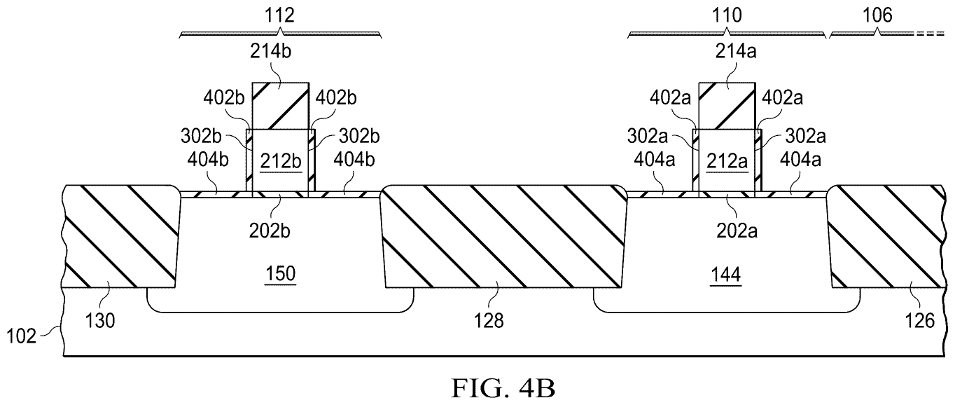

Referring to FIGS. 4A and 4B, reoxidation layers 402a, 402b are formed along the sidewalls 302a, 302b of the gate electrodes 212a, 212b. The reoxidation layers 402a, 402b may be formed by oxidizing the sidewalls 302a, 302b of the gate electrodes 212a, 212b, such as by ISSG oxidation. In some examples, the oxidation process may be performed at 750° C. or more for 45 seconds or more. The formation of the reoxidation layers 402a, 402b may remove damage on the sidewalls 302a, 302b of the gate electrodes 212a, 212b formed by the etch process that patterns the gate electrodes 212a, 212b, which damage may be plasma-induced. The formation of the reoxidation layers 402a, 402b may reduce gate-induced drain leakage current in the FETs (that include the gate electrodes 212a, 212b) that are to be formed.

Formation of the reoxidation layers 402a, 402b before formation of layers of the BJT (e.g., the collector layer, the base layer, emitter layer, and/or, if applicable, a raised base layer) permits a higher thermal budget for forming the reoxidation layers 402a, 402b. Without the layers of the BJT being present, concerns for outdiffusion and/or outgassing of dopants of those layers in high temperature processes is obviated for the formation of the reoxidation layers 402a, 402b. The formation of the reoxidation layers 402a, 402b may further form reoxidation layers 404a, 404b, 404c, 404d, 404e on exposed portions of the upper surface 120 of the semiconductor substrate 102.

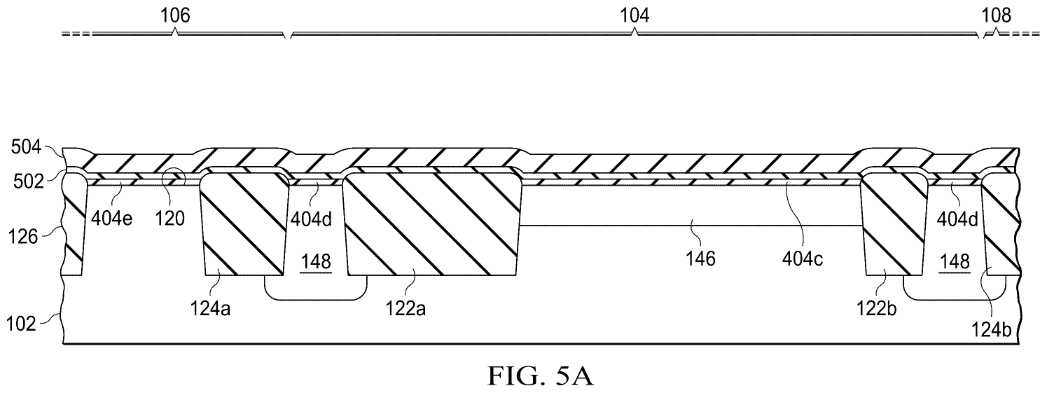

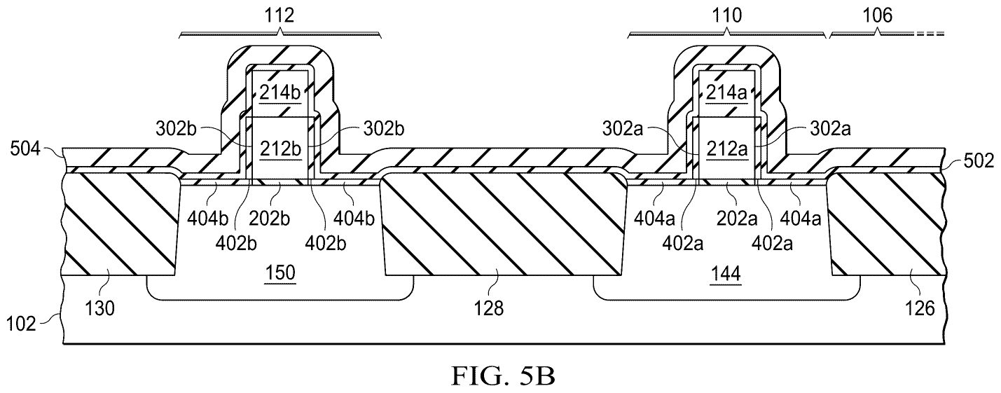

Referring to FIGS. 5A and 5B, an etch stop layer 502 is formed conformally over the semiconductor substrate 102 in the regions 104-112, and a pedestal dielectric layer 504 is formed over the etch stop layer 502 in the regions 104-112. The etch stop layer 502 is conformally deposited over the reoxidation layers 404a, 404b, 404c, 404d, 404e, the isolation structures 122-130, and the hardmask layers 214a, 214b (e.g., over the gate electrodes 212a, 212b) and along sidewalls of the reoxidation layers 402a, 402b and the hardmask layers 214a, 214b. Generally, an etch stop layer permits etch selectivity between the etch stop layer and an immediately overlying material or layer, and/or between the etch stop layer and an immediately underlying material or layer. For example, being or including a material different from immediately overlying or underlying materials or layers may permit etch selectivity. In some examples, the etch stop layer 502 is or includes a material different from the pedestal dielectric layer 504. In some examples, the etch stop layer 502 is silicon nitride deposited by CVD, atomic layer deposition (ALD), or the like, although other dielectric materials and/or other deposition processes may be used in other examples. In some examples, the pedestal dielectric layer 504 is silicon oxide (e.g., a tetraethyl orthosilicate (TEOS) oxide) deposited by CVD, although other dielectric materials and/or other deposition processes may be used in other examples. As illustrated subsequently, the etch stop layer 502 permits layers that are subsequently formed over the gate electrodes 212a, 212b to be selectively removed from over the gate electrodes 212a, 212b by etch processes.

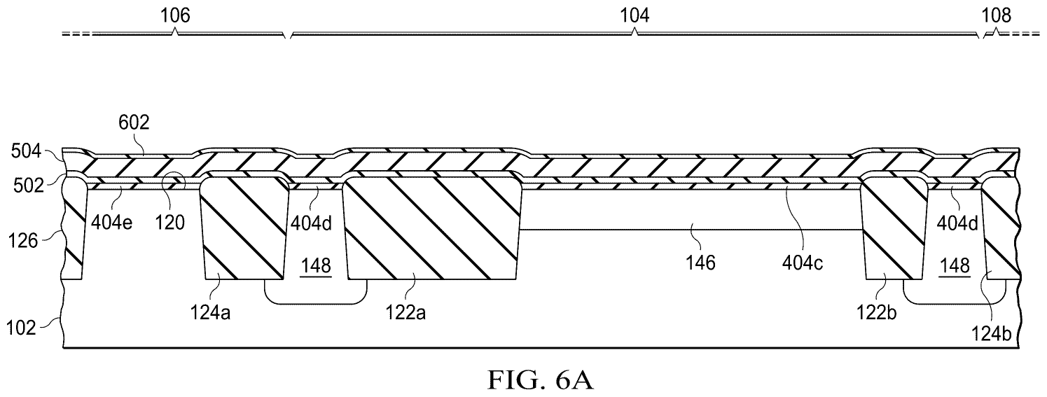

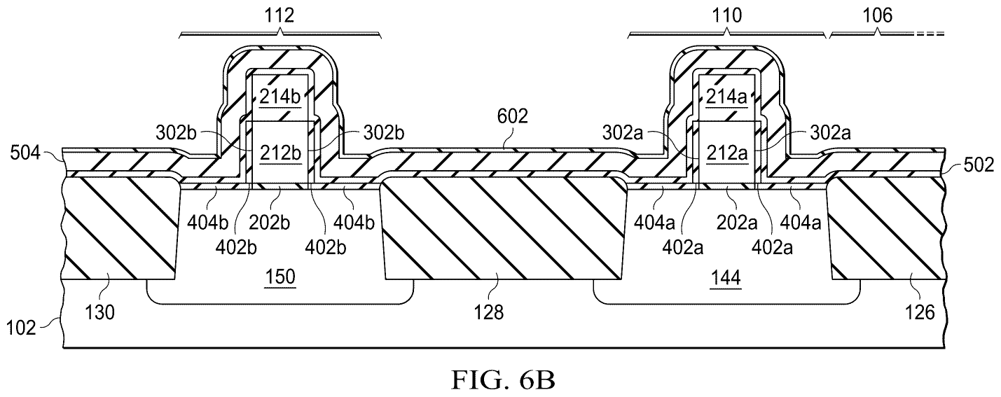

Referring to FIGS. 6A and 6B, a hardmask layer 602 is formed conformally over the pedestal dielectric layer 504 in the regions 104-112. In some examples, the hardmask layer 602 is or includes silicon nitride deposited by CVD, although other hardmask (e.g., dielectric) materials and/or other deposition processes may be used in other examples.

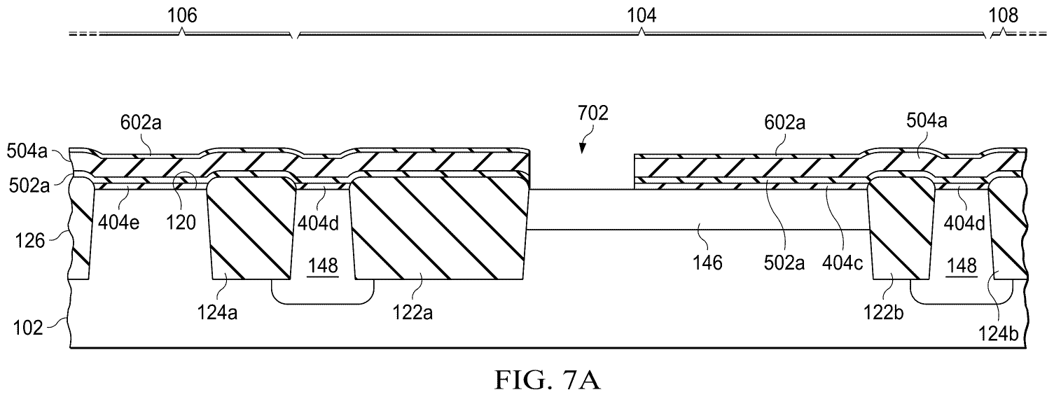

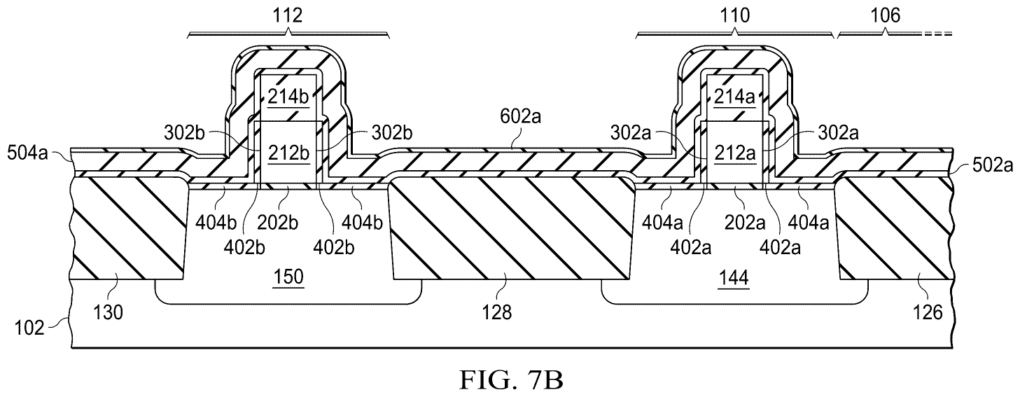

Referring to FIGS. 7A and 7B, the hardmask layer 602, the pedestal dielectric layer 504, the etch stop layer 502, and a portion of the reoxidation layers 404c are etched to form a collector opening 702 through the hardmask layer 602a, the pedestal dielectric layer 504a, and the etch stop layer 502a. The upper surface 120 of the semiconductor substrate 102 is exposed through the collector opening 702. The collector opening 702 generally extends from proximate to (or some lateral distance from) the first portion 122a of the isolation structure 122 laterally away from the first portion 122a of the isolation structure 122 in the BJT region 104. The collector opening 702 may be formed through the hardmask layer 602, pedestal dielectric layer 504, etch stop layer 502, and a portion of the reoxidation layers 404c using appropriate photolithography and etch (e.g., RIE) processes.

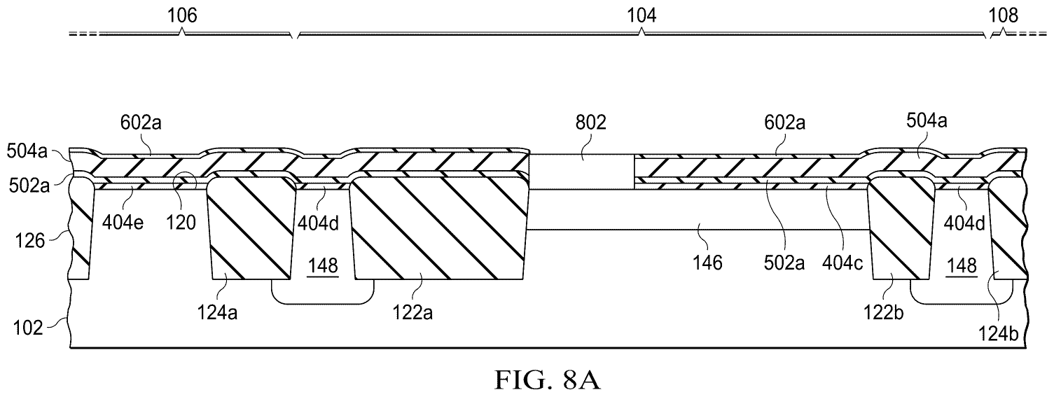

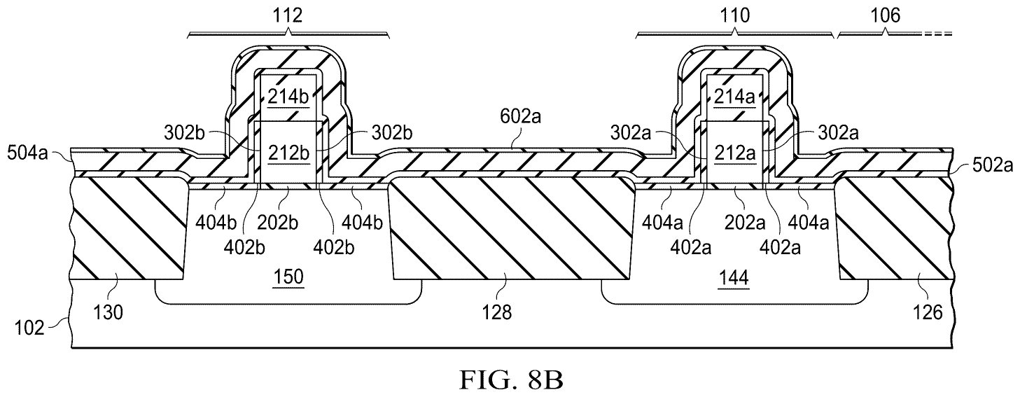

Referring to FIGS. 8A and 8B, a collector layer 802 is formed over (e.g., on) the upper surface 120 of the semiconductor substrate 102 and in the collector opening 702. In some examples, the collector layer 802 is or includes a semiconductor layer doped with an n-type dopant (e.g., a same dopant type as the n-type doped sub-collector diffusion region 146). In some examples, the collector layer 802 is or includes silicon. In some examples, the collector layer 802 is doped with an n-type dopant with a concentration in a range from 1×10¹⁹ cm⁻³ to 1×10²¹ cm⁻³. The collector layer 802 may be epitaxially grown on the upper surface 120 of the semiconductor substrate 102. The collector layer 802 may be epitaxially grown by a selective epitaxial growth process in some examples. The epitaxial growth of the collector layer 802 on the upper surface 120 of the semiconductor substrate 102 may result in the collector layer 802 being monocrystalline. Further, the collector layer 802 may be in situ doped during the epitaxial growth process (e.g., the selective epitaxial growth process). The epitaxial growth process may be a CVD process, such as a low pressure CVD (LPCVD), reduced pressure CVD (RPCVD), metal organic CVD (MOCVD), or the like. Other materials, dopant type, dopant concentration, and/or deposition process may be implemented.

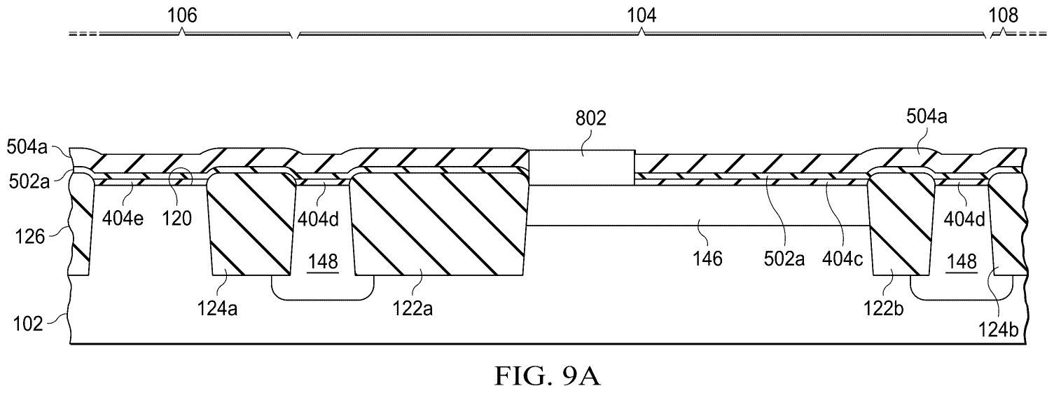

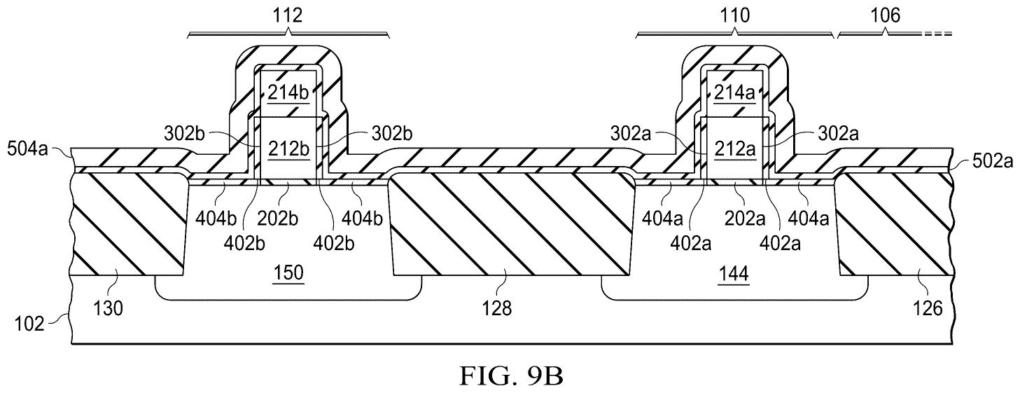

Referring to FIGS. 9A and 9B, the hardmask layer 602a is removed. The hardmask layer 602a may be removed using an etch selective to the material of the hardmask layer 602a. The etch process may be a wet or dry etch process and may be isotropic. For example, when the hardmask layer 602a is silicon nitride, the etch process may be or include using phosphoric acid.

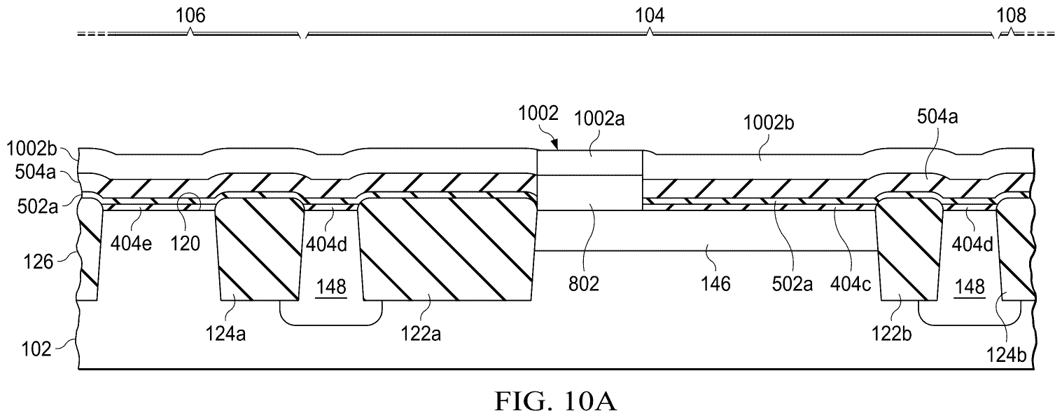

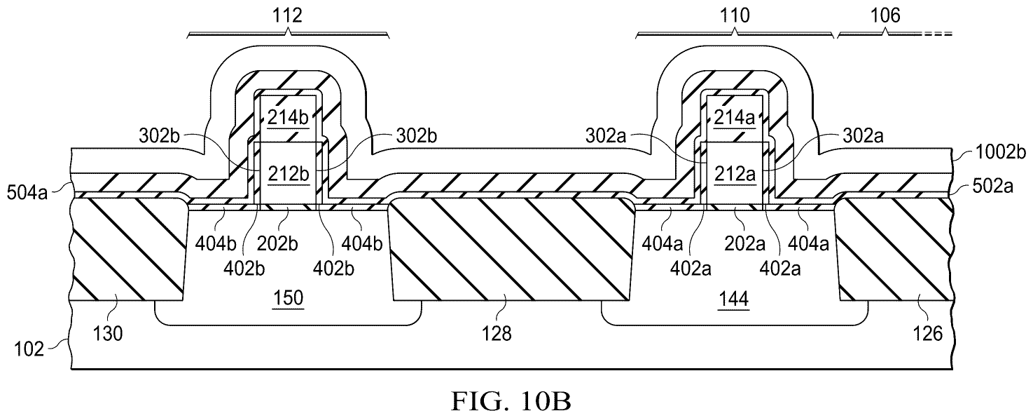

Referring to FIGS. 10A and 10B, a base layer 1002 is formed over the collector layer 802. The base layer 1002 includes a monocrystalline base layer 1002a and a polycrystalline base layer 1002b. The monocrystalline base layer 1002a and polycrystalline base layer 1002b together form the base layer 1002. In some examples, the base layer 1002 is or includes a semiconductor layer doped with a p-type dopant (e.g., an opposite dopant type as the collector layer 802). In some examples, the base layer 1002 is or includes silicon germanium. In some examples, the base layer 1002 is doped with a p-type dopant with a concentration in a range from 1×10¹⁷ cm⁻³ to 1×10²¹ cm⁻³. The base layer 1002 may also be doped with carbon (C) to prevent or reduce diffusion of the p-type dopant. The base layer 1002 may be epitaxially grown on the collector layer 802 and conformally on the pedestal dielectric layer 504a in the regions 104-112. The base layer 1002 may be epitaxially grown by a non-selective epitaxial growth process in some examples. The non-selective epitaxial growth process grows the monocrystalline base layer 1002a from the collector layer 802 and grows the polycrystalline base layer 1002b on other amorphous or polycrystalline surfaces, such as the pedestal dielectric layer 504a. The monocrystalline base layer 1002a may meet the polycrystalline base layer 1002b at a facet that is not specifically illustrated. The non-selective deposition of the base layer 1002 forms the base layer 1002 conformally. The base layer 1002 may be in situ doped during the epitaxial growth process. The base layer 1002 (e.g., the monocrystalline base layer 1002a and polycrystalline base layer 1002b each) may further include multiple sub-layers, such as a nucleation sub-layer of the same material as the collector layer 802, an undoped sub-layer, a doped sub-layer, and a cap sub-layer of the same material of the emitter layer (described subsequently). The epitaxial growth process may be a CVD process, such as LPCVD, RPCVD, MOCVD, or the like. Other materials, dopant type, dopant concentration, and/or deposition process may be implemented.

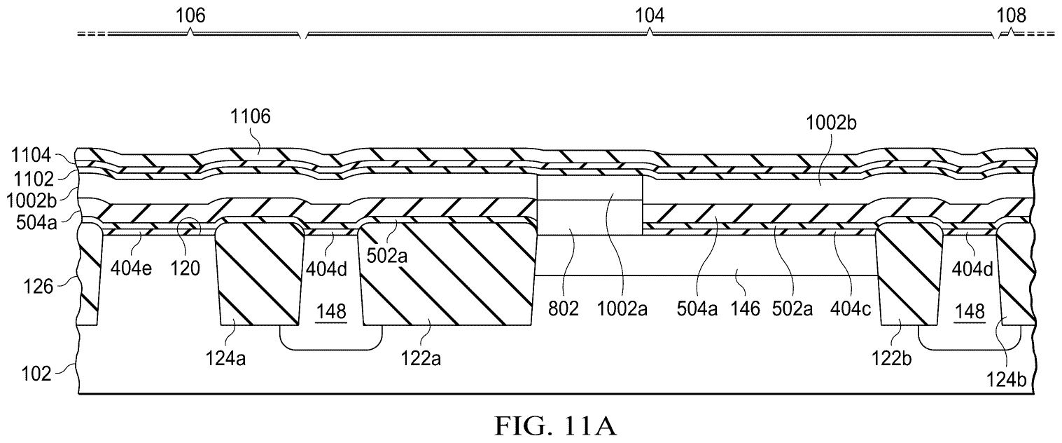

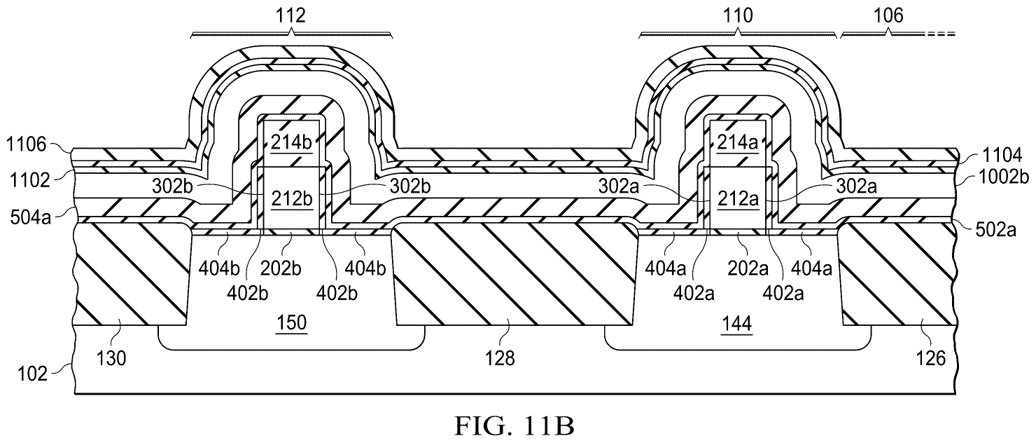

Referring to FIGS. 11A and 11B, a first dielectric spacer layer 1102 is formed conformally over the base layer 1002 in the regions 104-112. A second dielectric spacer layer 1104 is formed conformally over the first dielectric spacer layer 1102 in the regions 104-112, and a third dielectric spacer layer 1106 is formed conformally over the second dielectric spacer layer 1104 in the regions 104-112. In some examples, the first dielectric spacer layer 1102 and third dielectric spacer layer 1106 are a same dielectric material, and the second dielectric spacer layer 1104 is a dielectric material different from the dielectric material of the first dielectric spacer layer 1102 and third dielectric spacer layer 1106. In some examples, the first dielectric spacer layer 1102 and third dielectric spacer layer 1106 are silicon oxide (e.g., a TEOS oxide), and the second dielectric spacer layer 1104 is silicon nitride. The dielectric spacer layers 1102-1106 may be deposited by CVD. Other dielectric materials and/or other deposition processes may be used in other examples.

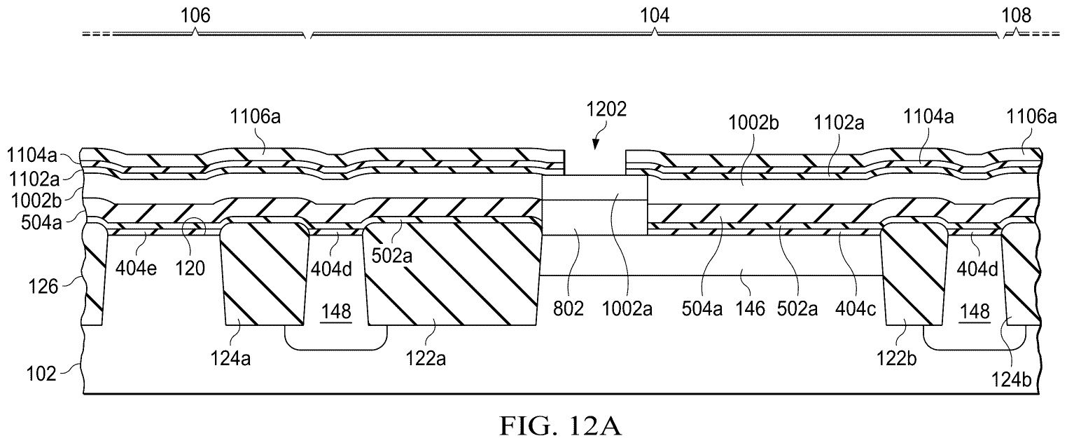

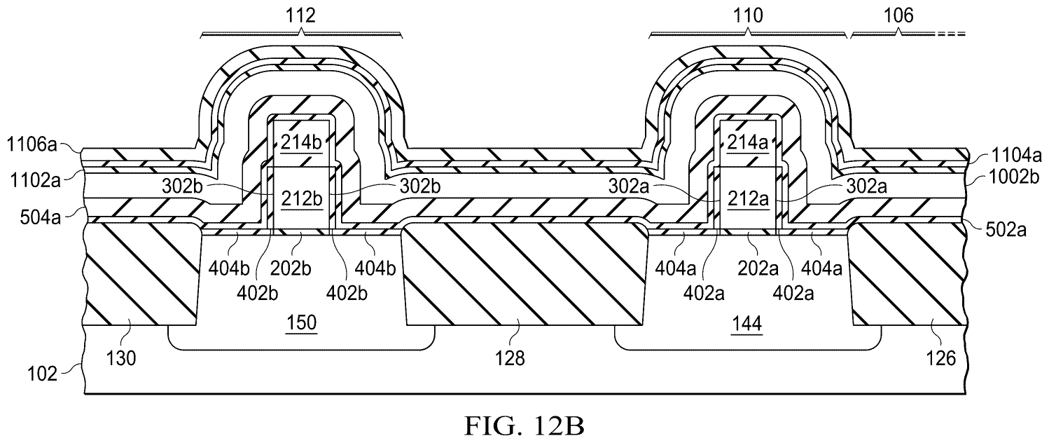

Referring to FIGS. 12A and 12B, the dielectric spacer layers 1102-1106 are etched to form a first emitter opening 1202 through the first dielectric spacer layer 1102a, second dielectric spacer layer 1104a, and third dielectric spacer layer 1106a. The monocrystalline base layer 1002a (of the base layer 1002) is exposed through the first emitter opening 1202. The first emitter opening 1202 is in the BJT region 104. The dielectric spacer layers 1102-1106 may be patterned using appropriate photolithography and etch (e.g., RIE) processes.

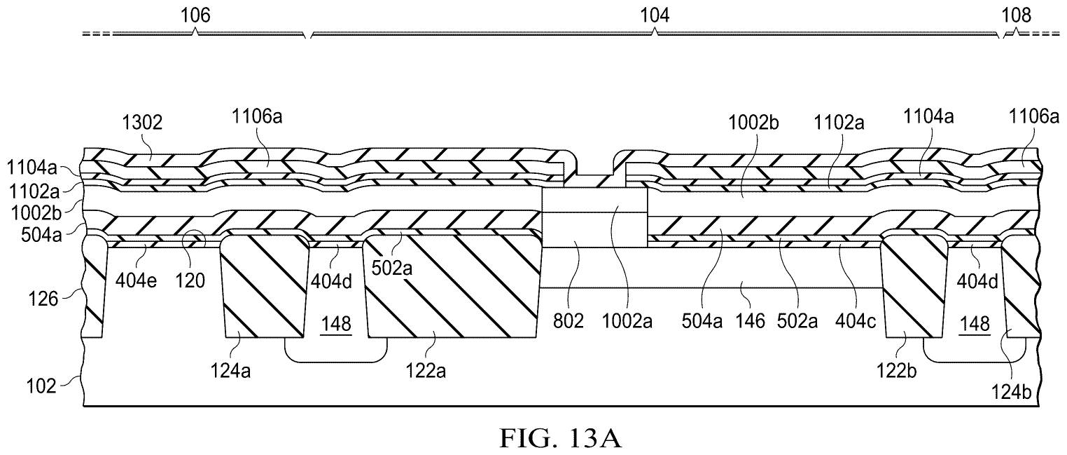

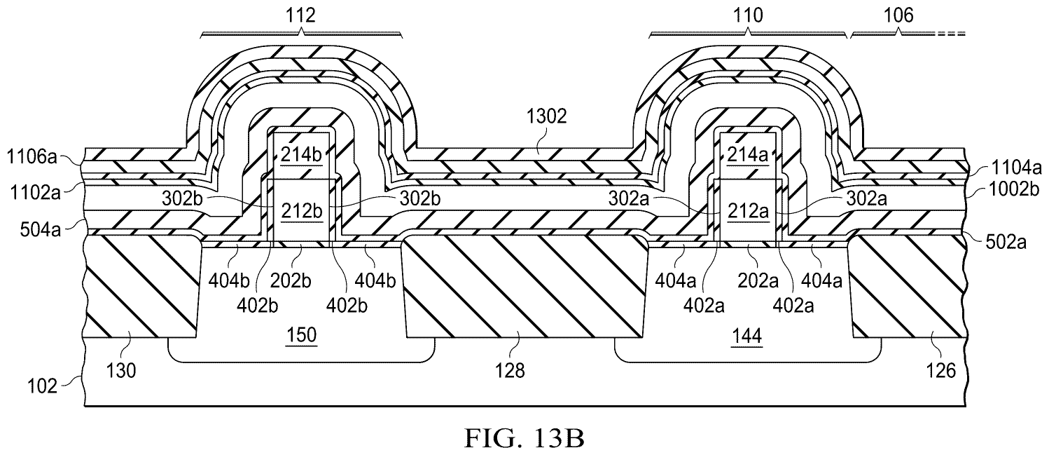

Referring to FIGS. 13A and 13B, an emitter dielectric spacer layer 1302 is conformally formed over the third dielectric spacer layer 1106a and in the first emitter opening 1202. In some examples, the emitter dielectric spacer layer 1302 is silicon oxide (e.g., a TEOS oxide) deposited by CVD, although other dielectric materials and/or other deposition processes may be used in other examples.

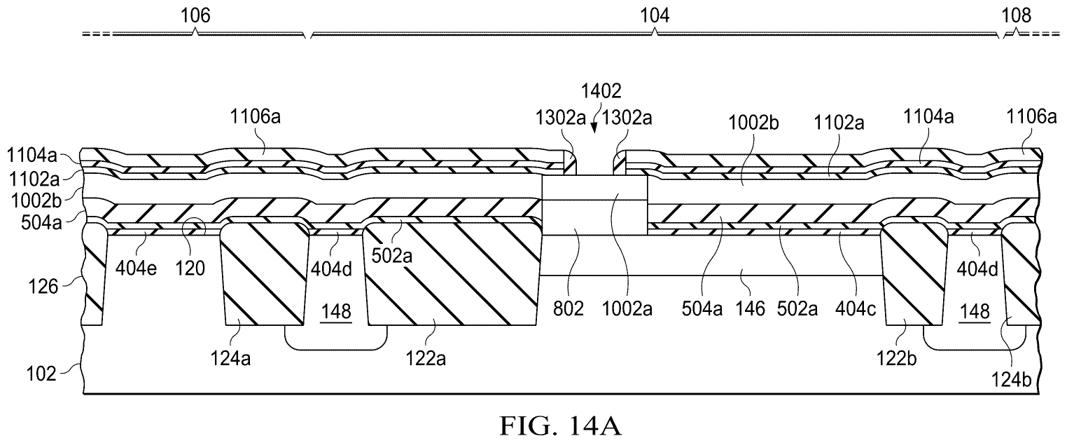

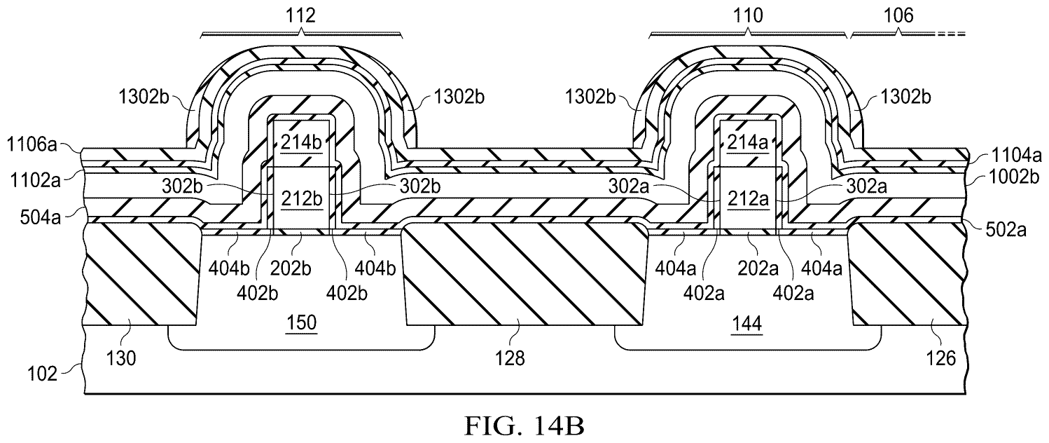

Referring to FIGS. 14A and 14B, the emitter dielectric spacer layer 1302 is anisotropically etched to form emitter dielectric spacers 1302a along sidewalls of the dielectric spacer layers 1102a, 1104a, 1106a that define the first emitter opening 1202. The emitter dielectric spacers 1302a constrict the first emitter opening 1202 to form a second emitter opening 1402. Additionally, residual dielectric spacers 1302b may remain on respective vertical surfaces, such as vertical surfaces at the sidewalls 302a, 302b of the gate electrodes 212a, 212b. The anisotropic etch may be an RIE, for example.

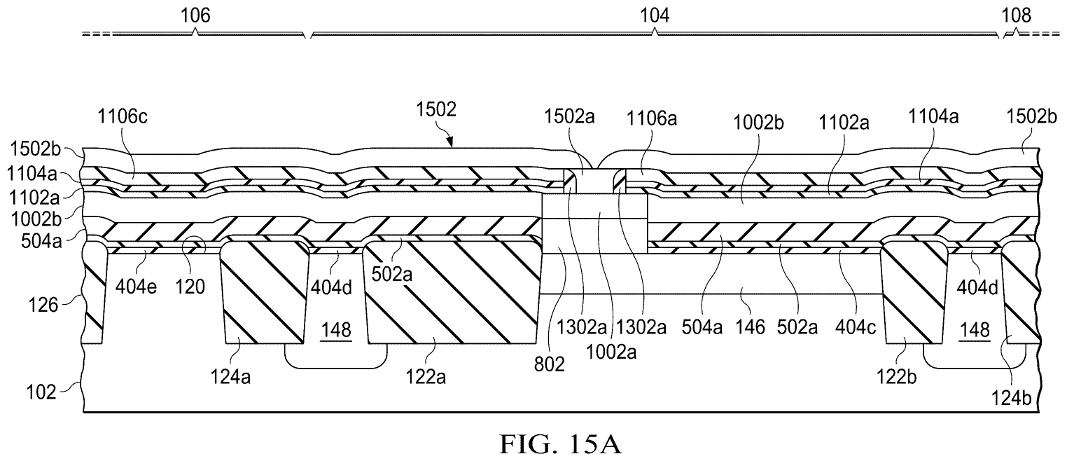

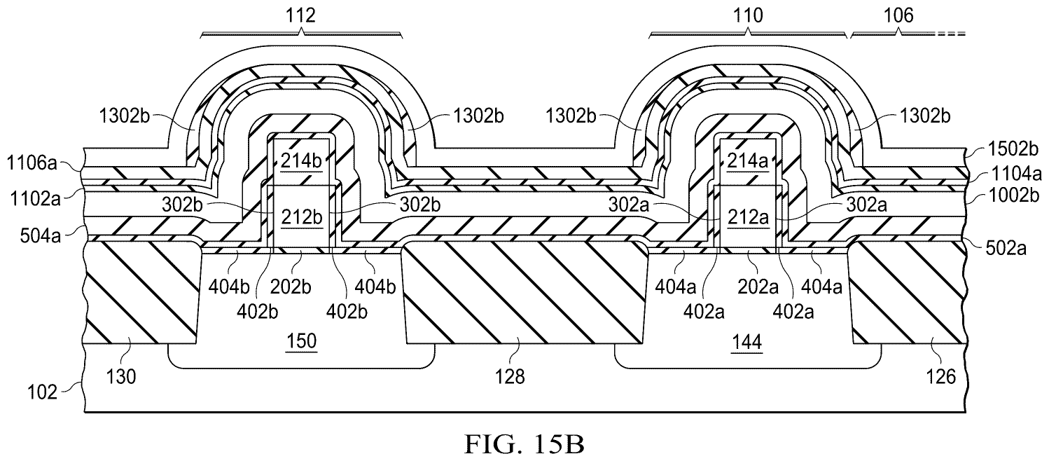

Referring to FIGS. 15A and 15B, an emitter layer 1502 is formed over the base layer 1002 (e.g., on the monocrystalline base layer 1002a). The emitter layer 1502 includes a monocrystalline emitter layer 1502a and a polycrystalline emitter layer 1502b. The monocrystalline emitter layer 1502a and polycrystalline emitter layer 1502b together form the emitter layer 1502. In some examples, the emitter layer 1502 is or includes a semiconductor layer doped with an n-type dopant (e.g., an opposite dopant type from the base layer 1002). In some examples, the emitter layer 1502 is or includes silicon. In some examples, the emitter layer 1502 is doped with an n-type dopant with a concentration in a range from 1×10¹⁹ cm⁻³ to 1×10²¹ cm⁻³. The emitter layer 1502 may be epitaxially grown on the base layer 1002 (e.g., the monocrystalline base layer 1002a) exposed through the second emitter opening 1402, the emitter dielectric spacers 1302a, the third dielectric spacer layer 1106a, and the residual dielectric spacers 1302b. The emitter layer 1502 may be epitaxially grown by a non-selective epitaxial growth process in some examples. The non-selective epitaxial growth process grows the monocrystalline emitter layer 1502a from the monocrystalline base layer 1002a and grows the polycrystalline emitter layer 1502b on other amorphous or polycrystalline surfaces, such as the emitter dielectric spacers 1302a, the third dielectric spacer layer 1106a, and the residual dielectric spacers 1302b. The monocrystalline emitter layer 1502a may meet the polycrystalline emitter layer 1502b at a facet that is not specifically illustrated. The non-selective deposition of the emitter layer 1502 forms the emitter layer 1502 conformally. The emitter layer 1502 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

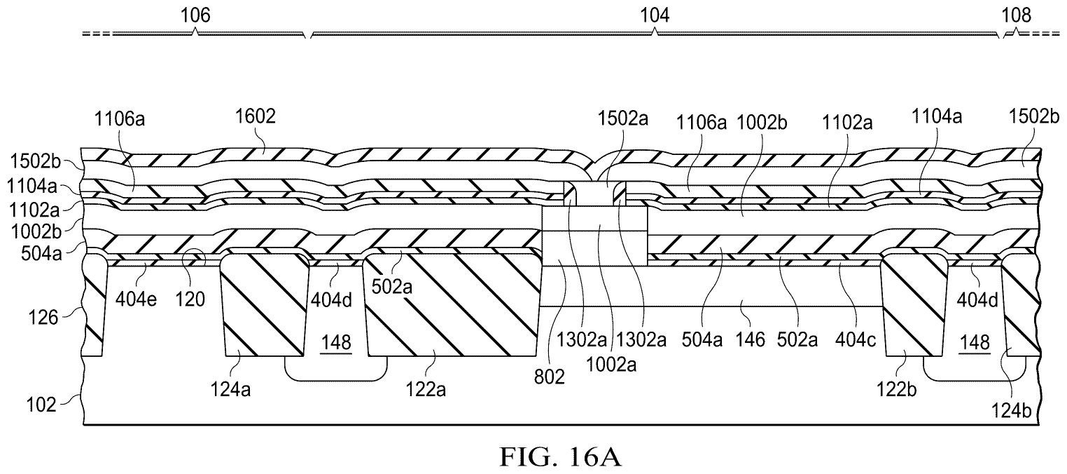

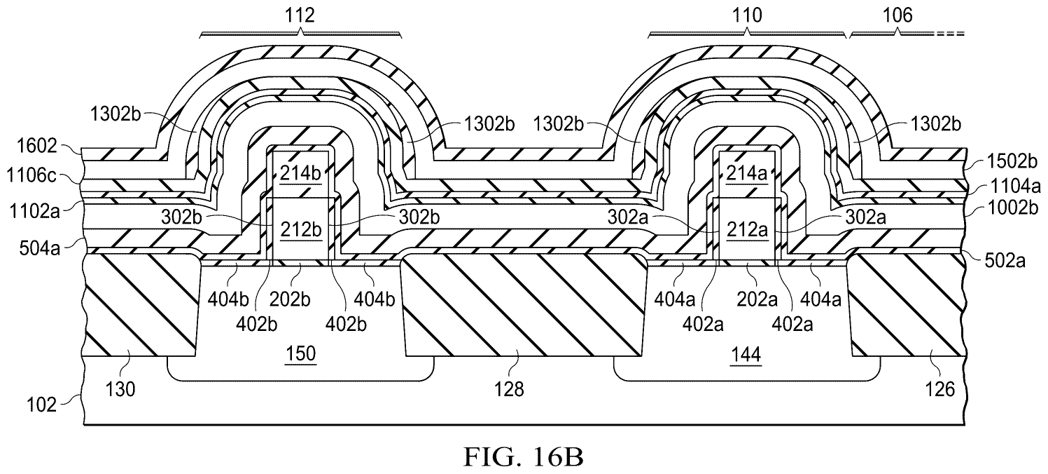

Referring to FIGS. 16A and 16B, an emitter dielectric cap layer 1602 is conformally formed over the emitter layer 1502 in the regions 104-112. In some examples, the emitter dielectric cap layer 1602 is silicon oxide (e.g., a TEOS oxide) deposited by CVD, although other dielectric materials and/or other deposition processes may be used in other examples.

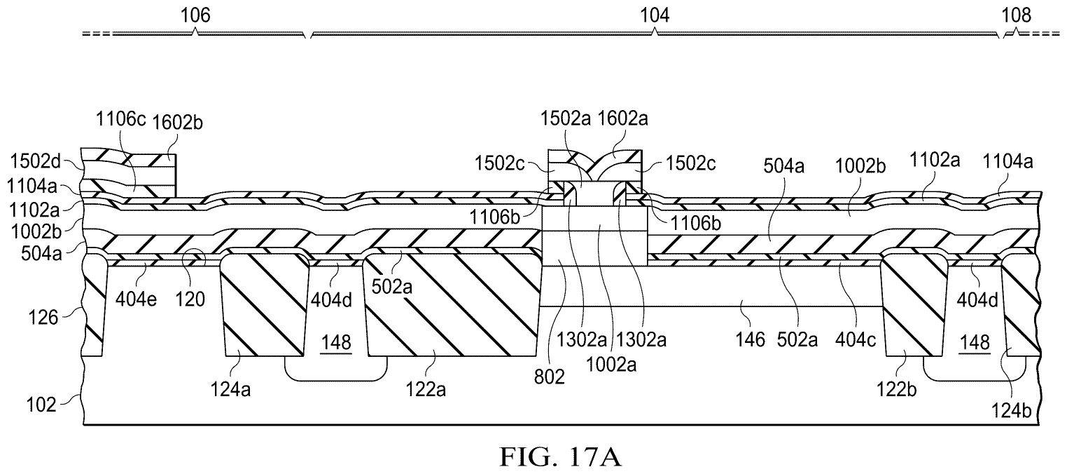

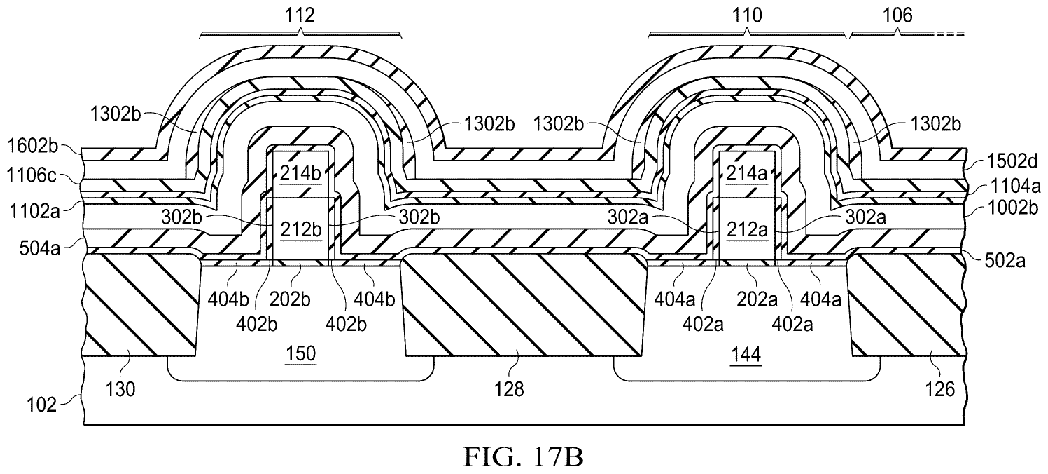

Referring to FIGS. 17A and 17B, the emitter dielectric cap layer 1602, polycrystalline emitter layer 1502b, and third dielectric spacer layer 1106a are etched to form the emitter dielectric cap layer 1602a, polycrystalline emitter layer 1502c, and third dielectric spacer 1106b in the BJT region 104. In the illustrated example, the layers 1602, 1502b, 1106a are patterned using appropriate photolithography and etch (e.g., anisotropic etch, such as RIE) processes. Residual emitter dielectric cap layer 1602b, residual polycrystalline emitter layer 1502d, and residual third dielectric spacer layer 1106c may remain, as illustrated, in the pFET region 110, nFET region 112, and at least partially in the first transition region 106 proximate to the pFET region 110.

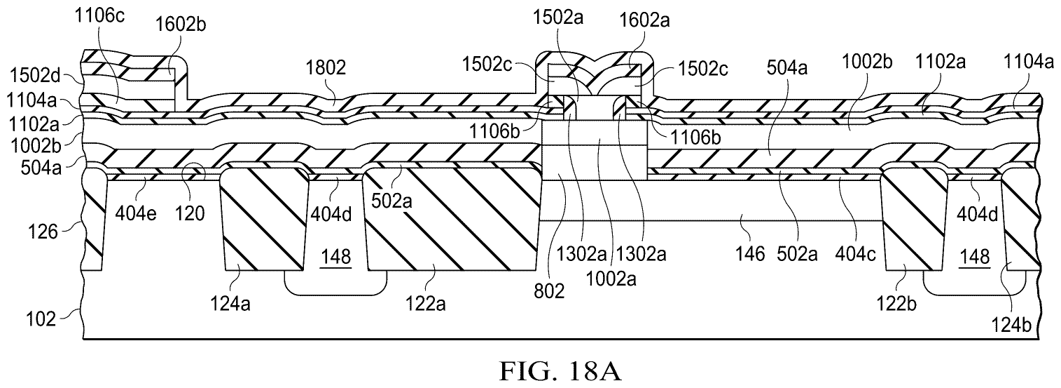

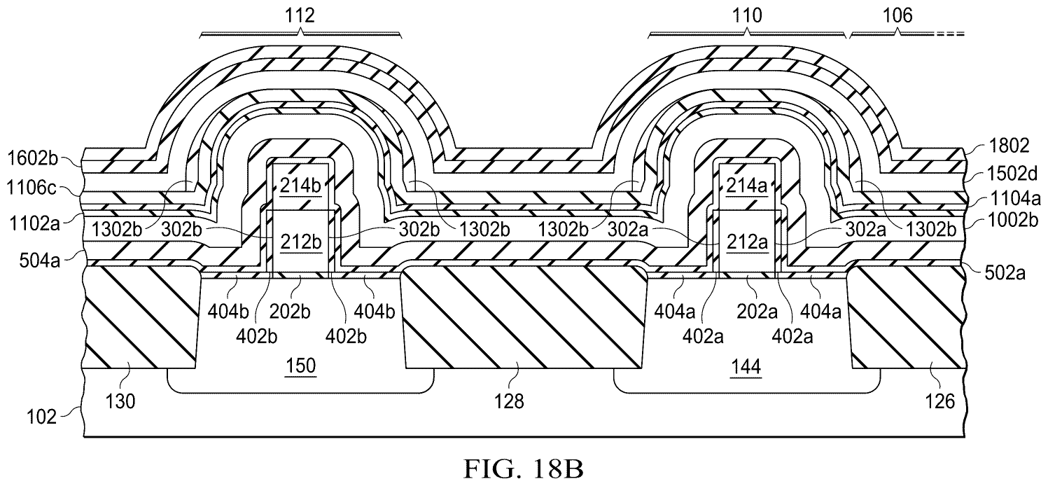

Referring to FIGS. 18A and 18B, an emitter dielectric protective spacer layer 1802 is conformally formed over the emitter dielectric cap layer 1602a and the second dielectric spacer layer 1104a and along sidewalls of the emitter dielectric cap layer 1602a, polycrystalline emitter layer 1502c, and third dielectric spacer 1106b in the BJT region 104. Additionally, the emitter dielectric protective spacer layer 1802 is conformally formed over the residual emitter dielectric cap layer 1602b in the pFET region 110, nFET region 112, and first transition region 106 and along sidewalls of the residual emitter dielectric cap layer 1602b, residual polycrystalline emitter layer 1502d, and residual third dielectric spacer layer 1106c in the first transition region 106. In some examples, the emitter dielectric protective spacer layer 1802 is silicon oxide (e.g., a TEOS oxide) deposited by CVD, although other dielectric materials and/or other deposition processes may be used in other examples.

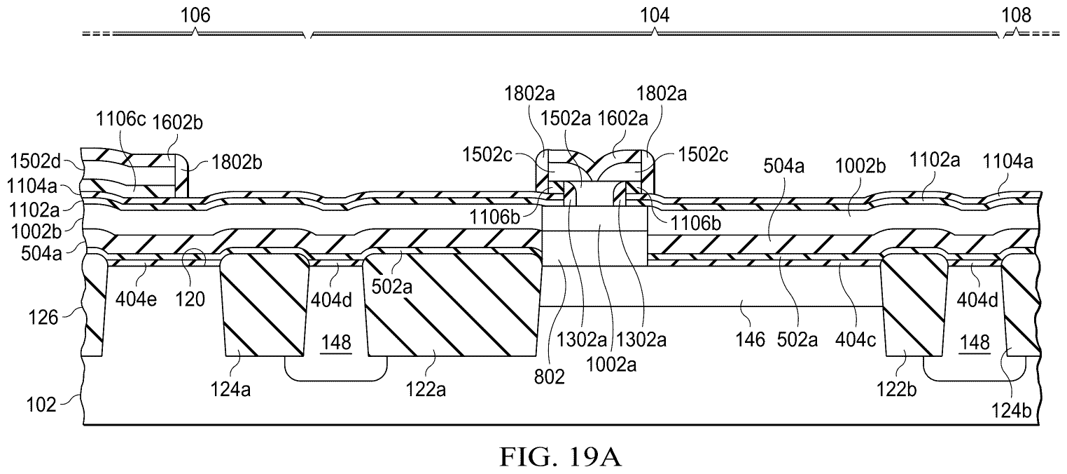

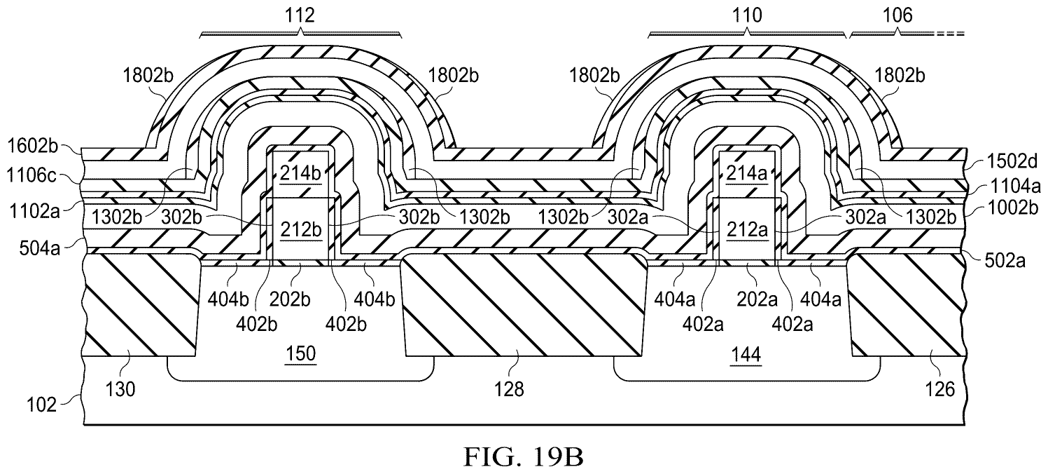

Referring to FIGS. 19A and 19B, the emitter dielectric protective spacer layer 1802 is anisotropically etched to form emitter dielectric protective spacers 1802a along sidewalls of the emitter dielectric cap layer 1602a, polycrystalline emitter layer 1502c, and third dielectric spacer 1106b. The emitter dielectric protective spacers 1802a protect sidewalls of the polycrystalline emitter layer 1502c. Additionally, residual dielectric spacers 1802b may remain on vertical surfaces, such as vertical surfaces of the residual emitter dielectric cap layer 1602b, residual polycrystalline emitter layer 1502d, and residual third dielectric spacer layer 1106c in the first transition region 106 and vertical surfaces of the residual emitter dielectric cap layer 1602b in the pFET region 110 and the nFET region 112. The anisotropic etch may be an RIE, for example.

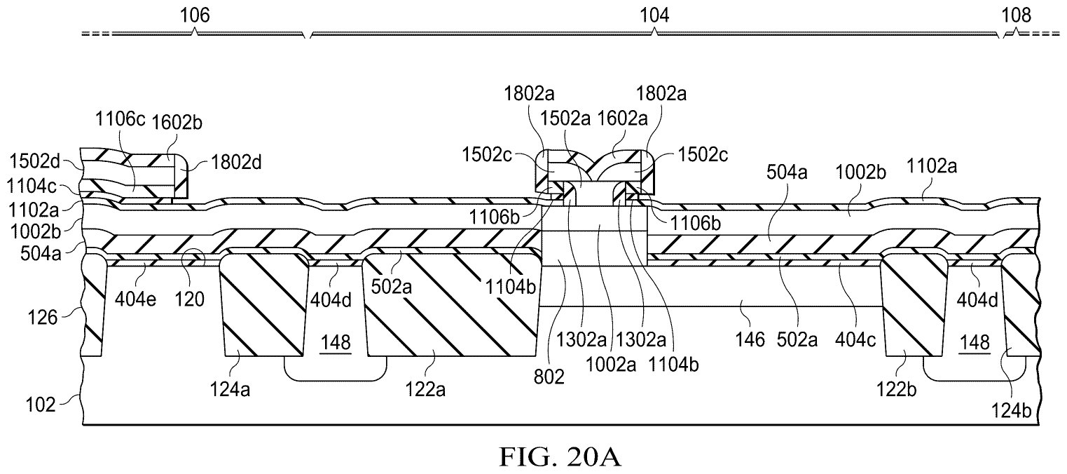

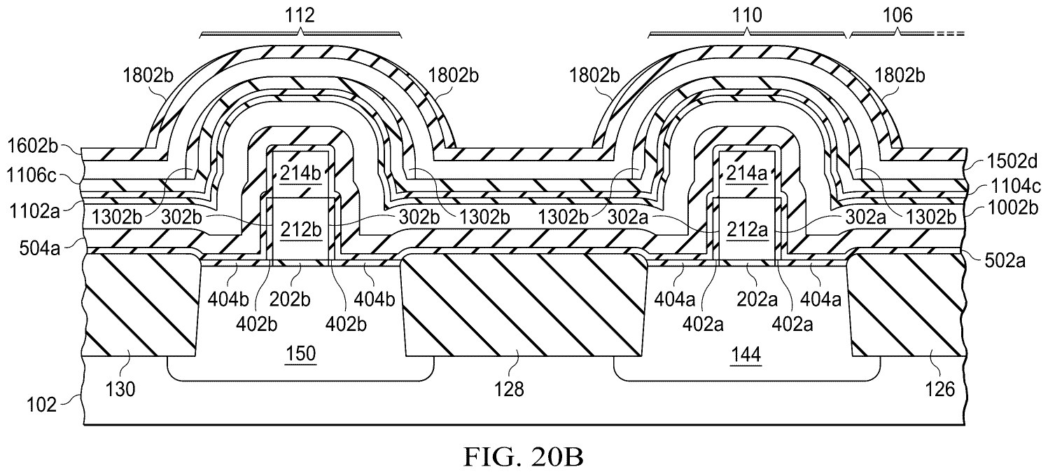

Referring to FIGS. 20A and 20B, the second dielectric spacer layer 1104a is etched. The etch removes exposed portions of the second dielectric spacer layer 1104a and undercuts the emitter dielectric protective spacers 1802a and third dielectric spacers 1106b laterally distal from the monocrystalline emitter layer 1502a, which results in second dielectric spacers 1104b under the third dielectric spacers 1106b. The etch may also undercut any of the residual dielectric spacer 1802b in the first transition region 106, which further forms residual second dielectric spacer layer 1104c. The etch may be a wet or dry etch selective to the material of the second dielectric spacer layer 1104a, which etch is also isotropic. For example, when the second dielectric spacer layer 1104a is silicon nitride, the etch process may be or include using phosphoric acid.

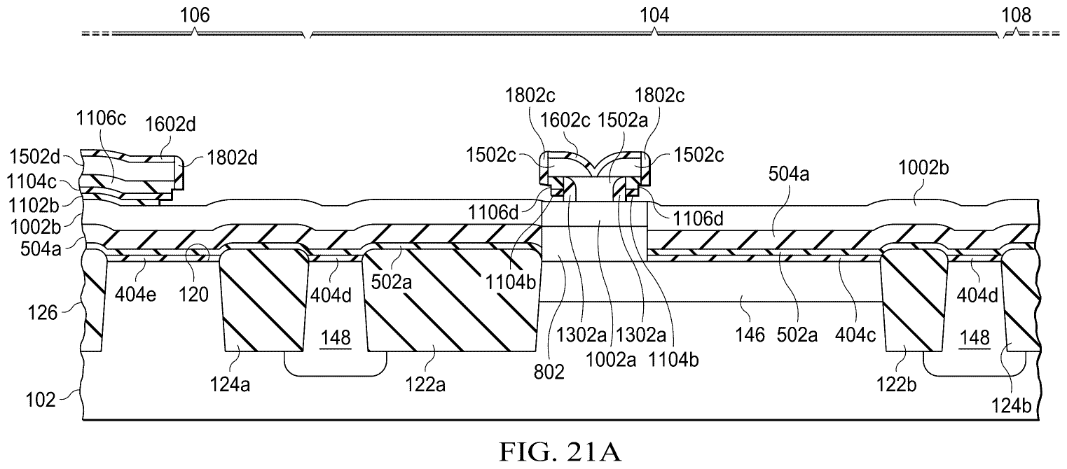

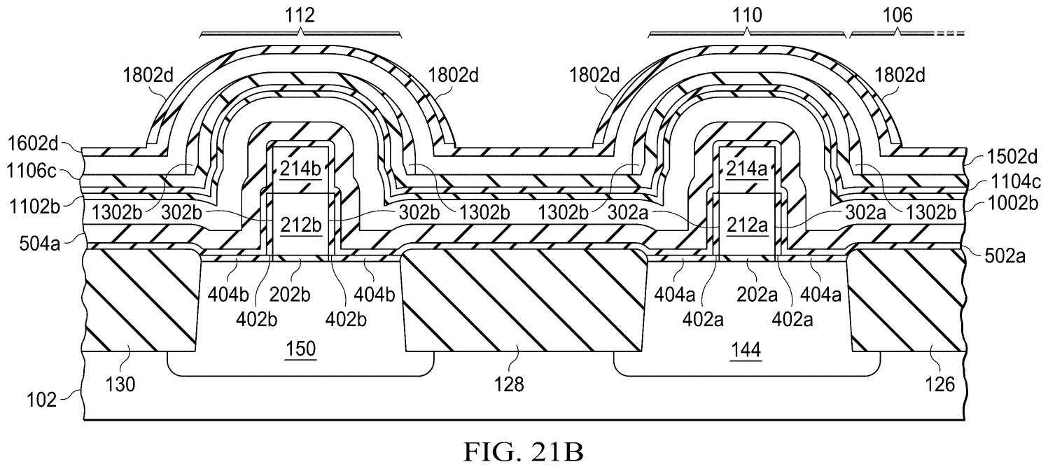

Referring to FIGS. 21A and 21B, the first dielectric spacer layer 1102a is etched. Etching the first dielectric spacer layer 1102a removes exposed portions of the first dielectric spacer layer 1102a, such as from the monocrystalline base layer 1002a. A residual first dielectric spacer layer 1102b, as illustrated, remains under the residual second dielectric spacer layer 1104c in the first transition region 106, the pFET region 110, and the nFET region 112. The etch may be a wet etch selective to the first dielectric spacer layer 1102a. For example, when the first dielectric spacer layer 1102a is silicon oxide, the first dielectric spacer layer 1102a may be etched using a dilute hydrochloric acid (dHCl) etch. A wet etch may remove the first dielectric spacer layer 1102a that underlies the emitter dielectric protective spacers 1802a and the second dielectric spacers 1104b. Additionally, in the BJT region 104, the wet etch may further etch the emitter dielectric cap layer 1602a, emitter dielectric protective spacers 1802a, and the third dielectric spacers 1106b, which reduces respective thicknesses of those layers and spacers and results in emitter dielectric cap layer 1602c, emitter dielectric protective spacers 1802c, and third dielectric spacers 1106d when those layers and spacers are a same material as the first dielectric spacer layer 1102a, such as illustrated. Additionally, in the first transition region 106, the pFET region 110, and the nFET region 112, the wet etch may further etch the residual dielectric spacers 1802b and the residual emitter dielectric cap layer 1602b, which reduces the spacers and layer resulting in residual dielectric spacers 1802d and a residual emitter dielectric cap spacer layer 1602d, when those spacers and layer are a same material as the first dielectric spacer layer 1102a, such as illustrated. The removal of the first dielectric spacer layer 1102a opens (e.g., exposes) an area on the base layer 1002 near the monocrystalline emitter layer 1502a on which a raised base layer may be formed.

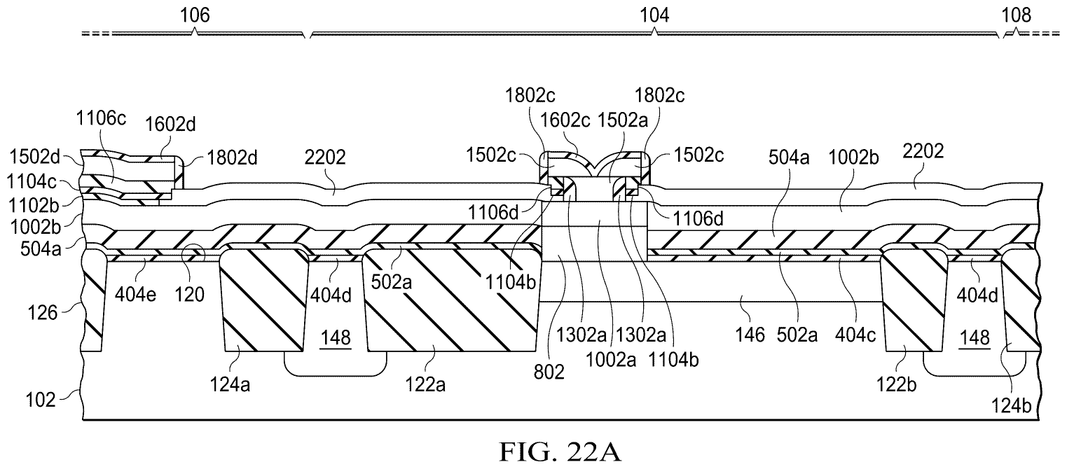

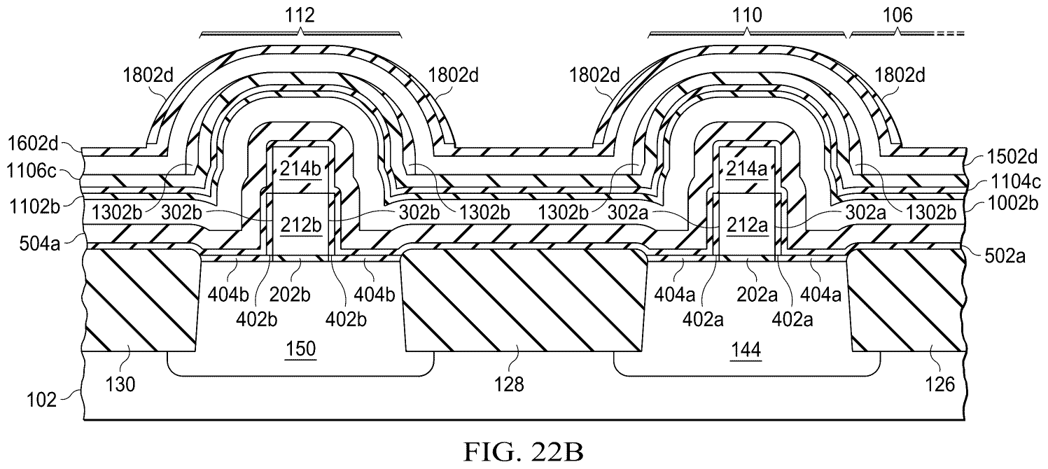

Referring to FIGS. 22A and 22B, a raised base layer 2202 is formed over the base layer 1002. The raised base layer 2202 includes at least a polycrystalline raised base layer on the polycrystalline base layer 1002b. The raised base layer 2202 may include a monocrystalline raised base layer. If the monocrystalline base layer 1002a is exposed by etching the first dielectric spacer layer 1102a, the raised base layer 2202 may include a monocrystalline portion on the monocrystalline base layer 1002a. In some examples, the raised base layer 2202 is or includes a semiconductor layer doped with a p-type dopant (e.g., a same dopant type as the base layer 1002). In some examples, the raised base layer 2202 is or includes silicon. In some examples, the raised base layer 2202 is doped with a p-type dopant with a concentration in a range from 1×10¹⁹ cm⁻³ to 1×10²¹ cm⁻³. The raised base layer 2202 may be epitaxially grown on the base layer 1002. The raised base layer 2202 may be epitaxially grown by a selective epitaxial growth process in some examples. The selective deposition of the raised base layer 2202 forms the raised base layer 2202 conformally on crystalline (e.g., polycrystalline and monocrystalline) surfaces, which include exposed portions of the base layer 1002 (e.g., the polycrystalline base layer 1002b). Further, the raised base layer 2202 may be in situ doped during the epitaxial growth process (e.g., the selective epitaxial growth process). The epitaxial growth process may be a CVD process, such as LPCVD, RPCVD, MOCVD, or the like. Other materials, dopant type, dopant concentration, and/or deposition process may be implemented.

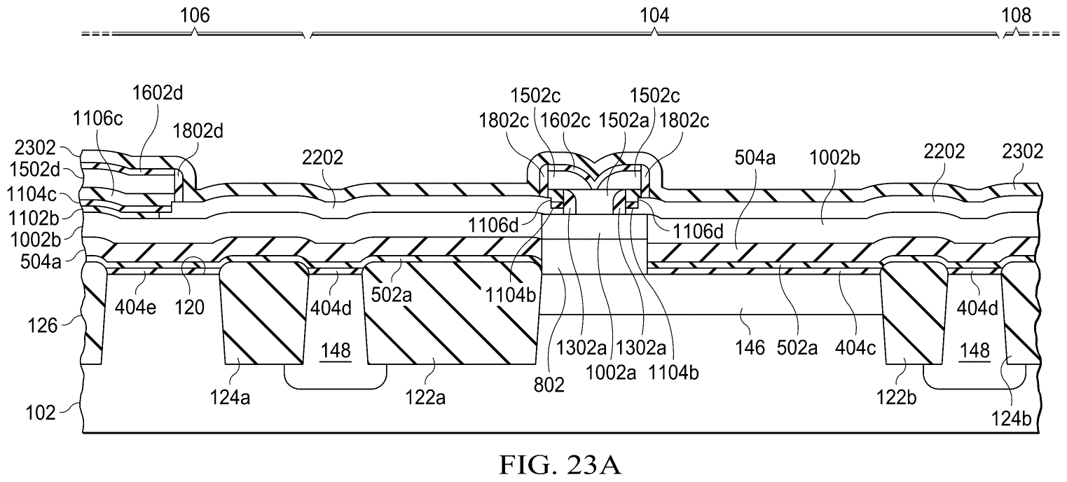

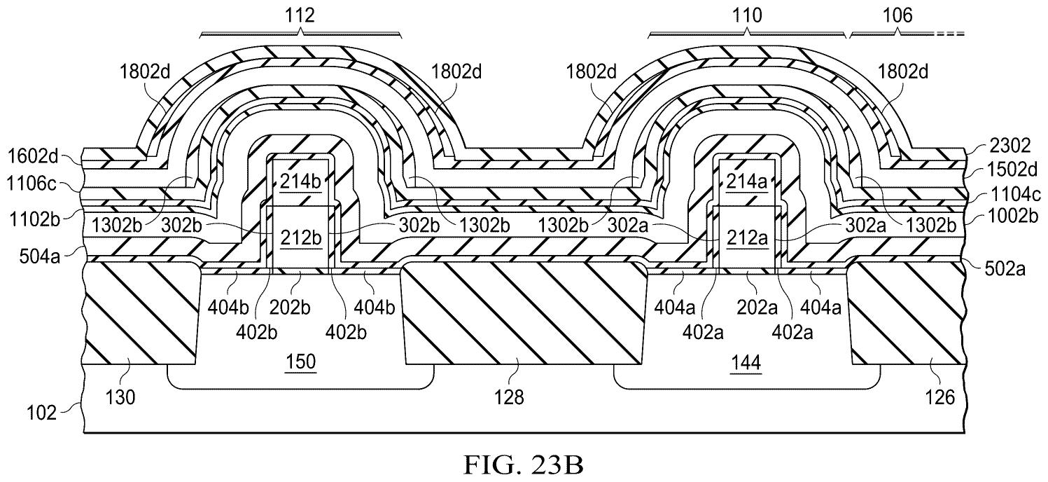

Referring to FIGS. 23A and 23B, a dielectric protective layer 2302 is conformally formed over and along the emitter dielectric cap layer 1602c, the emitter dielectric protective spacers 1802c, and the raised base layer 2202 in the BJT region 104. The dielectric protective layer 2302 is further conformally formed over and along the residual dielectric spacers 1802d and the residual emitter dielectric cap spacer layer 1602d in the first transition region 106, the pFET region 110, and the nFET region 112. In some examples, the dielectric protective layer 2302 is silicon oxide (e.g., a TEOS oxide) deposited by CVD, although other dielectric materials and/or other deposition processes may be used in other examples.

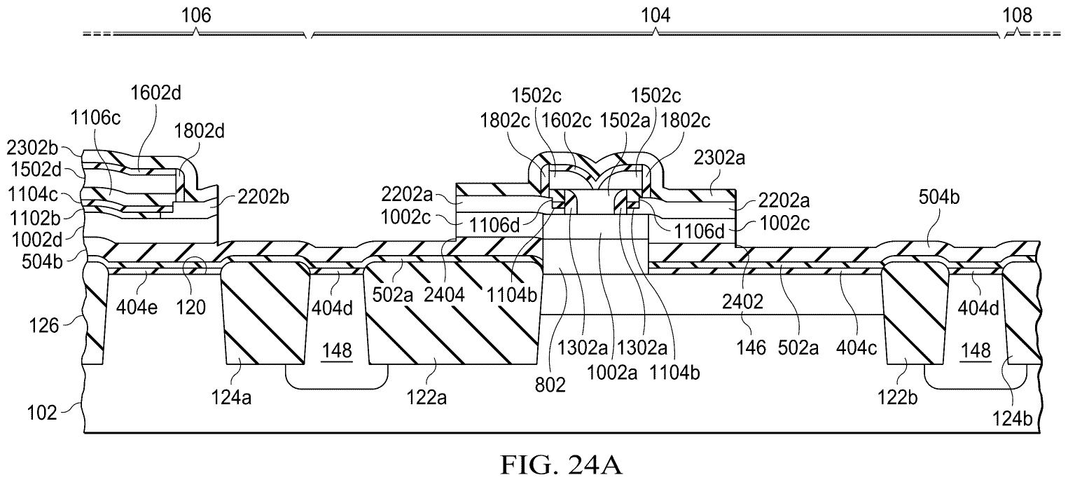

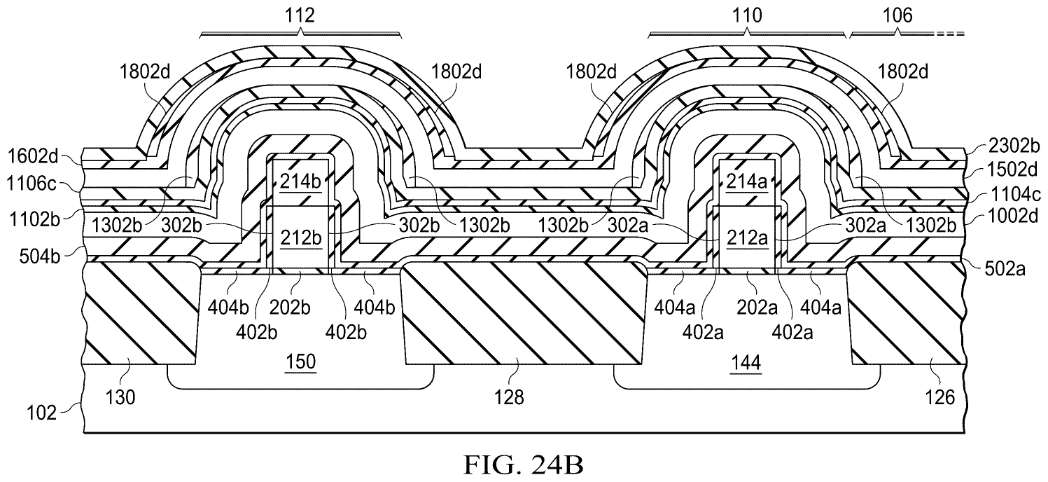

Referring to FIGS. 24A and 24B, the dielectric protective layer 2302, the raised base layer 2202, and the base layer 1002 (e.g., the polycrystalline base layer 1002b) are patterned, and portions of the pedestal dielectric layer 504a are thinned. The raised base layer 2202 and the polycrystalline base layer 1002b are patterned to remain as the raised base layer 2202a and polycrystalline base layer 1002c in the BJT region 104. The dielectric protective layer 2302 is patterned to remain as the dielectric protective layer 2302a over the raised base layer 2202a and the emitter dielectric cap layer 1602c and along sidewalls of the emitter dielectric protective spacers 1802c. The pedestal dielectric layer 504a is thinned in areas where the dielectric protective layer 2302, the raised base layer 2202, and the polycrystalline base layer 1002b are removed and results in the pedestal dielectric layer 504b. Thinning of the pedestal dielectric layer 504a results in sidewalls 2402, 2404 in the pedestal dielectric layer 504b that align with respective sidewalls of the polycrystalline base layer 1002c and, further, the raised base layer 2202a. The layers 2302, 2202, 1002b, 504a may be patterned using appropriate photolithography and etch (e.g., RIE) processes. As illustrated, etching the dielectric protective layer 2302 and the polycrystalline base layer 1002b results in the residual dielectric protective layer 2302b and the residual polycrystalline base layer 1002d remaining in the pFET region 110, the nFET region 112, and at least part of the first transition region 106. Further, etching the raised base layer 2202 may result in residual raised base layer 2202b remaining in the first transition region 106.

In subsequent processing for forming the nFET and the pFET, a lower thermal budget may be implemented. The lower thermal budget may mitigate against relaxation of the monocrystalline base layer 1002a when the monocrystalline base layer 1002a is a material dissimilar from the collector layer 802. The lower thermal budget may also mitigate against diffusion of dopants between the collector layer 802, base layer 1002, raised base layer 2202a, and/or emitter layer 1502. Examples of such thermal processing with a lower thermal budget are provided below.

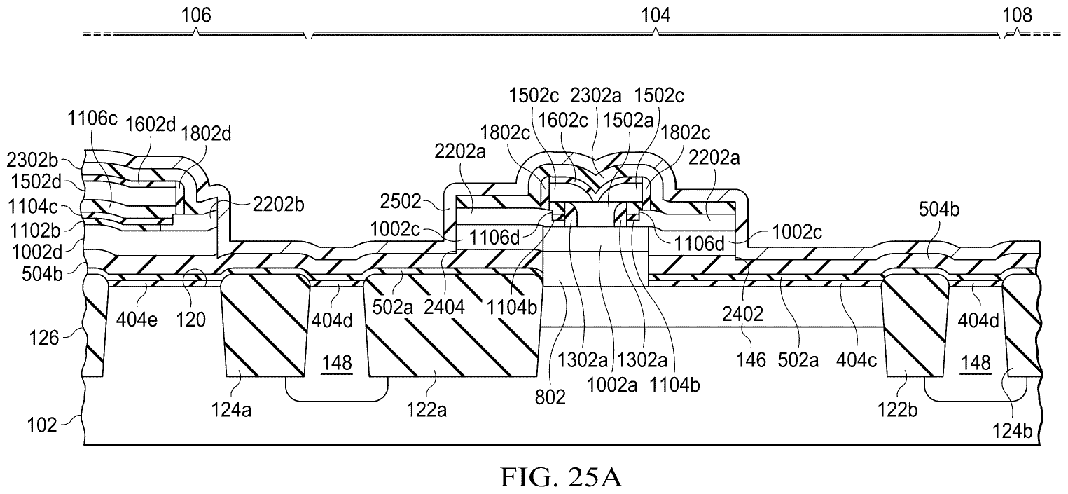

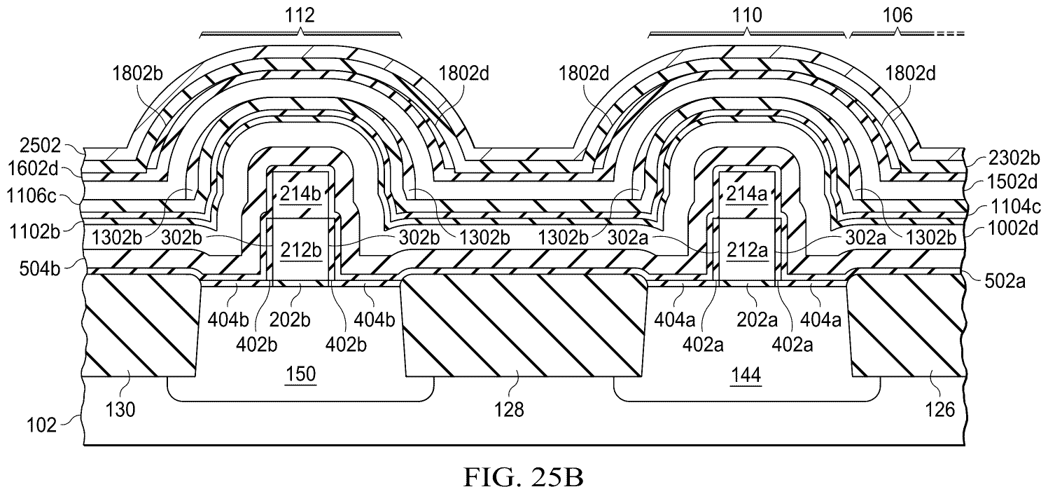

Referring to FIGS. 25A and 25B, a hardmask layer 2502 is conformally formed over the semiconductor substrate 102. More specifically, the hardmask layer 2502 is conformally formed over the pedestal dielectric layer 504b and the dielectric protective layer 2302a and along sidewalls of the polycrystalline base layer 1002c and raised base layer 2202a in the BJT region 104. The hardmask layer 2502 is conformally formed over the residual dielectric protective layer 2302b and the pedestal dielectric layer 504b in the first transition region 106, the pFET region 110, and the nFET region 112 and is along sidewalls of the residual polycrystalline base layer 1002d, residual raised base layer 2202b, and the residual dielectric protective layer 2302b in the first transition region 106. In some examples, the hardmask layer 2502 is or includes silicon nitride deposited by CVD, although other hardmask (e.g., dielectric) materials and/or other deposition processes may be used in other examples.

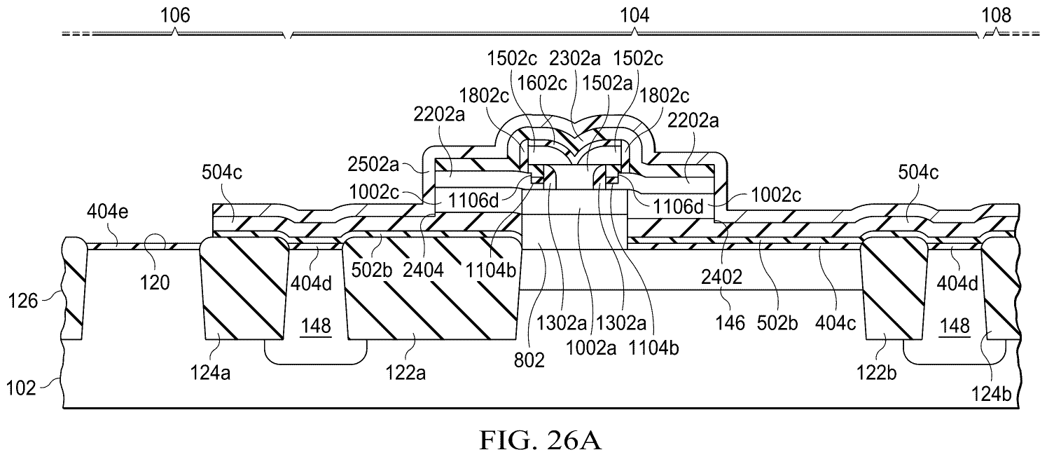

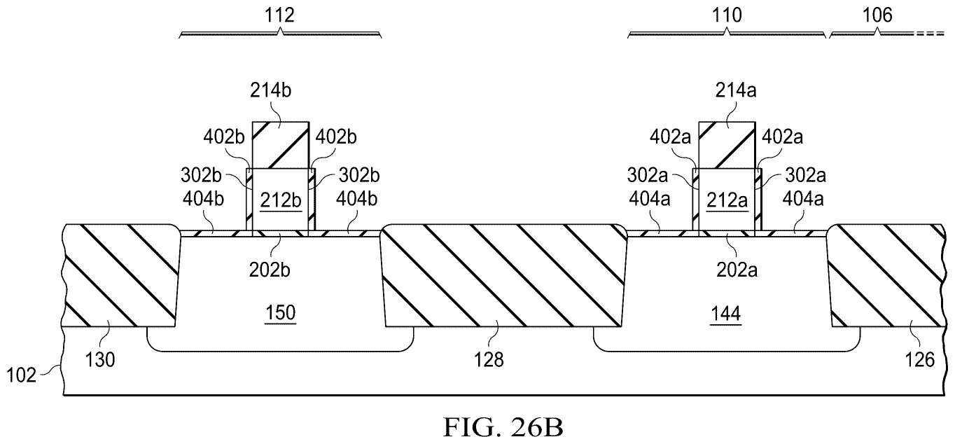

Referring to FIGS. 26A and 26B, the hardmask layer 2502, the residual layers 2302b, 1602d, 1502d, 1106c, 1104c, 1102b, 1002d, the residual dielectric spacers 1802d, 1302b, the pedestal dielectric layer 504b, and the etch stop layer 502a are removed from the pFET region 110 and the nFET region 112. Appropriate photolithography and etch processes may be used to remove these layers and spacers, and the etch process(es) may be or include a wet or dry etch, which may further be isotropic. The hardmask layer 2502, pedestal dielectric layer 504b, and etch stop layer 502a are patterned to remain in the BJT region 104 and extending at least partially into the transition regions 106, 108 as a hardmask layer 2502a, a pedestal dielectric layer 504c, and etch stop layer 502b, respectively. The presence of the etch stop layer 502a in the pFET region 110 and nFET region 112 permits increased selectivity for etch process(es) that remove the layers from the pFET region 110 and the nFET region 112, which may increase ease with which the layers may be removed.

Depending upon alignment of masks (e.g., photoresists between various photolithography processes), some residual portions of the layers in the first transition region 106 may remain. For example, some of the residual layers 2302b, 1602d, 1502d, 1106c, 1104c, 1102b, 1002d, 2202b may remain in the first transition region 106. The hardmask layer 2502, the residual layers 2302b, 1602d, 1502d, 1106c, 1104c, 1102b, 1002d, the residual dielectric spacers 1802d, 1302b, the pedestal dielectric layer 504b, and the etch stop layer 502a are removed from the lateral sides of the gate electrodes 212a, 212b in the pFET region 110 and nFET region 112 (e.g., removed from the reoxidation layers 402a, 402b on the sidewalls 302a, 302b).

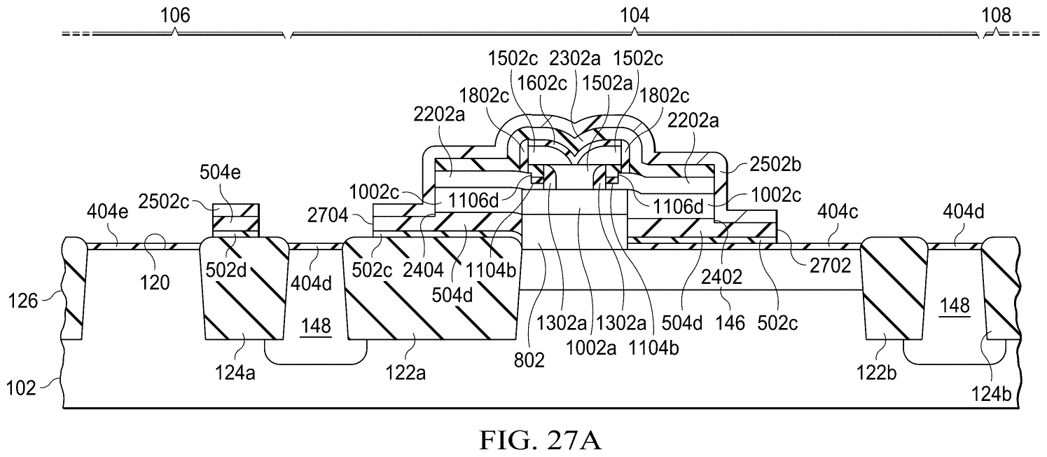

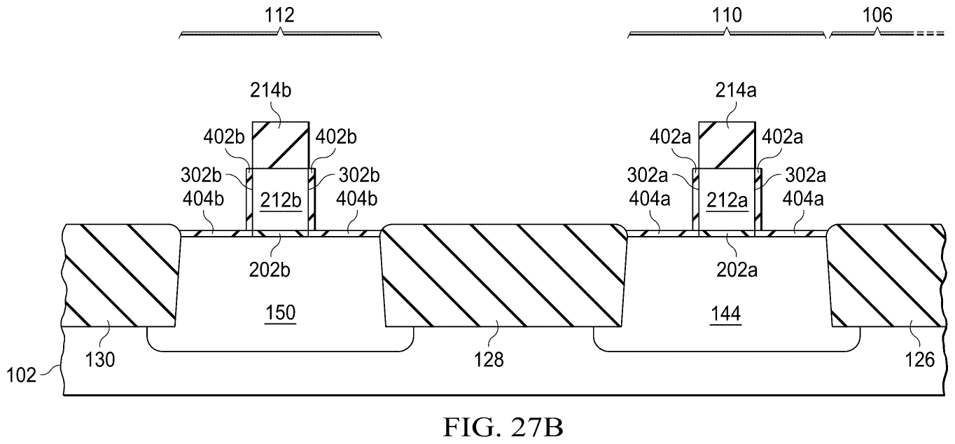

Referring to FIGS. 27A and 27B, the hardmask layer 2502a, the pedestal dielectric layer 504c, and the etch stop layer 502b are patterned into a hardmask layer 2502b, a pedestal dielectric layer 504d, and an etch stop layer 502c in the BJT region 104. The hardmask layer 2502b remains over the emitter layer 1502 (e.g., the polycrystalline emitter layer 1502c and the monocrystalline emitter layer 1502a), the base layer 1002 (e.g., the polycrystalline base layer 1002c and the monocrystalline base layer 1002a), the raised base layer 2202a, and the pedestal dielectric layer 504d. More specifically, the hardmask layer 2502b is over the dielectric protective layer 2302a and along sidewalls of the dielectric protective layer 2302a, the raised base layer 2202a and the polycrystalline base layer 1002c and the sidewalls 2402, 2404 of the pedestal dielectric layer 504d. The hardmask layer 2502b extends laterally away from the polycrystalline base layer 1002c and from the sidewalls 2402, 2404 of the pedestal dielectric layer 504d over the pedestal dielectric layer 504d in the BJT region 104. The pedestal dielectric layer 504d and the etch stop layer 502c are laterally coextensive with the hardmask layer 2502b. Patterning the pedestal dielectric layer 504c forms the pedestal dielectric layer 504d with sidewalls 2702, 2704, which are laterally away from respective sidewalls 2402, 2404 of the pedestal dielectric layer 504d. The sidewall 2702 of the pedestal dielectric layer 504d is over the upper surface 120 of the semiconductor substrate 102 and the n-type doped sub-collector diffusion region 146. The sidewall 2704 is over the first portion 122a of the isolation structure 122. Portions of the hardmask layer 2502a, the pedestal dielectric layer 504c, and the etch stop layer 502b are removed from over at least a portion of the n-type doped sub-collector diffusion region 146 and the p-type doped well 148. The hardmask layer 2502a, the pedestal dielectric layer 504c, and the etch stop layer 502b may be patterned using appropriate photolithography and etch (e.g., RIE) processes.

Depending upon alignment of masks (e.g., photoresists between various photolithography processes), residual portions of the hardmask layer 2502a, the pedestal dielectric layer 504c, and the etch stop layer 502b may remain in the first transition region 106, such as, as illustrated, a residual hardmask layer 2502c, a residual pedestal dielectric layer 504e, and a residual etch stop layer 502d. For example, a mask (e.g., a photoresist) may mask the first transition region 106 from where the residual hardmask layer 2502c remains extending into the pFET region 110 and the nFET region 112, and may mask where the hardmask layer 2502b remains in the BJT region 104 during an etch process.

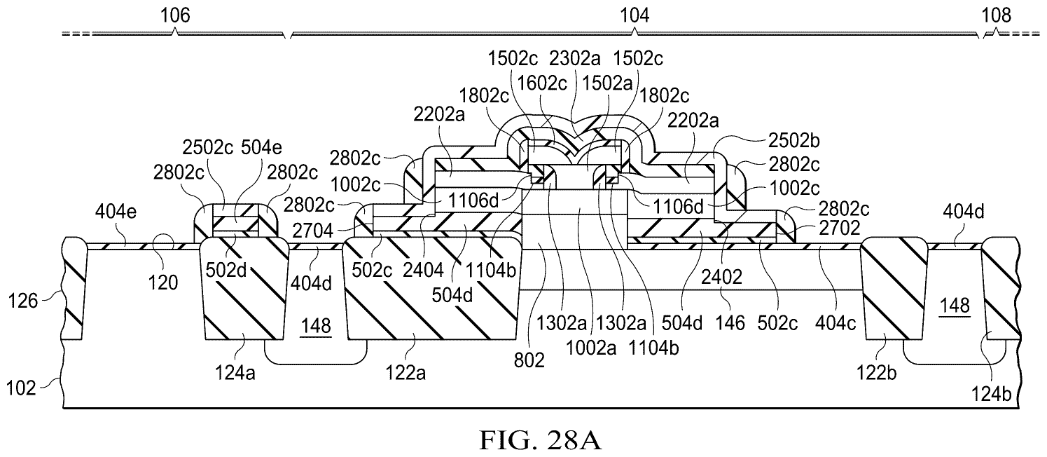

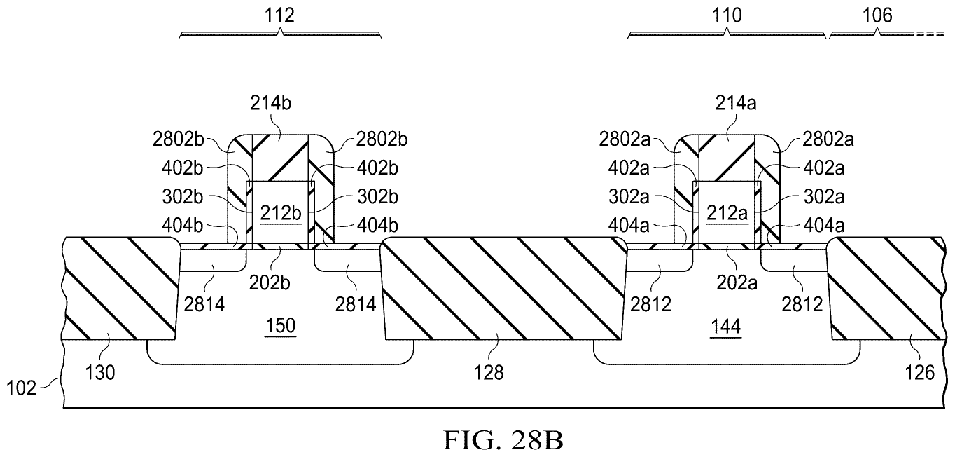

Referring to FIGS. 28A and 28B, first gate dielectric spacers 2802a, 2802b are formed along sidewalls 302a, 302b of the gate electrodes 212a, 212b (e.g., on the reoxidation layers 402a, 402b). The first gate dielectric spacers 2802a, 2802b may be formed by depositing a layer of the material of the first gate dielectric spacers 2802a, 2802b conformally over the semiconductor substrate 102 and anisotropically etching (e.g., by RIE) the layer such that the first gate dielectric spacers 2802a, 2802b remain. The material of the first gate dielectric spacers 2802a, 2802b may be any appropriate dielectric material, such as silicon nitride, silicon oxynitride, silicon carbon nitride, the like, or a combination thereof. The layer may be deposited by CVD, PECVD, atomic layer deposition (ALD), or the like. The formation of the first gate dielectric spacers 2802a, 2802b may further form residual dielectric spacers 2802c on vertical surfaces in the BJT region 104 and first transition region 106, such as vertical surfaces of the hardmask layers 2502b, 2502c, etc.

P-type lightly doped drain regions (LDDs) 2812 and n-type LDDs 2814 are formed in the semiconductor substrate 102 in the pFET region 110 and the nFET region 112, respectively-e.g., prior to forming the first gate dielectric spacers 2802a, 2802b in some examples. The p-type LDDs 2812 are in the semiconductor substrate 102 on laterally opposing sides of the gate electrode 212a, and the n-type LDDs 2814 are in the semiconductor substrate 102 on laterally opposing sides of the gate electrode 212b. The p-type LDDs 2812 may be formed by masking (e.g., by a photoresist using photolithography) the BJT region 104, transition regions 106, 108, and nFET region 112 and implanting a p-type dopant into the semiconductor substrate 102 in the pFET region 110. The n-type LDDs 2814 may be formed by masking (e.g., by a photoresist using photolithography) the BJT region 104, transition regions 106, 108, and pFET region 110 and implanting an n-type dopant into the semiconductor substrate 102 in the nFET region 112. A concentration of the p-type dopant of the p-type LDDs 2812 is greater than the concentration of the n-type dopant of the n-type doped well 144, and a concentration of the n-type dopant of the n-type LDDs 2814 is greater than the concentration of the p-type dopant of the p-type doped well 150. In some examples, the p-type LDDs 2812 are doped with a p-type dopant with a concentration in a range from 1×10¹⁹ cm⁻³ to 1×10²¹ cm⁻³, and the n-type LDDs 2814 are doped with an n-type dopant with a concentration in a range from 1×10¹⁹ cm⁻³ to 1×10²¹ cm⁻³. Other doping concentrations may be implemented.

After performing implantation(s) to form the p-type LDDs 2812 and the n-type LDDs 2814, an activation anneal may be performed. In some examples with a lower thermal budget, the activation anneal includes a laser anneal following the first implantation (e.g., of n-type or p-type dopants) and a spike anneal reaching 930° C. or less following the second implantation (e.g., of the other of the n-type or p-type dopants).

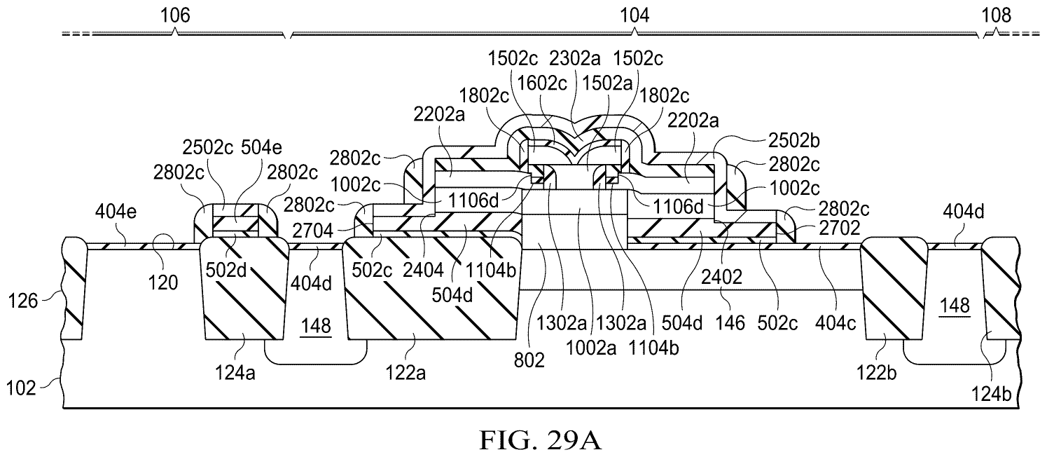

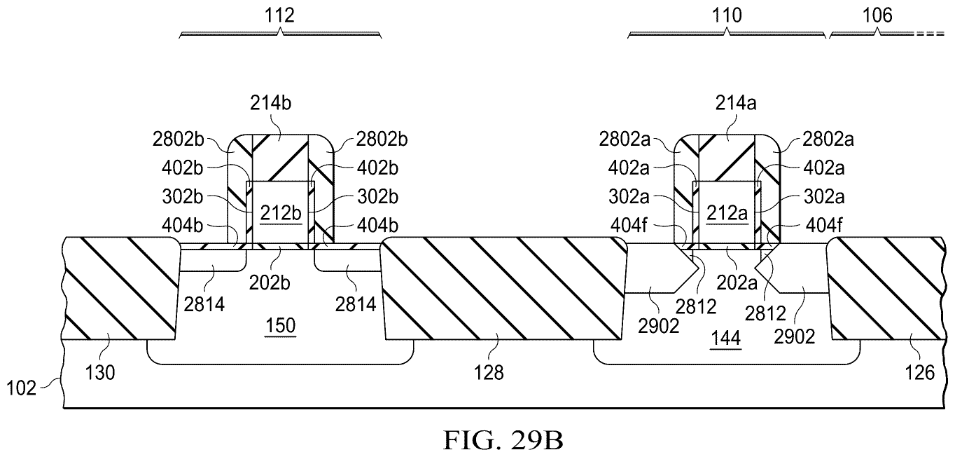

Referring to FIGS. 29A and 29B, embedded stressors 2902 are formed in the semiconductor substrate 102 in the pFET region 110. To form the embedded stressors 2902, respective recesses are formed in the semiconductor substrate 102. To form the recesses, a conformal hardmask layer (not illustrated) is formed over the semiconductor substrate 102 in the BJT region 104, transition regions 106, 108, and nFET region 112. The conformal hardmask layer may be or include silicon nitride, silicon oxynitride, the like, or a combination thereof. The conformal hardmask layer may be formed by conformally depositing and patterning the conformal hardmask layer. The conformal hardmask layer may be deposited by CVD, PECVD, ALD, or the like. The conformal hardmask layer may be patterned using photolithography and etching (e.g., RIE) processes. Then, stressor recesses are formed in the semiconductor substrate 102 in the pFET region 110. The stressor recesses are etched in the semiconductor substrate 102 where the embedded stressors are to be formed, which may pattern the reoxidation layers 404a into reoxidation layers 404f underlying respective first gate dielectric spacers 2802a. The stressor recesses may be formed using any appropriate etch process, which may be a wet or dry etch process. The etch process may be anisotropic and selective to (e.g., etching preferentially) a crystalline plane of the semiconductor substrate 102. The embedded stressors 2902 are then formed in the stressor recesses. The embedded stressors 2902 may be formed using a selective epitaxial growth process. The embedded stressors 2902 may be formed using MOCVD, molecular beam epitaxy (MBE), LPCVD, or another epitaxy process. In some examples, the embedded stressors 2902 are a semiconductor material that causes a compressive stress in the channel region in the semiconductor substrate 102 under the gate electrode 212a. For example, when the semiconductor substrate 102 is silicon, the embedded stressors 2902 may be or include silicon germanium.

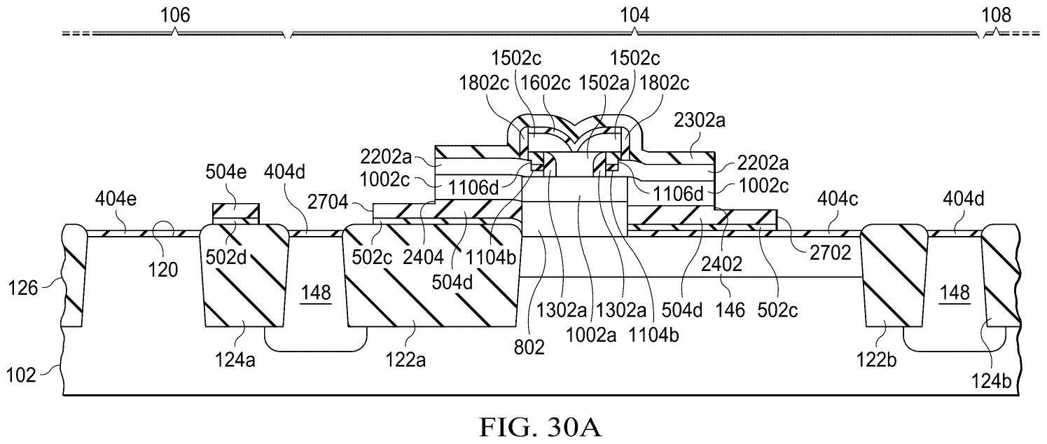

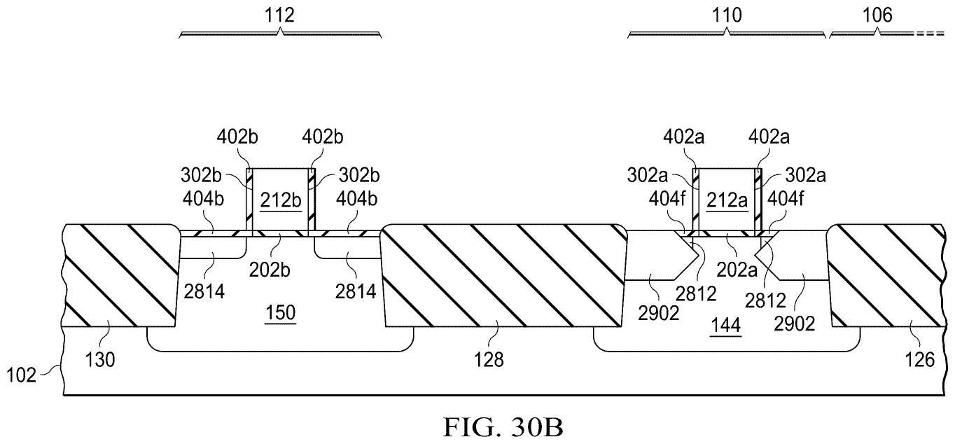

Referring to FIGS. 30A and 30B, the conformal hardmask layer for forming the embedded stressors 2902, the dielectric spacers 2802a, 2802b, 2802c, and the hardmask layers 214a, 214b, 2502b, 2502c are removed. These layers and spacers may be removed by an etch process selective to the material of the respective layers and spacers, which may be wet or dry etch processes and may be isotropic. As an example, when the conformal hardmask layer, the dielectric spacers 2802a, 2802b, 2802c, and the hardmask layers 214a, 214b, 2502b, 2502c are silicon nitride, a wet etch process including phosphoric acid may be implemented.

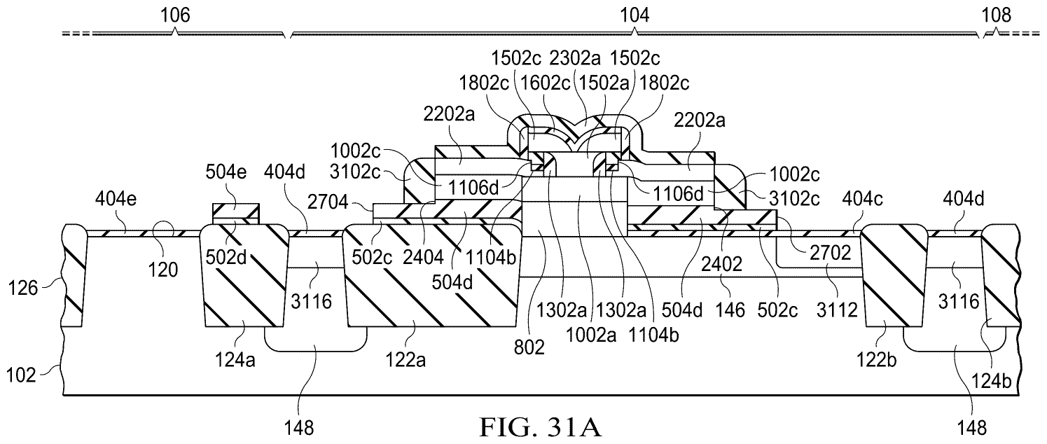

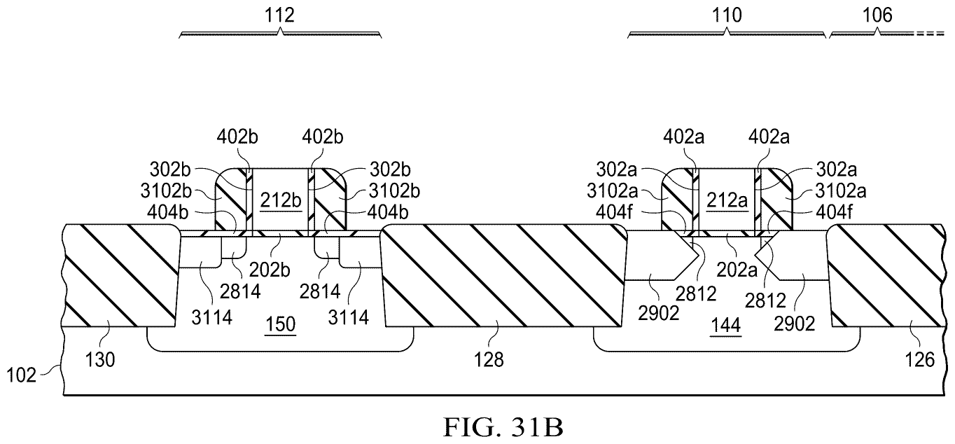

Referring to FIGS. 31A and 31B, second gate dielectric spacers 3102a, 3102b are formed along the sidewalls 302a, 302b of the gate electrodes 212a, 212b, respectively. The second gate dielectric spacers 3102a, 3102b may be formed by depositing a layer of the material of the second gate dielectric spacers 3102a, 3102b conformally over the semiconductor substrate 102 and anisotropically etching (e.g., by RIE) the layer such that the second gate dielectric spacers 3102a, 3102b remain. The material of the second gate dielectric spacers 3102a, 3102b may be any appropriate dielectric material, such as silicon nitride, silicon oxynitride, silicon carbon nitride, the like, or a combination thereof. The layer may be deposited by CVD, PECVD, ALD, or the like. The formation of the second gate dielectric spacers 3102a, 3102b may further form residual dielectric spacers (e.g., residual dielectric spacers 3102c) on sidewalls of components in the BJT region 104 and/or the first transition region 106.

The etch process for forming the second gate dielectric spacers 3102a, 3102b may include a cleaning process following, e.g., the anisotropic etch. Although not illustrated, the cleaning process may include an etchant that reduces or removes the dielectric protective layer 2302a, the emitter dielectric cap layer 1602c, and exposed portions of the pedestal dielectric layer 504d and the reoxidation layers 404b, 404c, 404d, 404e. For example, when the dielectric protective layer 2302a, the emitter dielectric cap layer 1602c, the pedestal dielectric layer 504d, and the reoxidation layers 404b, 404c, 404d, 404e are silicon oxide, the cleaning process may include hydrofluoric acid that reduces or removes the dielectric protective layer 2302a, the emitter dielectric cap layer 1602c, and exposed portions of the pedestal dielectric layer 504d and the reoxidation layers 404b, 404c, 404d, 404e. In some examples, the emitter dielectric protective spacers 1802c may also be reduced or removed or reduced by the cleaning process.

A stress memorization technique may be implemented, such as in the nFET region 112. A stressor dielectric layer is formed over the semiconductor substrate 102, gate electrode 212b, and second gate dielectric spacers 3102b in the nFET region 112. The stressor dielectric layer may be or include silicon nitride, the like, or a combination thereof. The stressor dielectric layer may be formed by conformally depositing and patterning the stressor dielectric layer. The stressor dielectric layer may be deposited by CVD, PECVD, ALD, or the like. The stressor dielectric layer may be patterned using photolithography and etching processes. An anneal process is performed with the stressor dielectric layer in the nFET region 112. The anneal process may be or include a millisecond laser anneal for dopant activation and a spike rapid thermal anneal (RTA) with reduced thermal budget. A spike RTA may be at peak temperature for approximately 1 second and rapidly decrease in temperature to minimize dopant diffusion. The anneal process permits the lattice structure of the semiconductor substrate 102 to conform due to the stress induced by the stressor dielectric layer. After the anneal process, the stressor dielectric layer is removed. The stressor dielectric layer may be removed by an etch process selective to the material of the stressor dielectric layer, which may be a wet or dry etch process.

An n-type collector contact region 3112, n-type source/drain (NSD) regions 3114, p-type source/drain (PSD) regions, and a p-type guardring contact region 3116 are formed in the semiconductor substrate 102. The n-type collector contact region 3112 is formed in the BJT region 104 in the n-type doped sub-collector diffusion region 146 in the semiconductor substrate 102. The n-type collector contact region 3112 is laterally between the pedestal dielectric layer 504d and the second portion 122b of the isolation structure 122. The NSD regions 3114 are formed in the nFET region 112 in the p-type doped well 150 in the semiconductor substrate 102. The NSD regions 3114 are on opposing lateral sides of the gate electrode 212b with the n-type LDDs 2814 therebetween. The PSD regions are formed in the pFET region 110 and may be formed in the embedded stressors 2902 and/or may further extend below the embedded stressors 2902 into the n-type doped well 144 in the semiconductor substrate 102. The PSD regions are on opposing lateral sides of the gate electrode 212a with the p-type LDDs 2812 therebetween. The p-type guardring contact region 3116 is formed in the BJT region 104 in the p-type doped well 148 in the semiconductor substrate 102. The p-type guardring contact region 3116 is laterally between the isolation structures 122, 124.

An implantation is performed to form the n-type collector contact region 3112 and the NSD regions 3114. The n-type collector contact region 3112 and the NSD regions 3114 may be formed by masking (e.g., by a photoresist using photolithography) the pFET region 110 and the base layer 1002, raised base layer 2202a, and emitter layer 1502 in the BJT region 104 and implanting an n-type dopant into the semiconductor substrate 102 in the nFET region 112 and exposed portion of the BJT region 104. An implantation is performed to form the PSD regions and the p-type guardring contact region 3116. The PSD regions and the p-type guardring contact region 3116 may be formed by masking (e.g., by a photoresist using photolithography) the BJT region 104, except the p-type doped well 148, and the nFET region 112 and implanting a p-type dopant into the semiconductor substrate 102 in the pFET region 110 and in the p-type doped well 148. Simultaneously with implanting the PSD regions and the p-type guardring contact region 3116, the raised base layer 2202a and/or base layer 1002 may be implanted. An area of the raised base layer 2202a may be exposed by the mask during the implantation of the PSD regions and the p-type guardring contact region 3116 to also implant p-type dopant into the raised base layer 2202a and/or base layer 1002.

A concentration of the n-type dopant of the n-type collector contact region 3112 is greater than the concentration of the n-type dopant of the n-type doped sub-collector diffusion region 146. A concentration of the n-type dopant of the NSD regions 3114 is greater than the concentration of the n-type dopant of the n-type LDDs 2814 and the concentration of the p-type dopant of the p-type doped well 150. A concentration of the p-type dopant of the PSD regions is greater than the concentration of the p-type dopant of the p-type LDDs 2812 and the concentration of the n-type dopant of the n-type doped well 144. A concentration of the p-type guardring contact region 3116 is greater than the concentration of the p-type dopant of the p-type doped well 148. In some examples, the n-type collector contact region 3112 and the NSD regions 3114 are doped with an n-type dopant with a concentration in a range from 1×10²⁰ cm⁻³ to 1×10²¹ cm⁻³, and the PSD regions and the p-type guardring contact region 3116 are doped with a p-type dopant with a concentration in a range from 1×10²⁰ cm⁻³ to 1×10²¹ cm⁻³. Other doping concentrations may be implemented.

After performing the implantations to form the n-type collector contact region 3112, NSD regions 3114, PSD regions, and p-type guardring contact region 3116, an activation anneal may be performed. In some examples with a lower thermal budget, the activation anneal includes a laser anneal following the first implantation (e.g., of n-type or p-type dopants) and a spike anneal reaching 1,010° C. or less following the second implantation (e.g., of the other of the n-type or p-type dopants).

Referring to FIGS. 32A and 32B, metal-semiconductor compound 3202, 3204, 3206, 3208, 3210, 3212, 3214, 3216, 3218 are formed. The metal-semiconductor compound 3202 is on the emitter layer 1502 (e.g., the polycrystalline emitter layer 1502c and/or monocrystalline emitter layer 1502a). The metal-semiconductor compound 3204 is on the raised base layer 2202a. The metal-semiconductor compound 3206 is on the upper surface 120 of the semiconductor substrate 102 at the n-type collector contact region 3112. The metal-semiconductor compound 3208 is on the upper surface 120 of the semiconductor substrate 102 at the p-type guardring contact region 3116. The metal-semiconductor compound 3210 is on any exposed portion of the upper surface 120 of the semiconductor substrate 102 in the first transition region 106. The metal-semiconductor compound 3212 are on the embedded stressors 2902. The metal-semiconductor compound 3214 are on the NSD regions 3114 in the semiconductor substrate 102. The metal-semiconductor compound 3216, 3218 are on the gate electrodes 212a, 212b, respectively. The metal-semiconductor compound 3202-3218 may be a silicide (e.g., NiSix, TiSix, CoSix, PtSix), a germanicide, or the like.

To form the metal-semiconductor compound 3202-3218, any remaining dielectric material on surfaces on which the metal-semiconductor compound 3202-3218 are to be formed is removed. For example, if any of the dielectric protective layer 2302a, the emitter dielectric cap layer 1602c, and exposed portions of the reoxidation layers 404b, 404c, 404d, 404e remain after forming the second gate dielectric spacers 3102a, 3102b, those layers, or exposed portions thereof, may be removed by an etch and/or cleaning process. For example, when the layers 2302a, 1602c, 404b, 404c, 404d, 404e are silicon oxide, dilute hydrochloric acid (dHCl) may be used. The portion of the reoxidation layer 404c not underlying the etch stop layer 502c is removed, which patterns the reoxidation layer 404g under the etch stop layer 502c. Other layers and/or spacers may be reduced by the etch and/or cleaning process. For example, the emitter dielectric protective spacers 1802c may be reduced, such as to emitter dielectric protective spacers 1802e, and exposed portions of the pedestal dielectric layers 504d, 504e are thinned to form the pedestal dielectric layer 504f and residual pedestal dielectric layer 504g. More specifically, the exposed portions of the pedestal dielectric layer 504d between the sidewalls 2402, 2702 and between the sidewalls 2404, 2704 are thinned.

The metal-semiconductor compound 3202-3218 may then be formed by depositing a metal (e.g., Ni, Ti, Co, Pt) over the semiconductor substrate 102, such as by physical vapor deposition (PVD), CVD, or the like. The metal is reacted with a semiconductor material, such as the semiconductor material of the emitter layer 1502 (e.g., polycrystalline emitter layer 1502c and/or monocrystalline emitter layer 1502a), the semiconductor material of the raised base layer 2202a, the semiconductor material of the semiconductor substrate 102, the semiconductor material of the embedded stressors 2902, and the semiconductor material (e.g., silicon, such as polysilicon) of the gate electrodes 212a, 212b. An anneal process may be used to cause the metal to react with a semiconductor material. For example, a laser anneal (e.g., a millisecond laser anneal) may be used in a reduced thermal budget implementation. Any unreacted metal may be removed, such as by an etch selective to the metal.

After forming the metal-semiconductor compound 3202-3218, in some examples, the second gate dielectric spacers 3102a, 3102b and the residual dielectric spacers 3102c are removed. An appropriate etch process, such as a wet or dry etch and/or isotropic etch, may be implemented to remove the second gate dielectric spacers 3102a, 3102b and the residual dielectric spacers 3102c. Further, the removal of the second gate dielectric spacers 3102a, 3102b and the residual dielectric spacers 3102c may implement a cleaning process that removes any remaining reoxidation layers 402a, 402b, 404b, 404f that were underlying the second gate dielectric spacers 3102a, 3102b. In some examples, removal of the second gate dielectric spacers 3102a, 3102b and the residual dielectric spacers 3102c may be omitted, and hence, removal of remaining reoxidation layers 402a, 402b, 404b, 404f may be omitted. Further, in some examples, the second gate dielectric spacers 3102a, 3102b may remain, while the residual dielectric spacers 3102c are removed. In such cases, masking (e.g., by a photoresist) may permit removal of the residual dielectric spacers 3102c while the second gate dielectric spacers 3102a, 3102b (and correspondingly, the reoxidation layers 402a, 402b, 404b, 404f) remain.

A dielectric layer 3222 is formed over the semiconductor substrate 102, and contacts 3232, 3234, 3236, 3242, 3244 are formed through the dielectric layer 3222. The dielectric layer 3222 may include one or more dielectric sub-layers. For example, the dielectric layer 3222 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 3222 may be or include a pre-metal dielectric (PMD), an inter-layer dielectric (ILD), or the like. The dielectric layer 3222 may be deposited using CVD, PECVD, ALD, or the like. The dielectric layer 3222 may be planarized, such as by a CMP.

The contacts 3232, 3234, 3236, 3242, 3244 extend through the dielectric layer 3222 and contact respective metal-semiconductor compound 3202, 3204, 3206, 3212, 3214. The contacts 3232, 3234, 3236, 3242, 3244 may each include one or more barrier and/or adhesion layers (e.g., titanium nitride (TiN), tantalum nitride (TaN), the like, or a combination thereof) conformally in a respective opening through the dielectric layer 3222, and a fill metal (e.g., tungsten (W), copper (Cu), aluminum (Al), the like, or a combination thereof) over and/or on the barrier and/or adhesion layer(s).

To form the contacts 3232, 3234, 3236, 3242, 3244, respective openings may be formed through the dielectric layer 3222 to the metal-semiconductor compound 3202, 3204, 3206, 3212, 3214 using appropriate photolithography and etching processes. A metal(s) of the contacts 3232, 3234, 3236, 3242, 3244 are deposited in the openings through the dielectric layer 3222. The metal(s) may be deposited using an appropriate deposition process(es), such as CVD, PVD, or the like. Any excess metal(s) may be removed, such as by a CMP and/or by patterning using photolithography and etch processes.

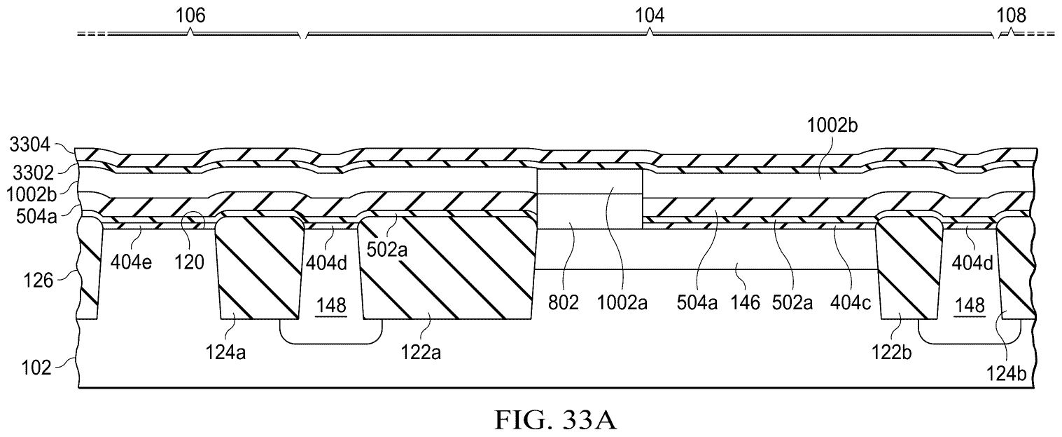

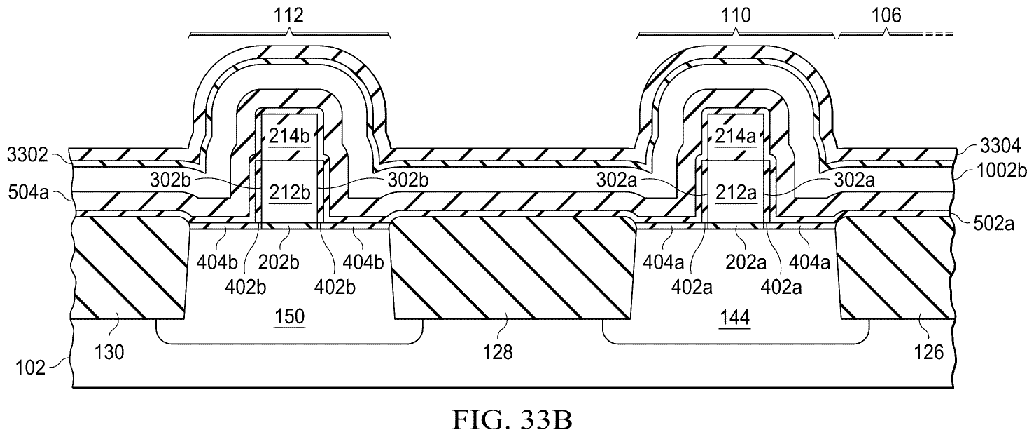

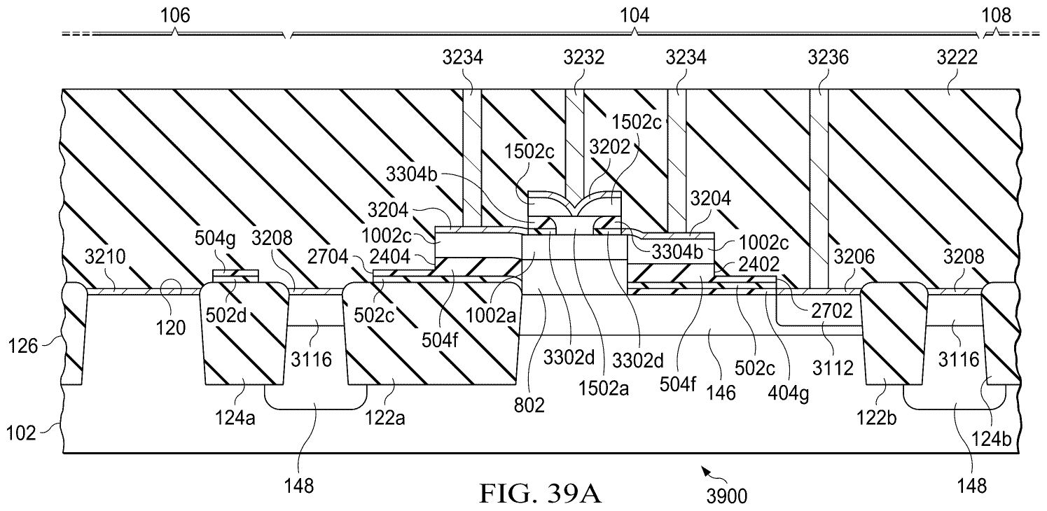

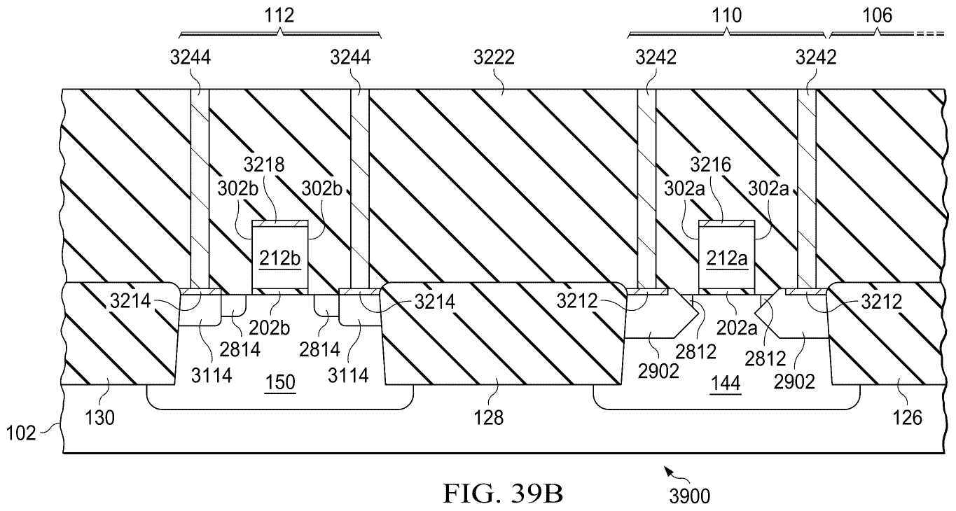

FIGS. 33A and 33B through FIGS. 39A and 39B are respective cross-sectional views of a semiconductor device in intermediate stages of manufacturing according to some examples. The method illustrated in these figures forms the semiconductor device 3900 of FIGS. 39A and 39B. Processing proceeds as described above with respect to FIGS. 1A and 1B through FIGS. 10A and 10B.

With reference to FIGS. 33A and 33B, a first dielectric spacer layer 3302 is formed conformally over the base layer 1002, and a second dielectric spacer layer 3304 is formed conformally over the first dielectric spacer layer 3302. In some examples, the second dielectric spacer layer 3304 is a dielectric material different from the dielectric material of the first dielectric spacer layer 3302. In some examples, the first dielectric spacer layer 3302 is silicon oxide (e.g., a TEOS oxide), and the second dielectric spacer layer 3304 is silicon nitride. The dielectric spacer layers 3302, 3304 may be deposited by CVD. Other dielectric materials and/or other deposition processes may be used in other examples.

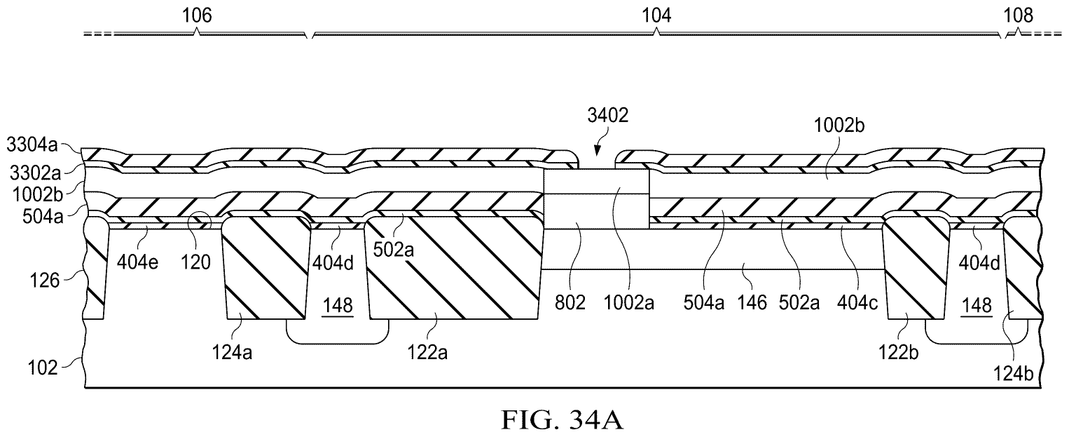

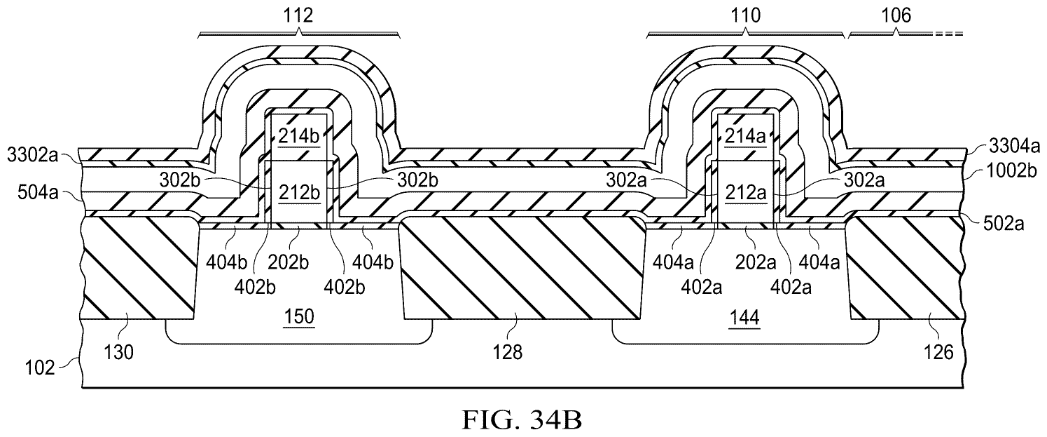

Referring to FIGS. 34A and 34B, the dielectric spacer layers 3302, 3304 are etched to form an emitter opening 3402 through the first dielectric spacer layer 3302a and the second dielectric spacer layer 3304a. The monocrystalline base layer 1002a (of the base layer 1002) is exposed through the emitter opening 3402. The emitter opening 3402 is in the BJT region 104. The dielectric spacer layers 3302, 3304 may be patterned using appropriate photolithography and etch (e.g., RIE) processes.

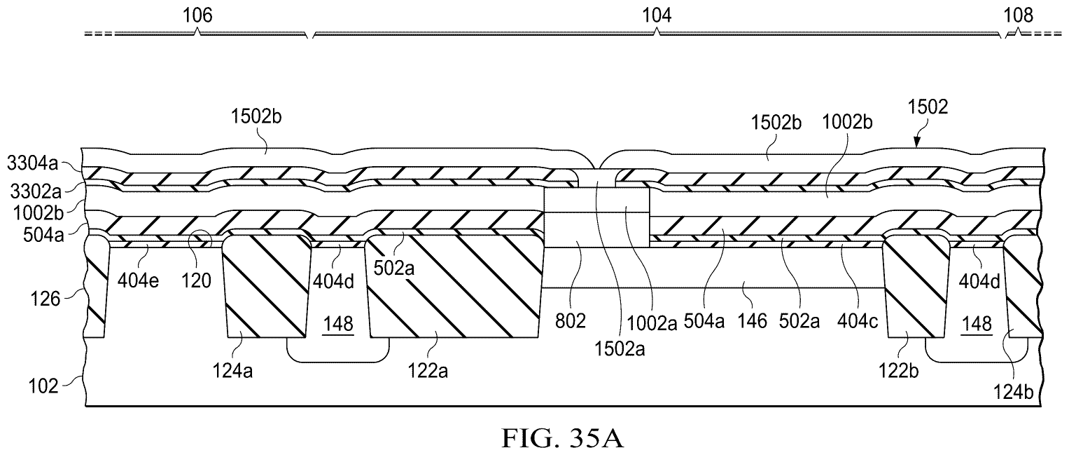

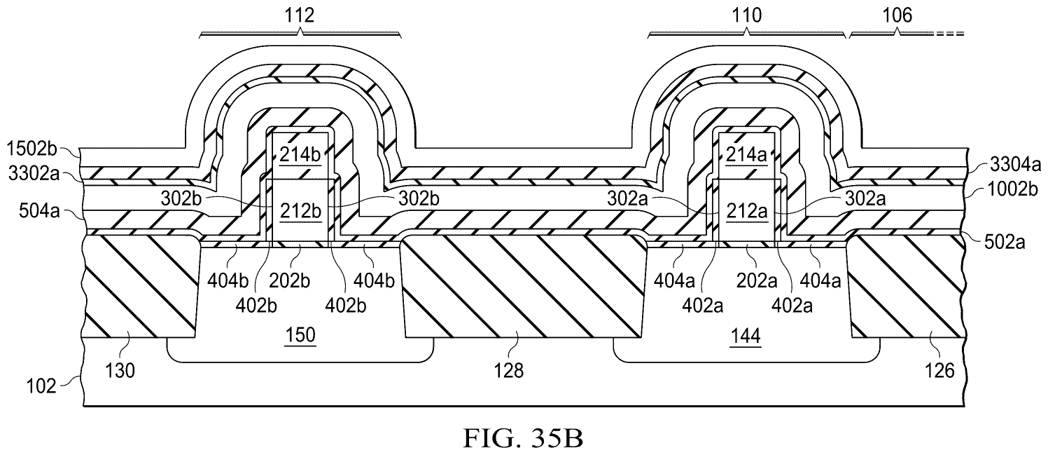

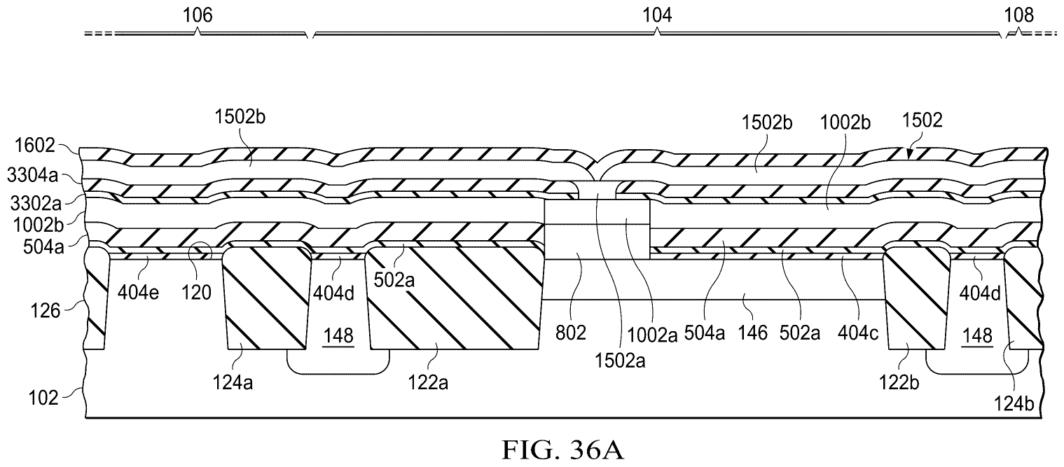

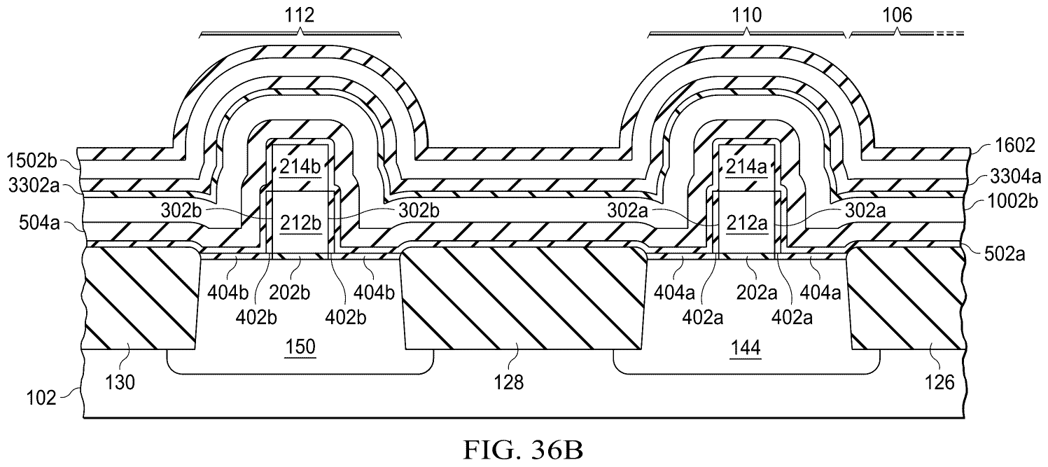

Referring to FIGS. 35A and 35B, an emitter layer 1502 is formed over the base layer 1002 (e.g., on the monocrystalline base layer 1002a) like described with respect to FIGS. 15A and 15B. The emitter layer 1502 may be epitaxially grown on the base layer 1002 (e.g., the monocrystalline base layer 1002a) exposed through the emitter opening 3402 and on the second dielectric spacer layer 3304a. Referring to FIGS. 36A and 36B, an emitter dielectric cap layer 1602 is conformally formed over the emitter layer 1502 like described with respect to FIGS. 16A and 16B.

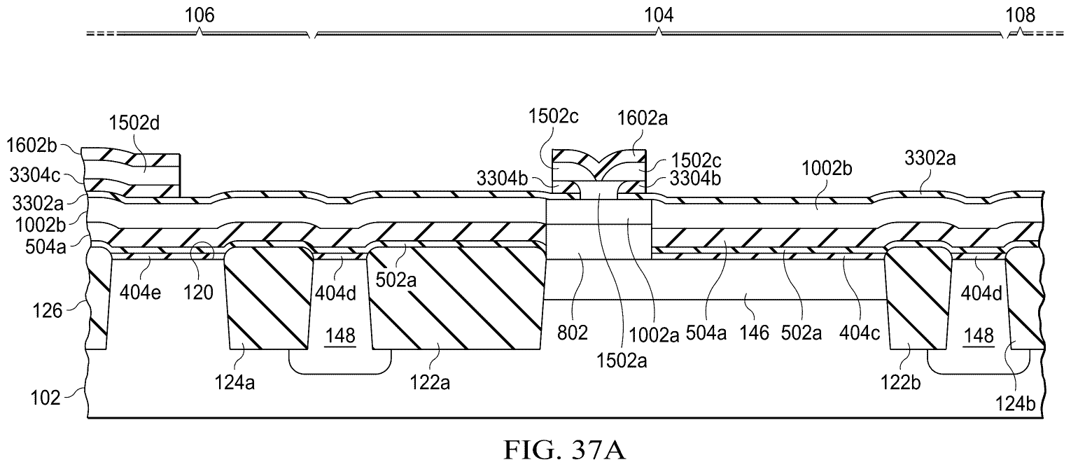

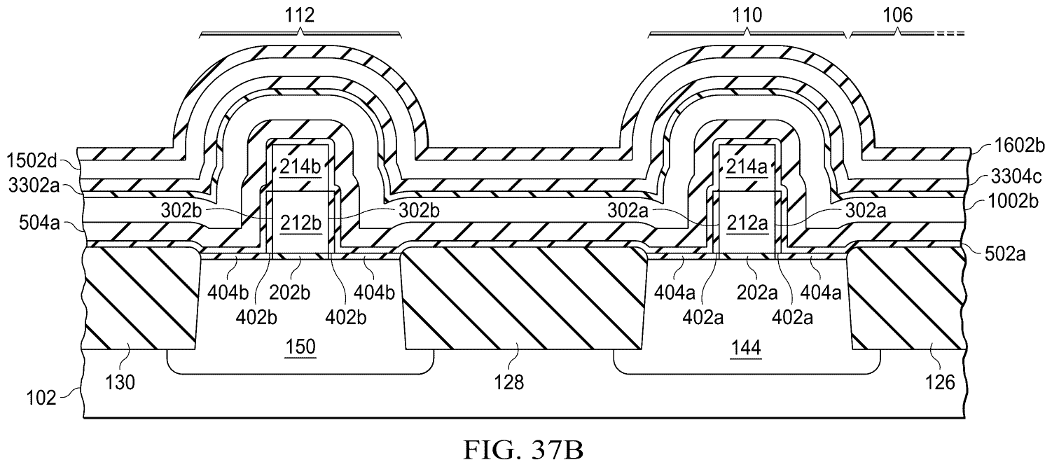

Referring to FIGS. 37A and 37B, the emitter dielectric cap layer 1602, the polycrystalline emitter layer 1502b, and the second dielectric spacer layer 3304a are etched to form the emitter dielectric cap layer 1602a, polycrystalline emitter layer 1502c, and second dielectric spacer 3304b. The layers 1602, 1502b, 3304a may be patterned using appropriate photolithography and etch (e.g., RIE) processes. Residual emitter dielectric cap layer 1602b, residual polycrystalline emitter layer 1502d, and residual second dielectric spacer layer 3304c may remain, as illustrated, in the pFET region 110, nFET region 112, and at least partially in the first transition region 106 proximate to the pFET region 110.

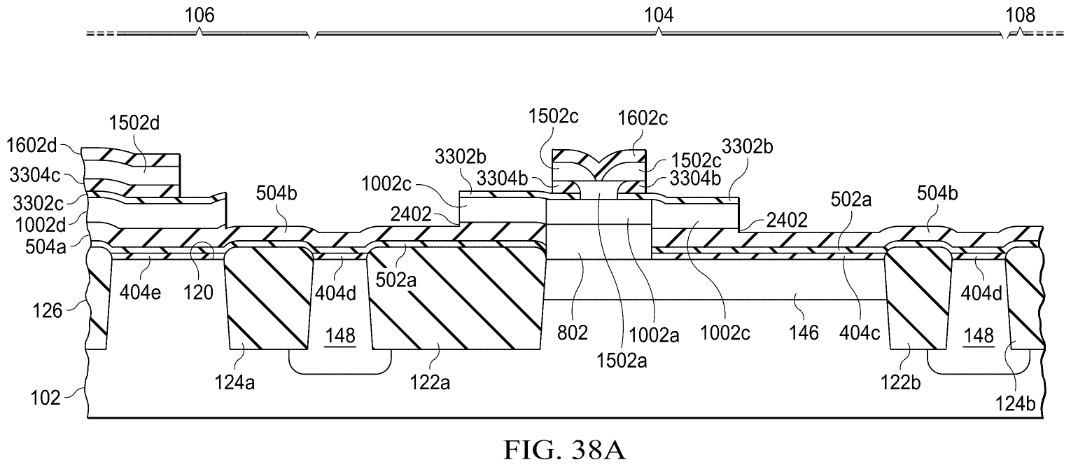

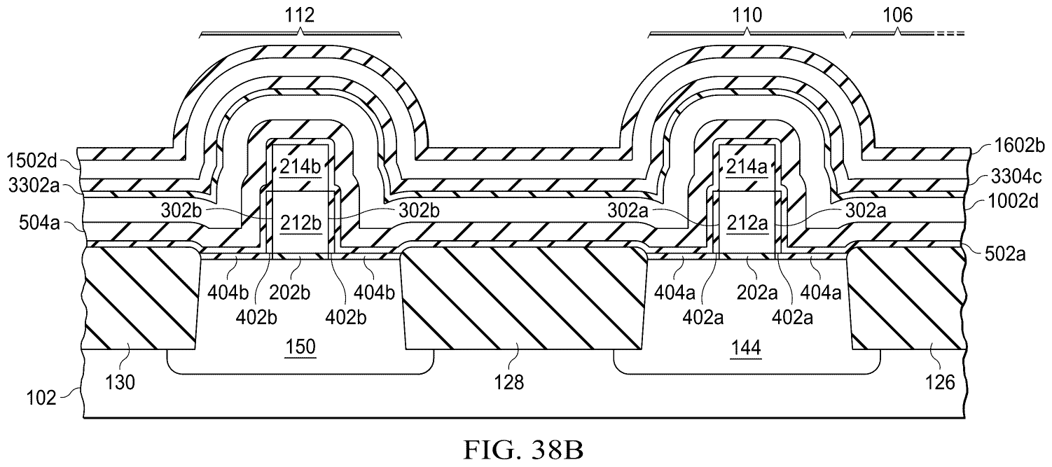

Referring to FIGS. 38A and 38B, the first dielectric spacer layer 3302a and the base layer 1002 (e.g., the polycrystalline base layer 1002b) are patterned, and portions of the pedestal dielectric layer 504a are thinned. The polycrystalline base layer 1002b is patterned to remain as the polycrystalline base layer 1002c in the BJT region 104. The first dielectric spacer layer 3302a is patterned to remain as the first dielectric spacer layer 3302b over the base layer 1002 (e.g., the polycrystalline base layer 1002c) in the BJT region 104. The pedestal dielectric layer 504a is thinned in areas where the first dielectric spacer layer 3302a and the polycrystalline base layer 1002b are removed and results in the pedestal dielectric layer 504b. Thinning of the pedestal dielectric layer 504a results in sidewalls 2402, 2404 in the pedestal dielectric layer 504b that align with respective sidewalls of the polycrystalline base layer 1002c. The first dielectric spacer layer 3302a and the polycrystalline base layer 1002b may be patterned using appropriate photolithography and etch (e.g., RIE) processes. Patterning the first dielectric spacer layer 3302a and the base layer 1002 (e.g., the polycrystalline base layer 1002b) permits residual first dielectric spacer layer 3302c and residual polycrystalline base layer 1002d to remain, as illustrated, in the pFET region 110, nFET region 112, and at least partially in the first transition region 106 proximate to the pFET region 110.

Thereafter, processing continues as described with respect to FIGS. 25A and 25B through FIGS. 32A and 32B above. FIGS. 39A and 39B correspond with processing through the processing described with respect to FIGS. 32A and 32B. With respect to the formation of metal-semiconductor compound described above with respect to FIGS. 32A and 32B, metal-semiconductor compound 3204 is on the base layer 1002 (e.g., the polycrystalline base layer 1002c) in FIGS. 39A and 39B. The deposited metal is reacted with the semiconductor material of the base layer 1002 (e.g., the polycrystalline base layer 1002c). In processing to form the metal-semiconductor compound, the first dielectric spacer layer 3302b not underlying the second dielectric spacer 3304b may be removed, such as by a cleaning or etch process, which may cause a first dielectric spacer 3302d to remain under the second dielectric spacer 3304b.

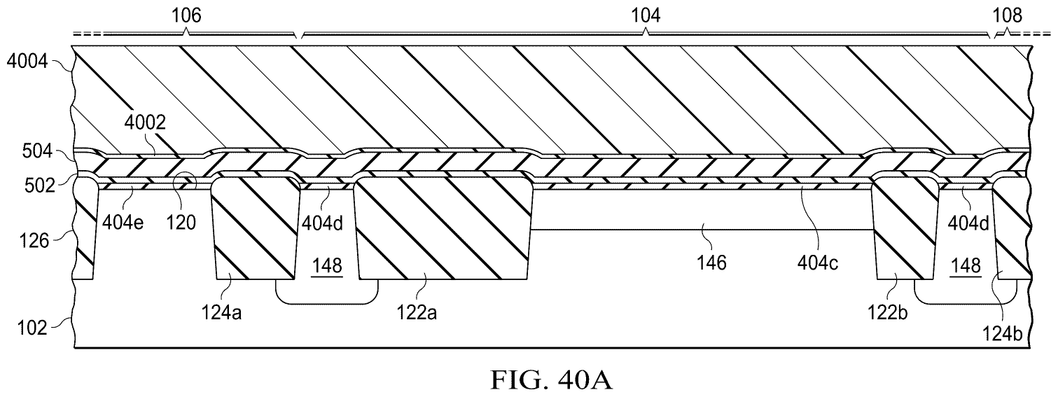

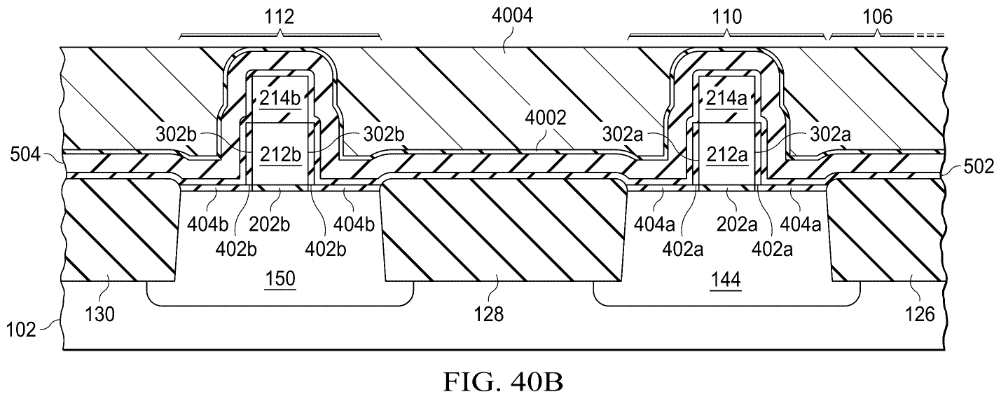

FIGS. 40A and 40B through FIGS. 42A and 42B are respective cross-sectional views of a semiconductor device in intermediate stages of manufacturing according to some examples. A first method of manufacturing including the stages illustrated by FIGS. 40A and 40B through FIGS. 42A and 42B forms the semiconductor device 3200 of FIGS. 32A and 32B. A second method of manufacturing including the stages illustrated by FIGS. 40A and 40B through FIGS. 42A and 42B forms the semiconductor device 3900 of FIGS. 39A and 39B.

In the first method to form the semiconductor device 3200 of FIGS. 32A and 32B, the processing of FIGS. 1A and 1B through FIGS. 5A and 5B is performed to obtain the etch stop layer 502 formed conformally over the semiconductor substrate 102 in the regions 104-112 and a pedestal dielectric layer 504 formed over the etch stop layer 502 in the regions 104-112, as shown in FIGS. 40A and 40B.

Further referring to FIGS. 40A and 40B, an etch stop layer 4002 is formed conformally over the pedestal dielectric layer 504 in the regions 104-112, and a sacrificial material 4004 is formed over the etch stop layer 4002 in the regions 104-112. The etch stop layer 4002 may be or include a material different from the sacrificial material 4004 and from the pedestal dielectric layer 504. In some examples, the sacrificial material 4004 may be a same material as the pedestal dielectric layer 504. In some examples, the etch stop layer 4002 is silicon nitride deposited by CVD, ALD, or the like, although other dielectric materials and/or other deposition processes may be used in other examples. In some examples, the sacrificial material 4004 is silicon oxide (e.g., a TEOS oxide) deposited by CVD, although other dielectric materials and/or other deposition processes may be used in other examples. After depositing the sacrificial material 4004, a planarization process is performed. In some examples, the planarization process is a CMP. The planarization process planarizes an upper surface of the sacrificial material 4004. The planarization process may cause the upper surface of the sacrificial material 4004 to remain over the etch stop layer 4002 over the hardmask layers 214a, 214b, to be coplanar with upper surfaces of the etch stop layer 4002 over the hardmask layers 214a, 214b, or to be coplanar with upper surfaces of the etch stop layer 4002 and upper surfaces of the hardmask layers 214a, 214b.

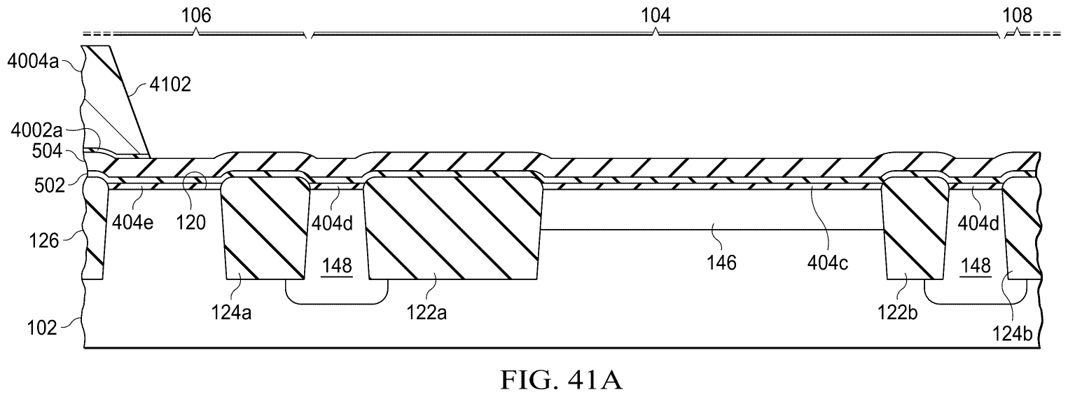

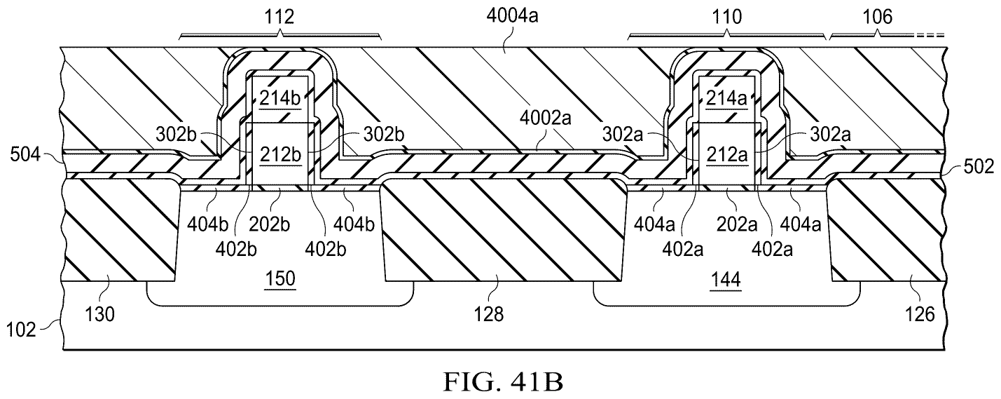

Referring to FIGS. 41A and 41B, the etch stop layer 4002 and the sacrificial material 4004 are patterned into an etch stop layer 4002a and a sacrificial material 4004a. The patterning of the etch stop layer 4002 and the sacrificial material 4004 removes the etch stop layer 4002 and the sacrificial material 4004 from the BJT region 104 and at least partially from the transition regions 106, 108. The etch stop layer 4002a and the sacrificial material 4004a remain in the pFET region 110, the nFET region 112, and at least partially the first transition region 106. The etch stop layer 4002 and the sacrificial material 4004 may be patterned using appropriate photolithography and etch (e.g., RIE) processes.

A sidewall 4102 of the sacrificial material 4004a is formed in the first transition region 106. In the illustrated example, the sidewall 4102 is sloped. In some examples, the sidewall 4102 may be formed with a low magnitude slope (e.g., relatively large lateral run compared to a smaller vertical rise) such that layers that are deposited on the sidewall 4102 and subsequent etched are completely removed by the respective etch. In such examples, residuals of such layers may be avoided in the first transition region 106. In other examples, the sidewall 4102 may be vertical or have a high magnitude slope such that residuals of layers are formed along the sidewall 4102. Examples of such residuals are described in U.S. patent application Ser. No. 18/411,331, entitled “SEMICONDUCTOR PROCESSING INTEGRATION FOR BIPOLAR JUNCTION TRANSISTOR (BJT)”, filed on Jan. 12, 2024, the entirety of which is incorporated herein by reference. The magnitude of the slope of the sidewall 4102 may be tuned by tuning parameters of the etch process in patterning the sacrificial material 4004.

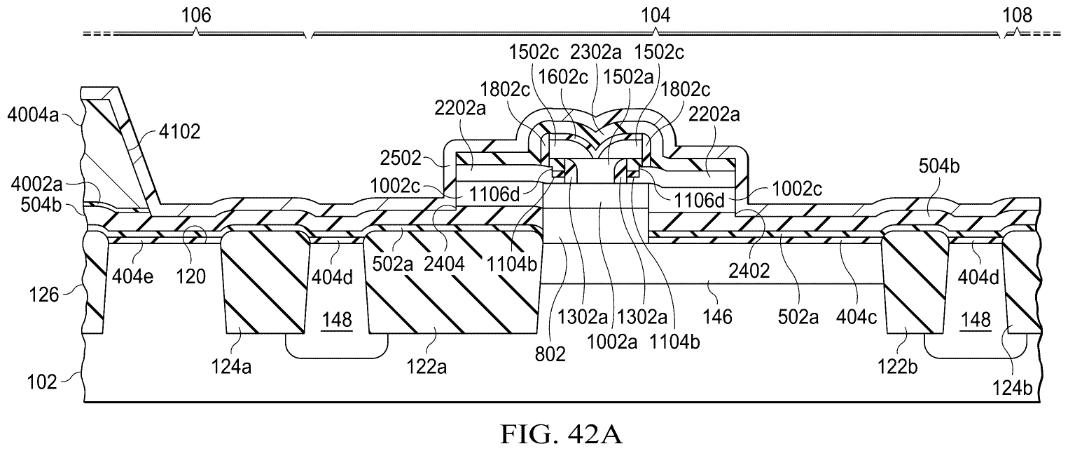

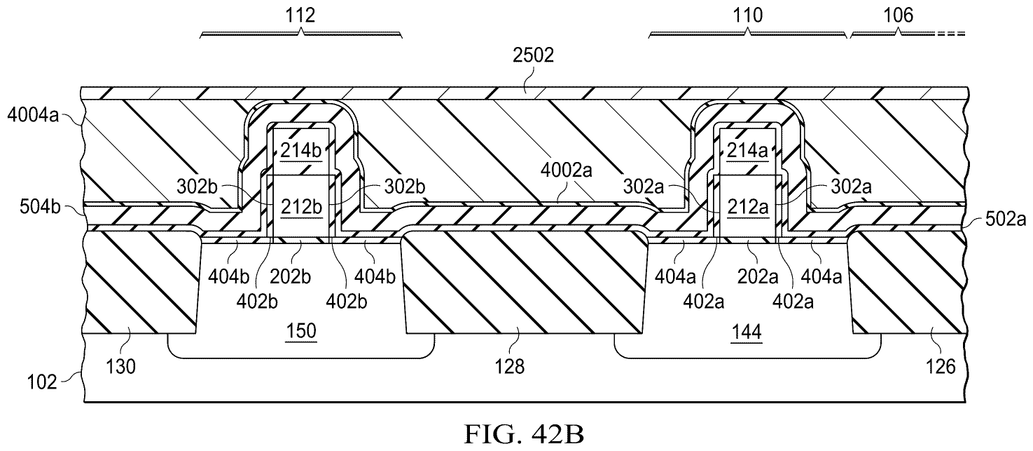

Following the processing of FIGS. 41A and 41B, the processing described above with respect to FIGS. 6A and 6B through FIGS. 25A and 25B is performed, which results in FIGS. 42A and 42B. In such processing, various layers may be deposited on or over the sacrificial material 4004a. When the respective layer is patterned, that layer may be removed from over the sacrificial material 4004a. For example, patterning the emitter dielectric cap layer 1602, the polycrystalline emitter layer 1502b, and the third dielectric spacer layer 1106a as described in FIGS. 17A and 17B may remove those layers from over the sacrificial material 4004a in the pFET region 110, nFET region 112, and the first transition region 106. Similarly, patterning the dielectric protective layer 2302, the raised base layer 2202, and the polycrystalline base layer 1002b as described in FIGS. 24A and 24B may remove those layers from over the sacrificial material 4004a in the pFET region 110, nFET region 112, and the first transition region 106. Depending on the slope of the sidewall 4102, residuals of these layers may remain as residual spacers along the sidewall 4102. Removing these layers from over the sacrificial material 4004a causes the hardmask layer 2502 to be formed on or over the sacrificial material 4004a in the pFET region 110, nFET region 112, and the first transition region 106 as shown in FIGS. 42A and 42B.

Thereafter, the processing described above with respect to FIGS. 26A and 26B through FIGS. 32A and 32B is performed. With respect to the processing described above with respect to FIGS. 26A and 26B, as shown in FIGS. 42A and 42B, the hardmask layer 2502, the sacrificial material 4004a, the etch stop layers 4002a, 502a, and the pedestal dielectric layer 504b are removed from the pFET region 110 and the nFET region 112. Appropriate photolithography and etch processes may be used to remove these layers and spacers, and the etch process may be or include a wet or dry etch, which may further be isotropic. The hardmask layer 2502, pedestal dielectric layer 504b, and etch stop layer 502a are patterned to remain in the BJT region 104 and extending at least partially into the transition regions 106, 108 as a hardmask layer 2502a, a pedestal dielectric layer 504c, and etch stop layer 502b, respectively. Depending upon alignment of masks (e.g., photoresists between various photolithography processes), some residual portions of the sacrificial material 4004a and etch stop layer 4002a and any other residual spacer in the first transition region 106 may remain in the first transition region 106. The sacrificial material 4004a, the etch stop layers 4002a, 502a, and the pedestal dielectric layer 504b are removed from the lateral sides of the gate electrodes 212a, 212b in the pFET region 110 and nFET region 112 (e.g., removed from the reoxidation layers 402a, 402b on the sidewalls 302a, 302b). Then, the processing through FIGS. 32A and 32B may be performed to form the semiconductor device 3200 of FIGS. 32A and 32B.

In the second method to form the semiconductor device 3900 of FIGS. 39A and 39B, the processing of FIGS. 1A and 1B through FIGS. 5A and 5B is performed to obtain the etch stop layer 502 formed conformally over the semiconductor substrate 102 in the regions 104-112 and a pedestal dielectric layer 504 formed over the etch stop layer 502 in the regions 104-112, as shown in FIGS. 40A and 40B. Then, processing proceeds as described above with respect to FIGS. 40A and 40B and FIGS. 41A and 41B. Processing then proceeds as described above with respect to FIGS. 6A and 6B through FIGS. 10A and 10B. Processing continues as described above with respect to FIGS. 33A and 33B through FIGS. 38A and 38B. Thereafter, processing continues as described with respect to FIGS. 25A and 25B through FIGS. 32A and 32B above, which forms the semiconductor device 3900 of FIGS. 39A and 39B.

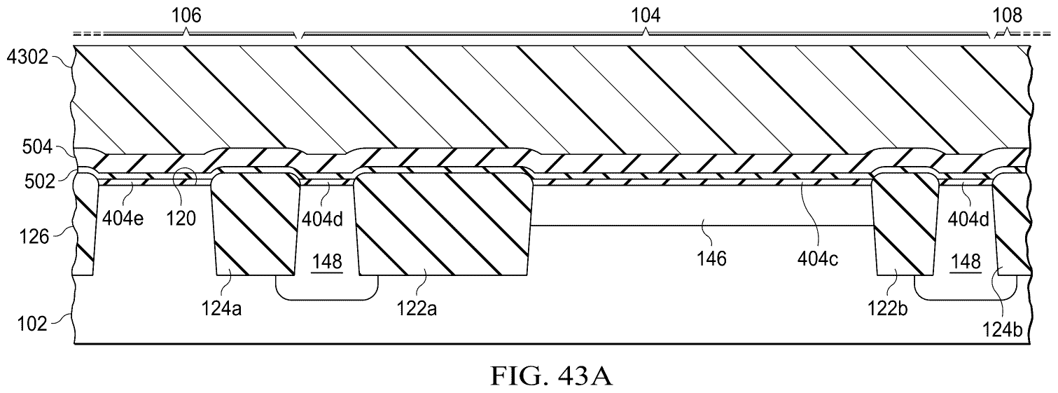

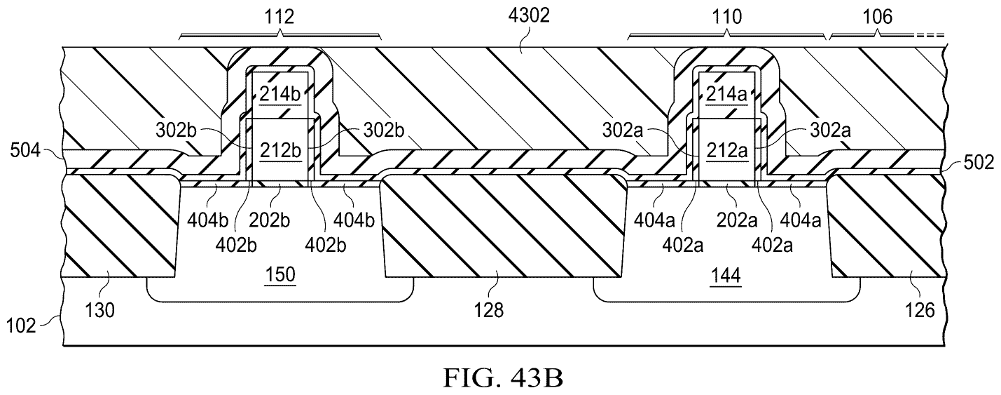

FIGS. 43A and 43B through FIGS. 45A and 45B are respective cross-sectional views of a semiconductor device in intermediate stages of manufacturing according to some examples. A first method of manufacturing including the stages illustrated by FIGS. 43A and 43B through FIGS. 45A and 45B forms the semiconductor device 3200 of FIGS. 32A and 32B. A second method of manufacturing including the stages illustrated by FIGS. 43A and 43B through FIGS. 45A and 45B forms the semiconductor device 3900 of FIGS. 39A and 39B.

In the first method to form the semiconductor device 3200 of FIGS. 32A and 32B, the processing of FIGS. 1A and 1B through FIGS. 5A and 5B is performed to obtain the etch stop layer 502 formed conformally over the semiconductor substrate 102 in the regions 104-112 and a pedestal dielectric layer 504 formed over the etch stop layer 502 in the regions 104-112, as shown in FIGS. 43A and 43B.

Further referring to FIGS. 43A and 43B, a sacrificial material 4302 is formed over the pedestal dielectric layer 504 in the regions 104-112. In some examples, the sacrificial material 4302 may be a material different from the pedestal dielectric layer 504, which may provide etch selectivity between the sacrificial material 4302 and the pedestal dielectric layer 504. In some examples, the sacrificial material 4302 is silicon (e.g., polysilicon) deposited by CVD, although other dielectric materials having etch selectivity from the pedestal dielectric layer 504 and/or other deposition processes may be used in other examples. After depositing the sacrificial material 4302, a planarization process is performed. In some examples, the planarization process is a CMP. The planarization process planarizes an upper surface of the sacrificial material 4302. The planarization process may cause the upper surface of the sacrificial material 4302 to remain over the hardmask layers 214a, 214b or to be coplanar with upper surfaces of the hardmask layers 214a, 214b.

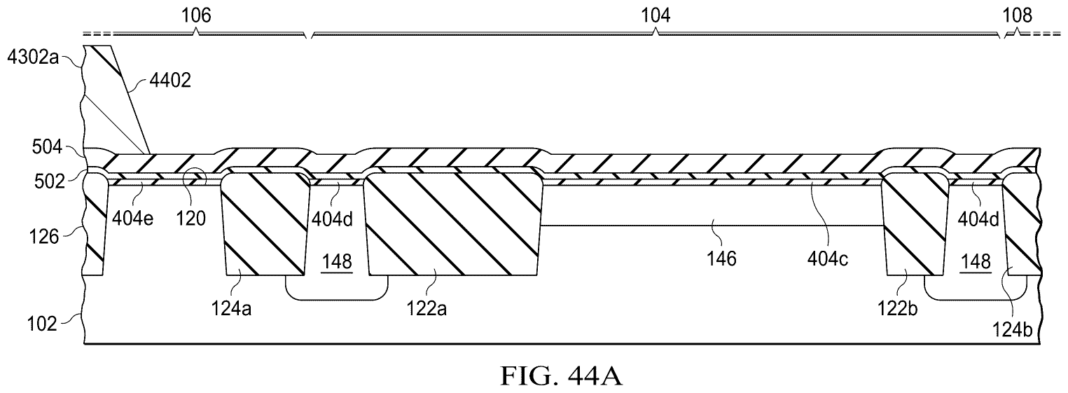

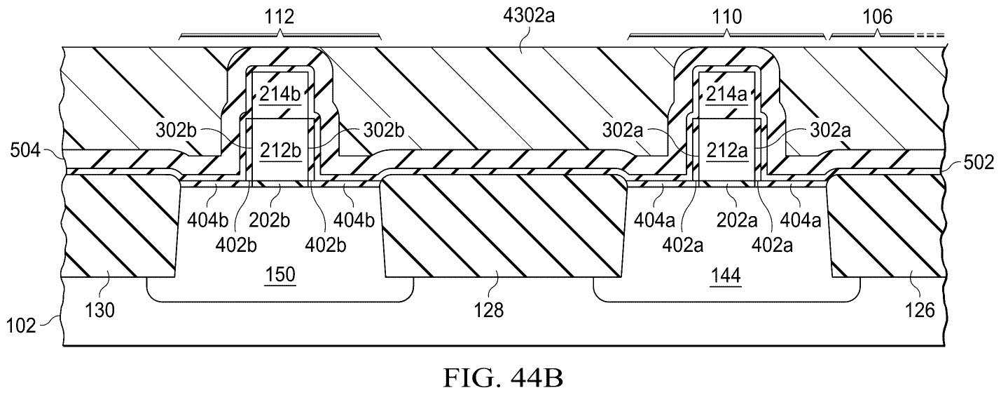

Referring to FIGS. 44A and 44B, the sacrificial material 4302 is patterned into a sacrificial material 4302a. The patterning of the sacrificial material 4302 removes the sacrificial material 4302 from the BJT region 104 and at least partially from the transition regions 106, 108. The sacrificial material 4302a remains in the pFET region 110, the nFET region 112, and at least partially the first transition region 106. The sacrificial material 4302 may be patterned using appropriate photolithography and etch (e.g., RIE) processes. A sidewall 4402 of the sacrificial material 4302a is formed in the first transition region 106. Like described above with respect to FIGS. 41A and 41B, the slope of the sidewall 4402 may be tuned by the etch process, which slope may avoid or may cause to be formed various residual spacers in the first transition region 106.

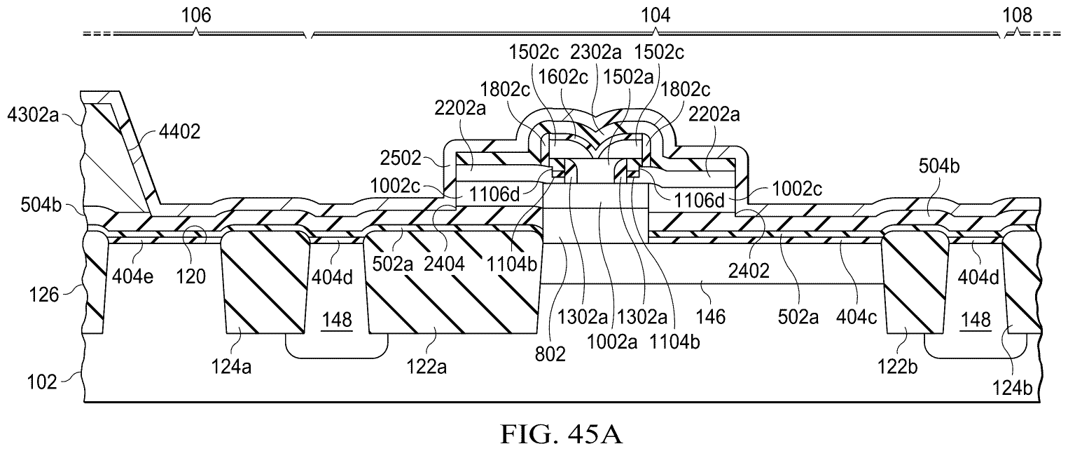

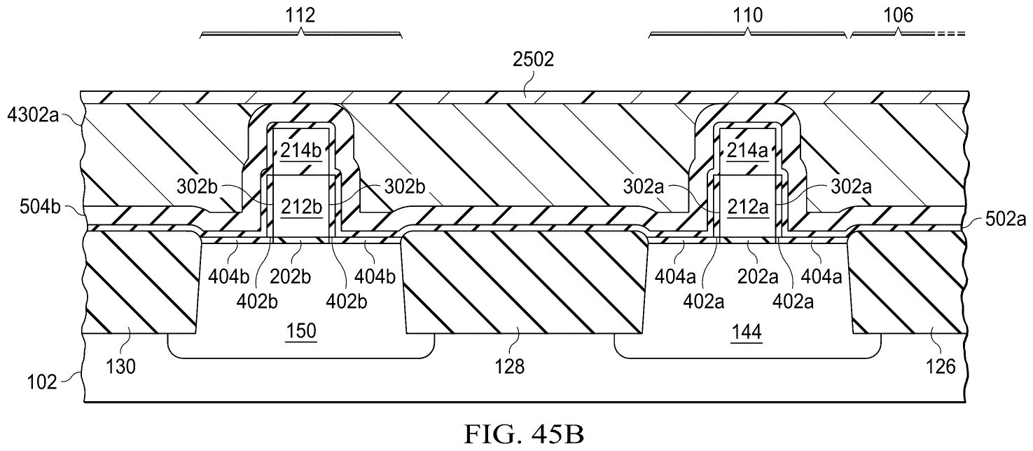

Following the processing of FIGS. 44A and 44B, the processing described above with respect to FIGS. 6A and 6B through FIGS. 25A and 25B is performed, which results in FIGS. 45A and 45B. In such processing, various layers may be deposited on or over the sacrificial material 4302a. When the respective layer is patterned, that layer may be removed from over the sacrificial material 4302a. For example, patterning the emitter dielectric cap layer 1602, the polycrystalline emitter layer 1502b, and the third dielectric spacer layer 1106a as described in FIGS. 17A and 17B may remove those layers from over the sacrificial material 4302a in the pFET region 110, nFET region 112, and the first transition region 106. Similarly, patterning the dielectric protective layer 2302, the raised base layer 2202, and the polycrystalline base layer 1002b as described in FIGS. 24A and 24B may remove those layers from over the sacrificial material 4302a in the pFET region 110, nFET region 112, and the first transition region 106. Depending on the slope of the sidewall 4402, residuals of these layers may remain as residual spacers along the sidewall 4402. Removing these layers from over the sacrificial material 4302a causes the hardmask layer 2502 to be formed on or over the sacrificial material 4302a in the pFET region 110, nFET region 112, and the first transition region 106 as shown in FIGS. 45A and 45B.

Thereafter, the processing described above with respect to FIGS. 26A and 26B through FIGS. 32A and 32B is performed. With respect to the processing described above with respect to FIGS. 26A and 26B, as shown in FIGS. 45A and 45B, the hardmask layer 2502, the sacrificial material 4302a, the etch stop layer 502a, and the pedestal dielectric layer 504b are removed from the pFET region 110 and the nFET region 112. Appropriate photolithography and etch processes may be used to remove these layers, and the etch process may be or include a wet or dry etch, which may further be isotropic. The hardmask layer 2502, pedestal dielectric layer 504b, and etch stop layer 502a are patterned to remain in the BJT region 104 and extending at least partially into the transition regions 106, 108 as a hardmask layer 2502a, a pedestal dielectric layer 504c, and etch stop layer 502b, respectively. Depending upon alignment of masks (e.g., photoresists between various photolithography processes), some residual portions of the sacrificial material 4302a and any other residual spacer in the first transition region 106 may remain. The sacrificial material 4302a, the etch stop layer 502a, and the pedestal dielectric layer 504b are removed from the lateral sides of the gate electrodes 212a, 212b in the pFET region 110 and nFET region 112 (e.g., removed from the reoxidation layers 402a, 402b on the sidewalls 302a, 302b). Then, the processing through FIGS. 32A and 32B may be performed to form the semiconductor device 3200 of FIGS. 32A and 32B.

In the second method to form the semiconductor device 3900 of FIGS. 39A and 39B, the processing of FIGS. 1A and 1B through FIGS. 5A and 5B is performed to obtain the etch stop layer 502 formed conformally over the semiconductor substrate 102 in the regions 104-112 and a pedestal dielectric layer 504 formed over the etch stop layer 502 in the regions 104-112, as shown in FIGS. 40A and 40B. Then, processing proceeds as described above with respect to FIGS. 43A and 43B and FIGS. 44A and 44B. Processing then proceeds as described above with respect to FIGS. 6A and 6B through FIGS. 10A and 10B. Processing continues as described above with respect to FIGS. 33A and 33B through FIGS. 38A and 38B. Thereafter, processing continues as described with respect to FIGS. 25A and 25B through FIGS. 32A and 32B above, which forms the semiconductor device 3900 of FIGS. 39A and 39B.

FIGS. 32A and 32B illustrate a semiconductor device 3200, and FIGS. 39A and 39B illustrate a semiconductor device 3900. Each illustrated semiconductor device 3200, 3900 includes a BJT in the BJT region 104. The BJT includes the collector layer 802, base layer 1002 (e.g., monocrystalline base layer 1002a and polycrystalline base layer 1002c), and emitter layer 1502 (e.g., monocrystalline emitter layer 1502a and polycrystalline emitter layer 1502b). The BJT of the semiconductor device 3200 of FIGS. 32A and 32B also includes a raised base layer 2202a on the base layer 1002 (e.g., on the polycrystalline base layer 1002c).

The collector layer 802 is over and on the upper surface 120 of the semiconductor substrate 102 and is through an opening in a pedestal dielectric layer 504f, etch stop layer 502c, and reoxidation layer 404g, which are also over the upper surface of the semiconductor substrate 102. The collector layer 802 is on the n-type doped sub-collector diffusion region 146 in the semiconductor substrate 102. The base layer 1002 (e.g., the monocrystalline base layer 1002a) is over and on the collector layer 802, and the base layer 1002 (e.g., the polycrystalline base layer 1002c) is over and on an upper surface of the pedestal dielectric layer 504f.

The pedestal dielectric layer 504f is in the BJT region 104 and underlies the base layer 1002. The portion of the pedestal dielectric layer 504f directly underlying the base layer 1002 has a first thickness. The pedestal dielectric layer 504f has sidewalls 2402, 2404 that align with respective sidewalls of the base layer 1002. The pedestal dielectric layer 504f has the first thickness laterally between the sidewalls 2402, 2404. The pedestal dielectric layer 504f extends laterally from the base layer 1002 (e.g., the polycrystalline base layer 1002c). For example, the pedestal dielectric layer 504f extends over and on the upper surface 120 of the semiconductor substrate 102 over the n-type doped sub-collector diffusion region 146 and laterally away from a corresponding sidewall of the polycrystalline base layer 1002c (and the aligned sidewall 2402 of the pedestal dielectric layer 504f) to the sidewall 2702 proximate the n-type collector contact region 3112. Additionally, the pedestal dielectric layer 504f extends over and on the first portion 122a of the isolation structure 122 laterally away from a corresponding sidewall of the polycrystalline base layer 1002c (and the aligned sidewall 2404 of the pedestal dielectric layer 504f) to the sidewall 2704 over the first portion 122a of the isolation structure 122. The pedestal dielectric layer 504f has a second thickness laterally between the sidewalls 2402, 2702 and laterally between the sidewalls 2404, 2704, which is less than the first thickness of the pedestal dielectric layer 504f laterally between the sidewalls 2402, 2404.

The emitter layer 1502 (e.g., the monocrystalline emitter layer 1502a) is over and on the base layer 1002 (e.g., the monocrystalline base layer 1002a) and is through an opening defined by a spacer structure, and the emitter layer 1502 (e.g., the polycrystalline emitter layer 1502c) is over and on the spacer structure. In the semiconductor device 3200 of FIGS. 32A and 32B, the spacer structure includes the second dielectric spacer 1104b, the third dielectric spacer 1106d, and emitter dielectric spacer 1302a. In the semiconductor device 3900 of FIGS. 39A and 39B, the spacer structure includes the first dielectric spacer 3302d and the second dielectric spacer 3304b.

The metal-semiconductor compound 3202 is on the emitter layer 1502 (e.g., the polycrystalline emitter layer 1502c and/or monocrystalline emitter layer 1502a). The metal-semiconductor compound 3206 is on the upper surface 120 of the semiconductor substrate 102 on the n-type collector contact region 3112. In the semiconductor device 3200 of FIGS. 32A and 32B, the metal-semiconductor compound 3204 is on the raised base layer 2202a. In the semiconductor device 3900 of FIGS. 39A and 39B, the metal-semiconductor compound 3204 is on the base layer 1002 (e.g., the polycrystalline base layer 1002c).

In some examples, the BJT may be a heterojunction BJT. As indicated previously, in some examples, the collector layer 802 and the emitter layer 1502 may be silicon, and the base layer 1002 may include silicon germanium. Hence, in some examples, the base layer 1002 may include a semiconductor material dissimilar from respective semiconductor materials of the collector layer 802 and emitter layer 1502. The dissimilar semiconductor materials may form one or more heterojunctions in the BJT, and the BJT may therefore be a heterojunction BJT.

Each illustrated semiconductor device 3200, 3900 includes a pFET in the pFET region 110 and an nFET in the nFET region 112. The pFET region 110 and nFET region 112 are in a CFET region. The pFET includes the gate electrode 212a, gate dielectric layer 202a, embedded stressors 2902, PSD regions, p-type LDDs 2812, and a channel region in the semiconductor substrate 102 underlying the gate electrode 212a. The gate electrode 212a is over and on the gate dielectric layer 202a, and the gate dielectric layer 202a is over and on the upper surface 120 of the semiconductor substrate 102. The p-type LDDs 2812 are on laterally opposing sides of the gate electrode 212a and in the semiconductor substrate 102. The channel region is laterally between the p-type LDDs 2812. The embedded stressors 2902 and PSD regions are on laterally opposing sides of the gate electrode 212a, with the p-type LDDs 2812 and channel region therebetween. Similarly, the nFET includes the gate electrode 212b, gate dielectric layer 202b, NSD regions 3114, n-type LDDs 2814, and a channel region in the semiconductor substrate 102 underlying the gate electrode 212b. The gate electrode 212b is over and on the gate dielectric layer 202b, and the gate dielectric layer 202b is over and on the upper surface 120 of the semiconductor substrate 102. The n-type LDDs 2814 are on laterally opposing sides of the gate electrode 212b and in the semiconductor substrate 102. The channel region is laterally between the n-type LDDs 2814. The NSD regions 3114 are on laterally opposing sides of the gate electrode 212b, with the n-type LDDs 2814 and channel region therebetween. The pFET and nFET may be complementary devices (e.g., complementary metal-oxide-semiconductor (CMOS) devices). In some examples, the pFET may be a p-type metal-oxide-semiconductor (PMOS) transistor, and the nFET may be an n-type metal-oxide-semiconductor (NMOS) transistor.

The first transition region 106 is between the BJT region 104 and the CFET region (e.g., with the CFET region having a boundary of the pFET region 110 in the illustrated examples). The second transition region 108 extends from a boundary of the BJT region 104 (e.g., opposite from the first transition region 106). A composite structure may remain in the first transition region 106 and/or second transition region 108. The composite structure may include respective residuals of various layers or materials formed during semiconductor processing and/or may be processing artifact(s). As illustrated in FIGS. 32A and 39A, the composite structure includes the residual pedestal dielectric layer 504g and the residual etch stop layer 502d. Further, in some examples, the composite structure may include one or both of a residual polycrystalline base spacer and a residual polycrystalline emitter spacer. The composite structure may include one or more other residual dielectric spacers. Example residual spacers that may be formed in the composite structure are described in U.S. patent application Ser. No. 18/411,331, entitled “SEMICONDUCTOR PROCESSING INTEGRATION FOR BIPOLAR JUNCTION TRANSISTOR (BJT)”, filed on Jan. 12, 2024. In other examples, a composite structure including such residual spacers or residual layers may not be formed in the first transition region 106 and/or second transition region 108.

The semiconductor processing to form the semiconductor devices 3200, 3900 of FIGS. 32A and 32B and FIGS. 39A and 39B may enable vertical scaling and horizontal scaling. In some examples, for vertical scaling, thicknesses of the collector layer 802, base layer 1002, and emitter layer 1502 may be reduced. In some examples, a thickness of the collector layer 802 does not exceed 200 nm, and a thickness of the base layer 1002 (e.g., the monocrystalline base layer 1002a) does not exceed 100 nm. Further, in some examples, the thickness of the collector layer 802 is in a range from 10 nm to 100 nm, and a thickness of the base layer 1002 (e.g., the monocrystalline base layer 1002a) is in a range from 10 nm to 50 nm. Additionally, in some examples, a thickness of the emitter layer 1502 (e.g., the monocrystalline emitter layer 1502a) does not exceed 100 nm. In some examples, the thickness of the emitter layer 1502 (e.g., the monocrystalline emitter layer 1502a) is in a range from 10 nm to 50 nm. Generally, a thickness of a given layer is in a direction normal to a tangent plane of the underlying surface on which the given layer is formed. However, in some instances, such as with a conformal deposition, a direction normal to a tangent plane of the underlying surface may not be a thickness, such as where a thickness from another tangent plane intersects that direction normal, like at a corner.

For horizontal scaling, widths of respective openings in which the collector layer 802 and the emitter layer 1502 (e.g., the monocrystalline emitter layer 1502a) are formed, may be reduced. The width of the collector opening 702, in which the collector layer 802 is formed, may be reduced, and the width of the emitter opening 1402, 3402, in which the monocrystalline emitter layer 1502a is formed, may be reduced. The semiconductor processing described above may enable horizontal scaling to, e.g., a 28 nm technology node and beyond (e.g., a 21 nm technology node or less). Referring to FIG. 46, the lateral boundaries of the pedestal dielectric layer 504f are shown. The collector layer 802 is laterally interior within the pedestal dielectric layer 504f in the collector opening 702. The collector opening 702 and hence, the collector layer 802, has a width 4612. The lateral boundaries of the base layer 1002 (e.g., the polycrystalline base layer 1002c), and where applicable, the raised base layer 2202a, are also shown. The emitter opening 1402, 3402 shown in FIGS. 14A and 34A are shown. The emitter opening 1402, 3402 has a width 4614. The emitter layer 1502 (e.g., the monocrystalline emitter layer 1502a) is formed in the emitter opening 1402, 3402. One or both of the widths 4612, 4614 may be reduced for horizontal scaling. In some examples, the width 4612 does not exceed 200 nm, and the width 4614 does not exceed 120 nm. Further, in some examples, the width 4612 is in a range from 80 nm to 180 nm, and the width 4614 is in a range from 40 nm to 100 nm.

Although various examples have been described in detail, it should be understood that various changes, substitutions, and alterations can be made therein without departing from the scope defined by the appended claims.

What is claimed is:

1. A semiconductor device, comprising:
a semiconductor substrate including a bipolar junction transistor (BJT) region and a complementary field effect transistor (CFET) region;
an etch stop layer over the semiconductor substrate in the BJT region;
a pedestal dielectric layer over the etch stop layer in the BJT region;
a BJT on the semiconductor substrate in the BJT region, at least a first portion of the BJT being in an opening through the pedestal dielectric layer and the etch stop layer, at least a second portion of the BJT further being over the pedestal dielectric layer; and
a field effect transistor (FET) on the semiconductor substrate in the CFET region.

2. The semiconductor device of claim 1, further comprising an oxidation layer on the semiconductor substrate in the BJT region, the etch stop layer being over the oxidation layer.

3. The semiconductor device of claim 1, wherein:
the BJT comprises:
a collector layer on the semiconductor substrate, the collector layer being in the opening through the pedestal dielectric layer and the etch stop layer;
a base layer on the collector layer, the base layer being over the pedestal dielectric layer; and
an emitter layer on the base layer.

4. The semiconductor device of claim 3, wherein the semiconductor substrate includes:
a doped sub-collector diffusion region in the BJT region, the collector layer being on the doped sub-collector diffusion region; and
a doped collector contact region in the doped sub-collector diffusion region, at least a portion of the pedestal dielectric layer being laterally between the collector layer and the doped collector contact region.

5. The semiconductor device of claim 3, wherein the pedestal dielectric layer extends laterally away from the base layer.

6. The semiconductor device of claim 3, wherein the BJT further comprises a raised base layer on the base layer.

7. The semiconductor device of claim 6, further comprising:
a base metal-semiconductor compound on the raised base layer; and
an emitter metal-semiconductor compound on the emitter layer.

8. The semiconductor device of claim 3, further comprising:
a base metal-semiconductor compound on the base layer; and
an emitter metal-semiconductor compound on the emitter layer.

9. A method, comprising:
forming a gate layer over a semiconductor substrate in a bipolar junction transistor (BJT) region and a complementary field effect transistor (CFET) region;
patterning the gate layer into a gate electrode of a field effect transistor (FET) in the CFET region;
forming a first etch stop layer conformally over the semiconductor substrate in the BJT region and the CFET region and over the gate electrode;
forming a collector layer on the semiconductor substrate and in an opening through the first etch stop layer in the BJT region;
forming a base layer on the collector layer and at least partially over the first etch stop layer; and
forming an emitter layer on the base layer.

10. The method of claim 9, further comprising forming a first oxidation layer on an upper surface of the semiconductor substrate in the BJT region, the first etch stop layer being formed over the first oxidation layer, forming the first oxidation layer including performing an oxidation process.

11. The method of claim 10, wherein the oxidation process further forms a second oxidation layer on a sidewall of the gate electrode, the first etch stop layer further being formed on the second oxidation layer.

12. The method of claim 9, further comprising forming a pedestal dielectric layer over the first etch stop layer, the opening through the first etch stop layer further being through the pedestal dielectric layer.

13. The method of claim 12, wherein the pedestal dielectric layer is conformally over the gate electrode and the first etch stop layer in the CFET region.

14. The method of claim 12, wherein:
forming the base layer includes:
depositing a material of the base layer conformally in the BJT region and the CFET region, the material of the base layer being deposited conformally over the gate electrode; and
patterning the material of the base layer into the base layer in the BJT region; and
forming the emitter layer includes:
depositing a material of the emitter layer conformally in the BJT region and the CFET region, the material of the emitter layer being deposited conformally over the gate electrode; and
patterning the material of the emitter layer into the emitter layer in the BJT region.

15. The method of claim 14, further comprising removing a portion of the material of the base layer and a portion of the material of the emitter layer from the CFET region after patterning the material of the base layer into the base layer and patterning the material of the emitter layer into the emitter layer.

16. The method of claim 12, further comprising:
forming a second etch stop layer in the CFET region over the pedestal dielectric layer; and
forming a sacrificial material in the CFET region over the second etch stop layer,
wherein:
forming the base layer includes:
depositing a material of the base layer conformally in the BJT region and the CFET region, the material of the base layer being deposited over the sacrificial material; and
patterning the material of the base layer into the base layer in the BJT region; and
forming the emitter layer includes:
depositing a material of the emitter layer conformally in the BJT region and the CFET region, the material of the emitter layer being deposited over the sacrificial material; and
patterning the material of the emitter layer into the emitter layer in the BJT region.

17. The method of claim 16, wherein:
patterning the material of the base layer into the base layer in the BJT region removes the material of the base layer from over the sacrificial material; and
patterning the material of the emitter layer into the emitter layer in the BJT region removes the material of the emitter layer from over the sacrificial material.

18. The method of claim 12, further comprising:
forming a sacrificial material in the CFET region over the pedestal dielectric layer, the sacrificial material being a different material from the pedestal dielectric layer,
wherein:
forming the base layer includes:
depositing a material of the base layer conformally in the BJT region and the CFET region, the material of the base layer being deposited over the sacrificial material; and
patterning the material of the base layer into the base layer in the BJT region; and
forming the emitter layer includes:
depositing a material of the emitter layer conformally in the BJT region and the CFET region, the material of the emitter layer being deposited over the sacrificial material; and
patterning the material of the emitter layer into the emitter layer in the BJT region.

19. The method of claim 18, wherein:
patterning the material of the base layer into the base layer in the BJT region removes the material of the base layer from over the sacrificial material; and
patterning the material of the emitter layer into the emitter layer in the BJT region removes the material of the emitter layer from over the sacrificial material.

20. A method, comprising:
forming a gate layer over a semiconductor substrate in a bipolar junction transistor (BJT) region and a complementary field effect transistor (CFET) region;
patterning the gate layer in the CFET region into a gate electrode of a field effect transistor (FET) in the CFET region;
forming a first etch stop layer conformally in the CFET region and the BJT region, the first etch stop layer being along a side of the gate electrode and over the gate electrode;
forming a collector layer on the semiconductor substrate and through an opening in the first etch stop layer in the BJT region;
forming a material of a base layer over the collector layer and over the first etch stop layer;
forming a material of an emitter layer over the base layer;
patterning the material of the emitter layer into the emitter layer in the BJT region; and
patterning the material of the base layer into the base layer in the BJT region.

21. The method of claim 20, further comprising oxidizing a sidewall of the gate electrode before forming the first etch stop layer, the first etch stop layer being formed on the oxidized sidewall of the gate electrode.

22. The method of claim 20, wherein:
the material of the base layer is deposited conformally along the side of the gate electrode and over the gate electrode; and
the material of the emitter layer being deposited conformally along the side of the gate electrode and over the gate electrode.

23. The method of claim 20, further comprising:
forming a pedestal dielectric layer in the BJT region and the CFET region conformally over the first etch stop layer, wherein the collector layer is formed through an opening in the pedestal dielectric layer in the BJT region;
forming a second etch stop layer in the CFET region over the pedestal dielectric layer; and
forming a sacrificial material in the CFET region over the second etch stop layer, wherein the material of the base layer is deposited over the sacrificial material, and the material of the emitter layer is deposited over the sacrificial material.

24. The method of claim 20, further comprising:
forming a pedestal dielectric layer in the BJT region and the CFET region conformally over the first etch stop layer, wherein the collector layer is formed through an opening in the pedestal dielectric layer in the BJT region; and
forming a sacrificial material in the CFET region over the pedestal dielectric layer, the sacrificial material being a different material from the pedestal dielectric layer, wherein the material of the base layer is deposited over the sacrificial material, and the material of the emitter layer is deposited over the sacrificial material.
